(19) United States
(12) Patent Application Publication
(10) Pub. No.: US 2026/0068628 A1
(43) Pub. Date: Mar. 5, 2026

(54) THREE-DIMENSIONAL MEMORY DEVICE WITH SIDE-CONTACT THROUGH-STACK CONTACT VIA STRUCTURES AND METHODS FOR FORMING THE SAME

(71) Applicant: Sandisk Technologies, Inc., Milpitas, CA (US)

(72) Inventors: Masaru KOBAYASHI, Yokkaichi (JP); Masaaki SHINOHARA, Yokkaichi (JP); Mako OIWA, Yokkaichi (JP); Akira TAKAHASHI, Yokkaichi (JP)

(21) Appl. No.: 18/933,511

(22) Filed: Oct. 31, 2024

Related U.S. Application Data
(63) Continuation of application No. 18/824,214, filed on Sep. 4, 2024.

(51) Int. Cl. H01L 23/522; G11C 16/04; H01L 23/528; H01L 23/532; H10B 43/10; H10B 43/27; H10B 43/35

(52) U.S. Cl. CPC H01L 23/5226; G11C 16/0483; H10B 43/10; H10B 43/27; H10B 43/35

(57) ABSTRACT

A device structure includes an alternating stack of insulating layers and electrically conductive layers, a memory opening vertically extending through each layer within the alternating stack, a memory opening fill structure located in the memory opening, a layer contact via structure vertically extending through a subset of the insulating layers and through a subset of the electrically conductive layers, and in contact with at least a planar annular top surface segment and a cylindrical sidewall of an annular region of a first electrically conductive layer which is a topmost electrically conductive layer of the subset of the electrically conductive layers, and a lower tubular dielectric spacer vertically extending through each of the subset of the insulating layers and each of the subset of the electrically conductive layers except the first electrically conductive layer, and in contact with the layer contact via structure.

### RELATED APPLICATIONS

This application is a continuation-in-part (CIP) application of U.S. application Ser. No. 18/824,214 filed on Sep. 4, 2024, the entire contents of which are incorporated herein by reference.

### FIELD

The present disclosure relates generally to the field of semiconductor devices, and particularly to a three-dimensional memory device including side-contact through-stack contact via structures and methods for forming the same.

### BACKGROUND

A three-dimensional memory device including three-dimensional vertical NAND strings having one bit per cell is disclosed in an article by T. Endoh et al., titled “Novel Ultra High Density Memory With A Stacked-Surrounding Gate Transistor (S-SGT) Structured Cell”, IEDM Proc. (2001) 33-36.

### SUMMARY

According to an aspect of the present disclosure, a device structure is provided, which comprises: an alternating stack of insulating layers and electrically conductive layers; a memory opening vertically extending through each layer within the alternating stack; a memory opening fill structure located in the memory opening and comprising a vertical stack of memory elements and a vertical semiconductor channel; a layer contact via structure vertically extending through a subset of the insulating layers and through a subset of the electrically conductive layers, and in contact with at least a planar annular top surface segment and a cylindrical sidewall of an annular region of a first electrically conductive layer which is a topmost electrically conductive layer of the subset of the electrically conductive layers; and a lower tubular dielectric spacer vertically extending through each of the subset of the insulating layers and each of the subset of the electrically conductive layers except the first electrically conductive layer, and in contact with the layer contact via structure.

According to another aspect of the present disclosure, a method of forming a device structure is provided, which comprises: forming an alternating stack of insulating layers and sacrificial material layers over a substrate; forming memory stack structures through the alternating stack, wherein each of the memory stack structures comprises a respective vertical stack of memory elements located at levels of the sacrificial material layers and a vertical semiconductor channel; forming a contact via cavity through a subset of the sacrificial material layers within the alternating stack and a subset of the insulating layers within the alternating stack; laterally recessing each layer within the subset of the insulating layers and the subset of the sacrificial material layers other than the first sacrificial material layer which is a topmost sacrificial material layer of the subset of the sacrificial material layers by a respective lateral recess distance that is greater than a lateral recess distance for the first sacrificial material layer; depositing a dielectric spacer material layer in a peripheral region of the contact via cavity; patterning the dielectric spacer material layer into a lower dielectric tubular spacer and an upper dielectric tubular spacer; forming a sacrificial via fill structure within a volume that is laterally surrounded by the upper dielectric tubular spacer and the lower dielectric tubular spacer; replacing the sacrificial material layers with electrically conductive layers, wherein the first sacrificial material layer is replaced at least with a first electrically conductive layer; and replacing the sacrificial via fill structure with a layer contact via structure such that the layer contact via structure contacts at least a cylindrical sidewall of the first electrically conductive layer.

According to the first embodiment of the present disclosure, a device structure includes an alternating stack of insulating layers and electrically conductive layers; a memory opening vertically extending through each layer within the alternating stack; a memory opening fill structure located in the memory opening and including a vertical stack of memory elements and a vertical semiconductor channel; and a layer contact via structure vertically extending through a subset of the insulating layers and through a subset of the electrically conductive layers, and in contact with at least cylindrical sidewall of an annular region of a first electrically conductive layer which is a topmost electrically conductive layer of the subset of the electrically conductive layers. The annular region of the first electrically conductive layer has a first thickness; and the first electrically conductive layer also includes an enclosure region that laterally surrounds the annular region and has a second thickness that is greater than the first thickness.

According to another aspect of the present disclosure, a method of forming a device structure is provided, which comprises: forming an alternating stack of insulating layers and sacrificial material layers over a substrate; forming stepped surfaces by patterning the alternating stack in a staircase region; thickening portions of the sacrificial material layers that are physically exposed at the stepped surfaces, wherein each of the sacrificial material layers comprises a respective nominal thickness region and a respective thickened region that are physically exposed in the staircase region; forming memory stack structures through the alternating stack, wherein each of the memory stack structures comprises a respective vertical stack of memory elements located at levels of the sacrificial material layers and a vertical semiconductor channel; forming a contact via cavity through a subset of the sacrificial material layers within the alternating stack and a subset of the insulating layers within the alternating stack, wherein a topmost layer among the subset of the sacrificial material layers comprises a first sacrificial material layer having a first thickened region through which the contact via cavity vertically extends; laterally recessing the subset of the insulating layers around the contact via cavity by performing a first isotropic etch process; isotropically etching the subset of the sacrificial material layers around the contact via cavity by performing a second isotropic etch process, wherein a remaining portion of the first thickened region comprises an annular thinned region that is laterally surrounded by an enclosure region which comprises a portion of the first thickened region that is not thinned by the second isotropic etch process; replacing the sacrificial material layers with at least electrically conductive layers, wherein the first sacrificial material layer is replaced at least with a first electrically conductive layer; and forming a contact via structure in the contact via cavity such that the contact via structure contacts at least a cylindrical sidewall of the first electrically conductive layer.

### BRIEF DESCRIPTION OF THE DRAWINGS

FIG. 1A is a plan view of a configuration of an exemplary semiconductor die including multiple three-dimensional memory array regions according to the first embodiment of the present disclosure. FIG. 1B is a schematic see-through top-down view of region M1 of FIG. 1A. FIG. 1C is a schematic vertical cross-sectional view of a region of the exemplary semiconductor die along the vertical plane C-C′ of FIG. 1B. The vertical plane E-E′ is the cut plane of the schematic vertical cross-sectional view of FIG. 1E. FIG. 1D is a schematic vertical cross-sectional view of a region of the exemplary semiconductor die along the vertical plane D-D′ of FIG. 1B. FIG. 1E is a schematic vertical cross-sectional view of a region of the exemplary semiconductor die along the vertical plane E-E′ of FIG. 1B. The vertical plane C-C′ is the cut plane of the schematic vertical cross-sectional view of FIG. 1C.

FIG. 2A is a schematic vertical cross-sectional view of a first exemplary structure for forming a semiconductor die after formation of a vertically alternating sequence of first-tier continuous insulating layers and first-tier continuous sacrificial material layers, and a first-tier stepped cavity according to a first embodiment of the present disclosure. FIG. 2B is a schematic vertical cross-sectional view of the first exemplary structure along the vertical plane B-B′ of FIG. 2A. The vertical plane A-A′ is the cut plane of the vertical cross-sectional view of FIG. 2A. FIG. 2C is a magnified view of a region of the first exemplary structure around a portion of a first-tier stepped cavity in FIG. 2B.

FIGS. 3A and 3B are sequential vertical cross-sectional views of a region of the first exemplary structure during thickening of physically-exposed portions of the first-tier sacrificial material layers according to the first embodiment of the present disclosure. FIG. 3C is a top-down view a region of the first exemplary structure after the processing steps of FIG. 3B according to the first embodiment of the present disclosure. FIGS. 3D and 3E are sequential vertical cross-sectional views of a region of the first exemplary structure during thickening of physically-exposed portions of the first-tier sacrificial material layers according to an alternative embodiment of the present disclosure.

FIG. 4A is a schematic vertical cross-sectional view of the first exemplary structure after formation of a first-tier retro-stepped dielectric material portion according to the first embodiment of the present disclosure. FIG. 4B is a schematic vertical cross-sectional view of the first exemplary structure along the vertical plane B-B′ of FIG. 4A. The vertical plane A-A′ is the cut plane of the vertical cross-sectional view of FIG. 4A. FIG. 4C is a magnified view of a region of the first exemplary structure around a thickened portion of a first-tier sacrificial material layer in FIG. 4B.

FIG. 5A is a schematic vertical cross-sectional view of the first exemplary structure after formation of various first-tier openings and various first-tier sacrificial opening fill structures according to the first embodiment of the present disclosure. FIG. 5B is a schematic vertical cross-sectional view of the first exemplary structure along the vertical plane B-B′ of FIG. 5A. The vertical plane A-A′ is the cut plane of the vertical cross-sectional view of FIG. 5A.

FIG. 6A is a schematic vertical cross-sectional view of the first exemplary structure after formation of a vertically alternating sequence of second-tier continuous insulating layers and second-tier continuous sacrificial material layers, a second-tier stepped cavity, and a second-tier retro-stepped dielectric material portion according to the first embodiment of the present disclosure. FIG. 6B is a schematic vertical cross-sectional view of the first exemplary structure along the vertical plane B-B′ of FIG. 6A. The vertical plane A-A′ is the cut plane of the vertical cross-sectional view of FIG. 6A. FIG. 6C is a see-through top-down view a region of the first exemplary structure of FIGS. 6A and 6B.

FIG. 7A is a schematic vertical cross-sectional view of the first exemplary structure after formation of various second-tier openings and various second-tier sacrificial opening fill structures according to the first embodiment of the present disclosure. FIG. 7B is a schematic vertical cross-sectional view of the first exemplary structure along the vertical plane B-B′ of FIG. 7A. The vertical plane A-A′ is the cut plane of the vertical cross-sectional view of FIG. 7A.

FIG. 8A is a schematic vertical cross-sectional view of the first exemplary structure after formation of a vertically alternating sequence of third-tier continuous insulating layers and third-tier continuous sacrificial material layers, a third-tier stepped cavity, and a third-tier retro-stepped dielectric material portion according to the first embodiment of the present disclosure.

FIG. 8B is a schematic vertical cross-sectional view of the first exemplary structure along the vertical plane B-B′ of FIG. 8A. The vertical plane A-A′ is the cut plane of the vertical cross-sectional view of FIG. 8A.

FIG. 9A is a schematic vertical cross-sectional view of the first exemplary structure after formation of various third-tier openings and various third-tier sacrificial opening fill structures according to the first embodiment of the present disclosure. FIG. 9B is a schematic vertical cross-sectional view of the first exemplary structure along the vertical plane B-B′ of FIG. 9A. The vertical plane A-A′ is the cut plane of the vertical cross-sectional view of FIG. 9A.

FIG. 10 is a schematic vertical cross-sectional view of the first exemplary structure after removal of sacrificial support opening fill structures according to the first embodiment of the present disclosure.

FIG. 11 is a schematic vertical cross-sectional view of the first exemplary structure after formation of support pillar structures according to the first embodiment of the present disclosure.

FIG. 12 is a schematic vertical cross-sectional view of the first exemplary structure after formation of memory opening according to the first embodiment of the present disclosure.

FIGS. 13A-13F illustrate sequential vertical cross-sectional views of a memory opening during formation of a memory opening fill structure according to the first embodiment of the present disclosure.

FIG. 14A is a schematic vertical cross-sectional view of the first exemplary structure after formation of memory opening fill structures according to the first embodiment of the present disclosure. FIG. 14B is a schematic vertical cross-sectional view of the first exemplary structure along the vertical plane B-B′ of FIG. 14A. The vertical plane A-A′ is the cut plane of the vertical cross-sectional view of FIG. 14A. FIG. 14C is a magnified view of a region of the first exemplary structure around a thickened portion of a first-tier sacrificial material layer in FIG. 14B.

FIG. 15A is a schematic vertical cross-sectional view of the first exemplary structure after formation of a contact-level dielectric layer and contact via cavities according to the first embodiment of the present disclosure. FIG. 15B is a schematic vertical cross-sectional view of the first exemplary structure along the vertical plane B-B′ of FIG. 15A. The vertical plane A-A′ is the cut plane of the vertical cross-sectional view of FIG. 15A. FIG. 15C is a magnified view of a region of the first exemplary structure around a bottom corner of a first-tier stepped cavity in FIG. 15B.

FIGS. 16A-16D are sequential vertical cross-sectional views of a region of the first exemplary structure during a sequence of processing steps for isotropically recessing the insulating layers and the retro-stepped dielectric material portions, for isotropically recessing the sacrificial material layers, and for formation of tubular dielectric spacers according to the first embodiment of the present disclosure.

FIG. 17A is a schematic vertical cross-sectional view of the first exemplary structure after formation of in-process contact-via-region assemblies according to the first embodiment of the present disclosure. FIG. 17B is a schematic vertical cross-sectional view of the first exemplary structure along the vertical plane B-B′ of FIG. 17A. The vertical plane A-A′ is the cut plane of the vertical cross-sectional view of FIG. 17A. FIG. 17C is a magnified view of a region of the first exemplary structure around an in-process contact-via-region assembly in FIG. 17B.

FIG. 18A is a schematic vertical cross-sectional view of the first exemplary structure after formation of lateral isolation trenches according to the first embodiment of the present disclosure. FIG. 18B is a schematic vertical cross-sectional view of the first exemplary structure along the vertical plane B-B′ of FIG. 18A. The vertical plane A-A′ is the cut plane of the vertical cross-sectional view of FIG. 18A. FIG. 18C is a magnified view of a region of the first exemplary structure around an in-process contact-via-region assembly in FIG. 18B.

FIG. 19A is a schematic vertical cross-sectional view of the first exemplary structure after formation of semiconductor oxide spacer liners and lateral recesses according to the first embodiment of the present disclosure. FIG. 19B is a schematic vertical cross-sectional view of the first exemplary structure along the vertical plane B-B′ of FIG. 19A. The vertical plane A-A′ is the cut plane of the vertical cross-sectional view of FIG. 19A. FIG. 19C is a magnified view of a region of the first exemplary structure around an in-process contact-via-region assembly in FIG. 19B.

FIG. 20A is a schematic vertical cross-sectional view of the first exemplary structure after formation of electrically conductive layers according to the first embodiment of the present disclosure. FIG. 20B is a schematic vertical cross-sectional view of the first exemplary structure along the vertical plane B-B′ of FIG. 20A. The vertical plane A-A′ is the cut plane of the vertical cross-sectional view of FIG. 20A. FIG. 20C is a magnified view of a region of the first exemplary structure around an in-process contact-via-region assembly in FIG. 20B.

FIG. 21A is a schematic vertical cross-sectional view of the first exemplary structure after formation of lateral isolation trench fill structures according to the first embodiment of the present disclosure. FIG. 21B is a schematic vertical cross-sectional view of the first exemplary structure along the vertical plane B-B′ of FIG. 21A. The vertical plane A-A′ is the cut plane of the vertical cross-sectional view of FIG. 21A. FIG. 21C is a magnified view of a region of the first exemplary structure around an in-process contact-via-region assembly in FIG. 21B.

FIG. 22A is a schematic vertical cross-sectional view of the first exemplary structure after removal of the sacrificial via fill structures according to the first embodiment of the present disclosure. FIG. 22B is a schematic vertical cross-sectional view of the first exemplary structure along the vertical plane B-B′ of FIG. 22A. The vertical plane A-A′ is the cut plane of the vertical cross-sectional view of FIG. 22A. FIG. 22C is a magnified view of a region of the first exemplary structure around a contact via cavity in FIG. 22B.

FIG. 23A is a schematic vertical cross-sectional view of the first exemplary structure after formation of layer contact via structures according to the first embodiment of the present disclosure. FIG. 23B is a schematic vertical cross-sectional view of the first exemplary structure along the vertical plane B-B′ of FIG. 23A. The vertical plane A-A′ is the cut plane of the vertical cross-sectional view of FIG. 23A. FIGS. 23C, 23D and 23E are magnified views of a region of the first exemplary structure around a layer contact via structure in FIG. 23B according to alternative embodiments of the present disclosure.

FIG. 24 is a schematic vertical cross-sectional view of the first exemplary structure after formation of a memory die according to the first embodiment of the present disclosure.

FIG. 25 is a schematic vertical cross-sectional view of the first exemplary structure after bonding of the memory die to a logic die according to the first embodiment of the present disclosure.

FIG. 26 is a schematic vertical cross-sectional view of the first exemplary structure after removal of the carrier substrate and formation of source-side structures according to the first embodiment of the present disclosure.

FIG. 27A-27E are sequential vertical cross-sectional views of a region around a contact via cavity during formation of a lower tubular dielectric spacer and an upper tubular dielectric spacer according to a second embodiment of the present disclosure.

FIG. 28A is a schematic vertical cross-sectional view of the second exemplary structure after formation of in-process contact-via-region assemblies according to the second embodiment of the present disclosure. FIG. 28B is a schematic vertical cross-sectional view of the second exemplary structure along the vertical plane B-B′ of FIG. 28A. The vertical plane A-A′ is the cut plane of the vertical cross-sectional view of FIG. 28A. FIG. 28C is a magnified view of a region of the second exemplary structure around an in-process contact-via-region assembly in FIG. 28B.

FIG. 29A is a schematic vertical cross-sectional view of the second exemplary structure after formation of lateral isolation trenches according to the second embodiment of the present disclosure. FIG. 29B is a schematic vertical cross-sectional view of the second exemplary structure along the vertical plane B-B′ of FIG. 29A. The vertical plane A-A′ is the cut plane of the vertical cross-sectional view of FIG. 29A. FIG. 29C is a magnified view of a region of the second exemplary structure around an in-process contact-via-region assembly in FIG. 29B.

FIG. 30A is a schematic vertical cross-sectional view of the second exemplary structure after formation of semiconductor oxide spacer liners and lateral recesses according to the second embodiment of the present disclosure. FIG. 30B is a schematic vertical cross-sectional view of the second exemplary structure along the vertical plane B-B′ of FIG. 30A. The vertical plane A-A′ is the cut plane of the vertical cross-sectional view of FIG. 30A. FIG. 30C is a magnified view of a region of the second exemplary structure around an in-process contact-via-region assembly in FIG. 30B.

FIG. 31A is a schematic vertical cross-sectional view of the second exemplary structure after formation of electrically conductive layers according to the second embodiment of the present disclosure. FIG. 31B is a schematic vertical cross-sectional view of the second exemplary structure along the vertical plane B-B′ of FIG. 31A. The vertical plane A-A′ is the cut plane of the vertical cross-sectional view of FIG. 31A. FIG. 31C is a magnified view of a region of the second exemplary structure around an in-process contact-via-region assembly in FIG. 31B.

FIG. 32A is a schematic vertical cross-sectional view of the second exemplary structure after formation of lateral isolation trench fill structures according to the second embodiment of the present disclosure. FIG. 32B is a schematic vertical cross-sectional view of the second exemplary structure along the vertical plane B-B′ of FIG. 32A. The vertical plane A-A′ is the cut plane of the vertical cross-sectional view of FIG. 32A. FIG. 32C is a magnified view of a region of the second exemplary structure around an in-process contact-via-region assembly in FIG. 32B.

FIG. 33A is a schematic vertical cross-sectional view of the second exemplary structure after removal of the sacrificial via fill structures according to the second embodiment of the present disclosure. FIG. 33B is a schematic vertical cross-sectional view of the second exemplary structure along the vertical plane B-B′ of FIG. 33A. The vertical plane A-A′ is the cut plane of the vertical cross-sectional view of FIG. 33A. FIG. 33C is a magnified view of a region of the second exemplary structure around a contact via cavity in FIG. 33B.

FIG. 34 is a magnified view of a region of the second exemplary structure around a contact via cavity after removing physically exposed portions of the backside blocking dielectric layers according to the second embodiment of the present disclosure.

FIG. 35A is a schematic vertical cross-sectional view of the second exemplary structure after formation of layer contact via structures according to the second embodiment of the present disclosure. FIG. 35B is a schematic vertical cross-sectional view of the second exemplary structure along the vertical plane B-B′ of FIG. 35A. The vertical plane A-A′ is the cut plane of the vertical cross-sectional view of FIG. 35A. FIG. 35C is a magnified view of a region of the second exemplary structure around a layer contact via structure in FIG. 35B.

FIG. 36 is a schematic vertical cross-sectional view of the second exemplary structure after formation of a memory die according to the second embodiment of the present disclosure.

FIG. 37 is a schematic vertical cross-sectional view of the second exemplary structure after bonding of the memory die to a logic die according to the second embodiment of the present disclosure.

FIG. 38 is a schematic vertical cross-sectional view of the second exemplary structure after removal of the carrier substrate and formation of source-side structures according to the second embodiment of the present disclosure.

### DETAILED DESCRIPTION

As discussed above, embodiments of the present disclosure are directed to a three-dimensional memory device including side-contact through-stack contact via structures and methods for forming the same, the various aspects of which are now described in detail.

The drawings are not drawn to scale. Multiple instances of an element may be duplicated where a single instance of the element is illustrated, unless absence of duplication of elements is expressly described or clearly indicated otherwise. Ordinals such as “first,” “second,” and “third” are employed merely to identify similar elements, and different ordinals may be employed across the specification and the claims of the instant disclosure. The term “at least one” element refers to all possibilities including the possibility of a single element and the possibility of multiple elements. The same reference numerals refer to the same element or similar element. Unless otherwise indicated, elements having the same reference numerals are presumed to have the same composition and the same function. Unless otherwise indicated, a “contact” between elements refers to a direct contact between elements that provides an edge or a surface shared by the elements. If two or more elements are not in direct contact with each other or from each other, the two elements are “disjoined from” each other or “disjoined among” one another. As used herein, a first element located “on” a second element can be located on the exterior side of a surface of the second element or on the interior side of the second element. As used herein, a first element is located “directly on” a second element if there exist a physical contact between a surface of the first element and a surface of the second element. As used herein, a first element is “electrically connected to” a second element if there exists a conductive path consisting of at least one conductive material between the first element and the second element. As used herein, a “prototype” structure or an “in-process” structure refers to a transient structure that is subsequently modified in the shape or composition of at least one component therein.

As used herein, a “layer” refers to a material portion including a region having a thickness. A layer may extend over the entirety of an underlying or overlying structure, or may have an extent less than the extent of an underlying or overlying structure. Further, a layer may be a region of a homogeneous or inhomogeneous continuous structure that has a thickness less than the thickness of the first continuous structure. For example, a layer may be located between any pair of horizontal planes between, or at, a top surface and a bottom surface of the first continuous structure. A layer may extend horizontally, vertically, and/or along a tapered surface. A substrate may be a layer, may include one or more layers therein, or may have one or more layer thereupon, thereabove, and/or therebelow.

As used herein, a surface of a structural element has a “convex profile” in a cross-sectional view if the surface is contoured such that a center of curvature of a curved segment of the surface is located on a side of the structural element relative to the surface of the structural element in the cross-sectional view. As used herein, a surface of a structural element has a “concave profile” in a cross-sectional view if the surface is contoured such that a center of curvature of a curved segment of the surface is located on an opposite side of the structural element relative to the surface of the structural element in the cross-sectional view. As used herein, a surface of a structural element is a “convex surface” if the surface has a convex profile in a cross-sectional view. A surface is a “vertically-convex surface” if the surface has a convex profile in a vertical cross-sectional view. A surface is a “vertically-concave surface” if the surface has a convex profile in a vertical cross-sectional view. A surface is a “vertically-straight surface” if the surface has no curvature in a vertical cross-sectional view. A surface is a “horizontally-convex surface” if the surface has a convex profile in a horizontal cross-sectional view. A surface is a “horizontally-concave surface” if the surface has a concave profile in a vertical cross-sectional view. A surface is a “horizontally-straight surface” if the surface has no curvature in a horizontal cross-sectional view. Generally, convexity or concavity in a vertical cross-sectional view is independent of convexity or concavity in a horizontal cross-sectional view.

As used herein, a first surface and a second surface are “vertically coincident” with each other if the second surface overlies or underlies the first surface and there exists a vertical plane or a substantially vertical plane that includes the first surface and the second surface. A substantially vertical plane is a plane that extends straight along a direction that deviates from a vertical direction by an angle less than 5 degrees. A vertical plane or a substantially vertical plane is straight along a vertical direction or a substantially vertical direction, and may, or may not, include a curvature along a direction that is perpendicular to the vertical direction or the substantially vertical direction.

As used herein, a “memory level” or a “memory array level” refers to the level corresponding to a general region between a first horizontal plane (i.e., a plane parallel to the top surface of the substrate) including topmost surfaces of an array of memory elements and a second horizontal plane including bottommost surfaces of the array of memory elements. As used herein, a “through-stack” element refers to an element that vertically extends through a memory level.

As used herein, a “semiconducting material” refers to a material having electrical conductivity in the range from 1.0×10⁵ S/m to 1.0×10⁵ S/m. As used herein, a “semiconductor material” refers to a material having electrical conductivity in the range from 1.0×10⁻⁵ S/m to 1.0 S/m in the absence of electrical dopants therein, and is capable of producing a doped material having electrical conductivity in a range from 1.0 S/m to 1.0×10⁷ S/m upon suitable doping with an electrical dopant. As used herein, an “electrical dopant” refers to a p-type dopant that adds a hole to a valence band within a band structure, or an n-type dopant that adds an electron to a conduction band within a band structure. As used herein, a “conductive material” refers to a material having electrical conductivity greater than 1.0×10⁵ S/m. As used herein, an “insulator material” or a “dielectric material” refers to a material having electrical conductivity less than 1.0×10⁻⁵ S/m. As used herein, a “heavily doped semiconductor material” refers to a semiconductor material that is doped with electrical dopant at a sufficiently high atomic concentration to become a conductive material either as formed as a crystalline material or if converted into a crystalline material through an anneal process (for example, from an initial amorphous state), i.e., to provide electrical conductivity greater than 1.0×10⁵ S/m. A “doped semiconductor material” may be a heavily doped semiconductor material, or may be a semiconductor material that includes electrical dopants (i.e., p-type dopants and/or n-type dopants) at a concentration that provides electrical conductivity in the range from 1.0×10⁻⁵ S/m to 1.0×10⁷ S/m. An “intrinsic semiconductor material” refers to a semiconductor material that is not doped with electrical dopants. Thus, a semiconductor material may be semiconducting or conductive, and may be an intrinsic semiconductor material or a doped semiconductor material. A doped semiconductor material may be semiconducting or conductive depending on the atomic concentration of electrical dopants therein. As used herein, a “metallic material” refers to a conductive material including at least one metallic element therein. All measurements for electrical conductivities are made at the standard condition.

Generally, a semiconductor package (or a “package”) refers to a unit semiconductor device that may be attached to a circuit board through a set of pins or solder balls. A semiconductor package may include a semiconductor chip (or a “chip”) or a plurality of semiconductor chips that are bonded throughout, for example, by flip-chip bonding or another chip-to-chip bonding. A package or a chip may include a single semiconductor die (or a “die”) or a plurality of semiconductor dies. A die is the smallest unit that may independently execute external commands or report status. Typically, a package or a chip with multiple dies is capable of simultaneously executing as many number of external commands as the total number of dies therein. Each die includes one or more planes. Identical concurrent operations may be executed in each plane within a same die, although there may be some restrictions. In case a die is a memory die, i.e., a die including memory elements, concurrent read operations, concurrent write operations, or concurrent erase operations may be performed in each plane within a same memory die. In a memory die, each plane contains a number of memory blocks (or “blocks”), which are the smallest unit that may be erased by in a single erase operation. Each memory block contains a number of pages, which are the smallest units that may be selected for programming. A page is also the smallest unit that may be selected to a read operation.

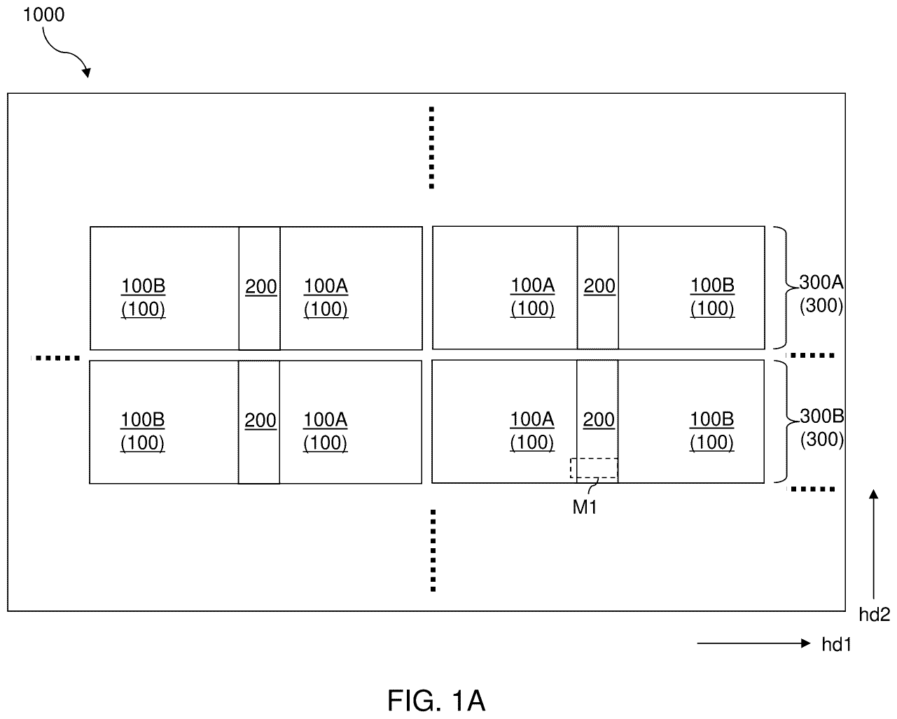

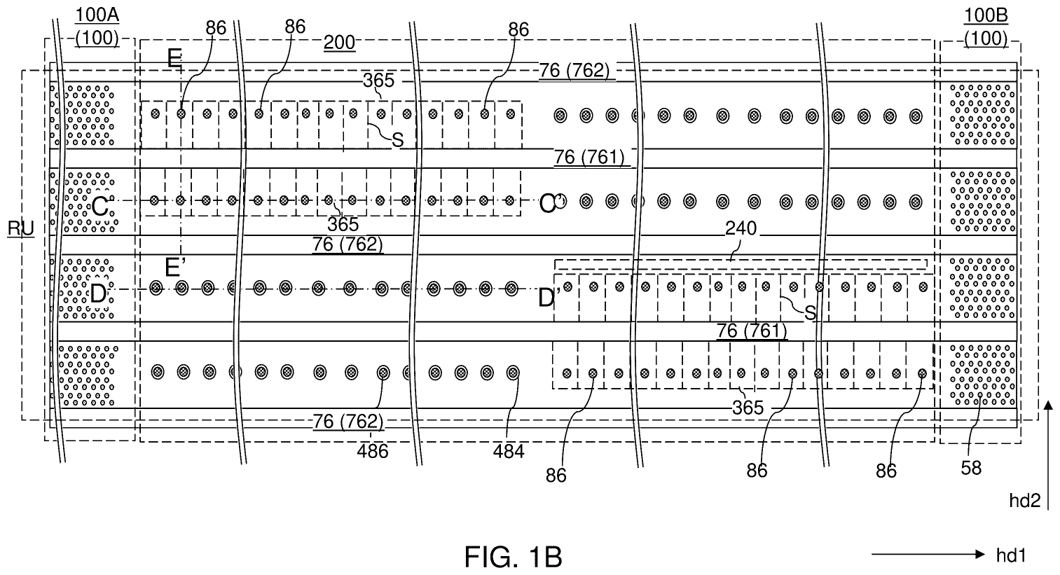

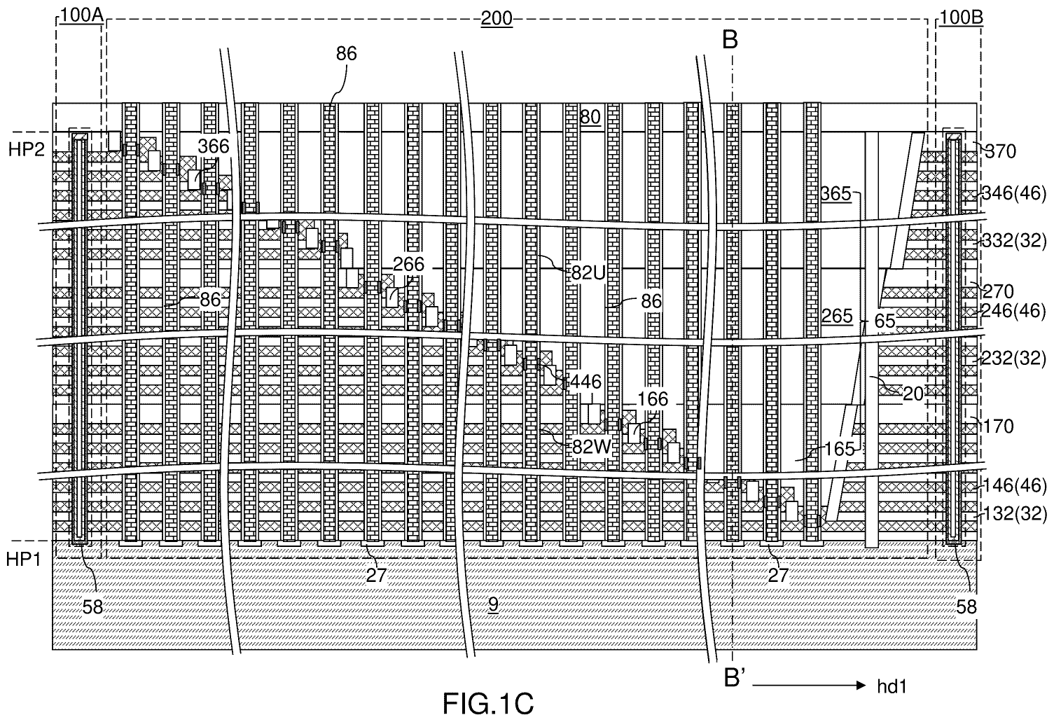

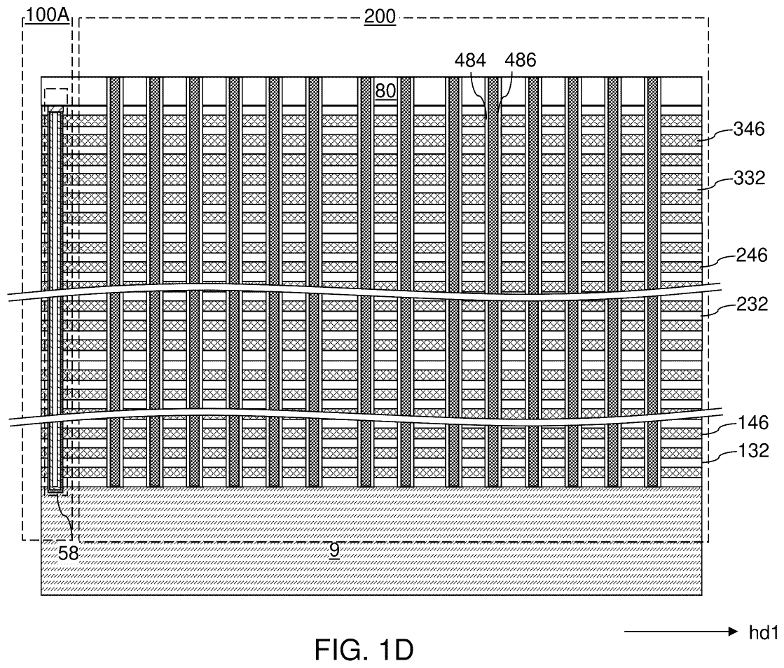

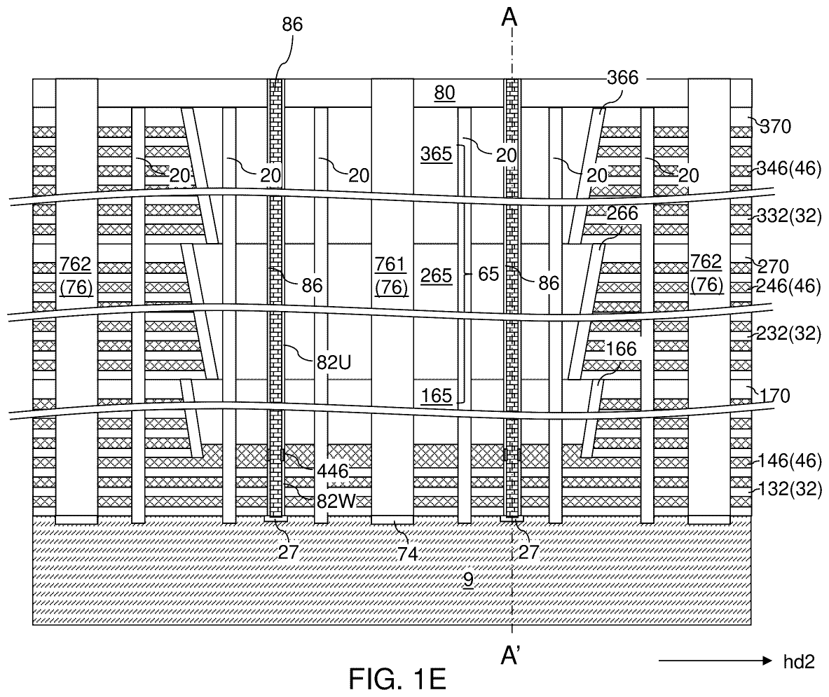

Referring to FIGS. 1A-1E, an exemplary semiconductor die 1000 according to the first embodiment of the present disclosure is illustrated. The exemplary semiconductor die 1000 comprises a substrate 9, which may be a semiconductor substrate and/or a carrier substrate. For example, the substrate 9 may comprise a commercially available silicon wafer. If the substrate 9 comprises a carrier substrate, the substrate 9 may comprise any material that may be removed selectively to the materials of overlying structures to be subsequently formed. The exemplary semiconductor die 1000 is illustrated after a set of processing steps that forms various contact via structures (86, 88), which include layer contact via structures 86 and drain contact via structures 88. The exemplary semiconductor die 1000 illustrates an exemplary layout and configuration of the various device structures of the present disclosure that are subsequently described. However, the layout and the configuration of the exemplary semiconductor die 1000 in FIGS. 1A-1E are only illustrative, and do not limit the general layout and/or configurations of embodiments of the present disclosure.

The exemplary semiconductor die 1000 includes multiple three-dimensional memory array regions and multiple inter-array regions. The exemplary semiconductor die 1000 can include multiple planes 300 (such as a first plane 300A and a second plane 300B, etc.), each of which includes two memory array regions 100, such as a first memory array region 100A and a second memory array region 100B that are laterally spaced apart by a respective inter-array region 200. Generally, a semiconductor die 1000 may include a single plane 300 or multiple planes. The total number of planes in the semiconductor die 1000 may be selected based on performance requirements on the semiconductor die 1000. A pair of memory array regions 100 in a plane 300 may be laterally spaced apart along a first horizontal direction hd1 (which may be the word line direction). A second horizontal direction hd2 (which may be the bit line direction) can be perpendicular to the first horizontal direction hd1.

The size of the first memory array region 100A may be the same as, or may differ from, the size of the second memory array region 100B within a given plane. In one embodiment, each of the first memory array region 100A and the second memory array region 100B may have a respective rectangular area having a same width along the second horizontal direction hd2. In one embodiment, the inter-array region 200 within each plane 300 can be located off-center of the respective plane 300 along the first horizontal direction hd1 (i.e., the inter-array region 200 is located closer to one end than to another end of the respective plane 300). For example, the inter-array region 200 in the left plane 300A may be shifted toward the left edge of the die 1000, while the inter-array region 200 in the right plane 300B may be shifted toward the right edge of the die 1000. Alternatively, the inter-array region 200 within each plane 300 can be centered in the respective plane 300 along the first horizontal direction hd1 (i.e., the inter-array region 200 is located the same distance from both ends of the respective plane 300).

Each memory array region 100 includes first-tier alternating stacks of first-tier insulating layers 132 and first-tier electrically conductive layers 146 (which function as first word lines), optional second-tier alternating stacks of second-tier insulating layers 232 and second-tier electrically conductive layers 246 (which function as second word lines), and optional third-tier alternating stacks of third-tier insulating layers 332 and third-tier electrically conductive layers 346 (which function as third word lines). Each second-tier alternating stack (232, 246) overlies a respective first-tier alternating stack (132, 146), and each third-tier alternating stack (332, 346), if present, overlies a respective second-tier alternating stack (232, 246). Each combination of a first-tier alternating stack (132, 146), an overlying second-tier alternating stack (232, 246), and an optional overlying third-tier alternating stack (332, 346) may be laterally spaced apart from neighboring combinations of a respective first-tier alternating stack (132, 146), an overlying respective second-tier alternating stack (232, 246), and an overlying optional third-tier alternating stack (332, 346) by lateral isolation trench fill structures 76 that laterally extend along the first horizontal direction hd1 (which may be a word line direction). The first-tier insulating layers 132, the second-tier insulating layers 232, and the third-tier insulating layers 332 are collectively referred to as insulating layers 32. The first-tier electrically conductive layers 146, the second-tier electrically conductive layers 246, and the third-tier electrically conductive layers 346 are collectively referred to as electrically conductive layers 46.

As used herein, a “first-tier level” refers to the tier level that is most proximal to a substrate, a “second-tier level” refers to the tier level that is most proximal to the substrate among tier levels that overlie the first-tier level, and a “third-tier level” refers to the tier level that is most proximal to the substrate among tier levels that overlie the second-tier level, etc. A “first-tier” element refers to an element that is located within the first-tier level; a “second-tier” element refers to an element that is located within the second-tier level; a “third-tier” element refers to an element that is located within the second-tier level; etc. Individual tier levels within a structure including multiple tier levels may be labeled as a first tier level, a second tier level, a third tier level, etc. In this case, the first tier level may be any of the multiple tier levels, the second tier level may be a tier level that is different from the first tier level, etc.

A first-tier alternating stack of first-tier insulating layers 132 and first-tier electrically conductive layers 146 is located over the substrate 9 between each neighboring pair of lateral isolation trench fill structures 76. A first-tier retro-stepped dielectric material portion 165 overlies, and contacts, first stepped surfaces of the first-tier alternating stack (132, 146). A second-tier alternating stack of second-tier insulating layers 232 and second-tier electrically conductive layers 246 overlies the first-tier alternating stack (132, 146), and overlies a horizontal plane including a planar top surface of the first-tier retro-stepped dielectric material portion 165 between each neighboring pair of lateral isolation trench fill structures 76. A second-tier retro-stepped dielectric material portion 265 overlies, and contacts, second stepped surfaces of the second-tier alternating stack (232, 246). A third-tier alternating stack of third-tier insulating layers 332 and third-tier electrically conductive layers 346, if present, overlies the second-tier alternating stack (232, 246), and overlies a horizontal plane including a planar top surface of the second-tier retro-stepped dielectric material portion 265 between each neighboring pair of lateral isolation trench fill structures 76. A third-tier retro-stepped dielectric material portion 365 overlies, and contacts, third stepped surfaces of the third-tier alternating stack (332, 346), if present. Vertical steps S of the first stepped surfaces and the second stepped surfaces laterally extend along the second horizontal direction hd2 (which may be a bit line direction). The first-tier retro-stepped dielectric material portion 165, the second-tier retro-stepped dielectric material portion 265, and the third-tier retro-stepped dielectric material portion 365 are collectively referred to as retro-stepped dielectric material portions 65.

Memory opening fill structures 58 can be located within each memory array region 100 (which includes a first memory array region 100A and a second memory array region 100B) between each neighboring pair of lateral isolation trench fill structures 76. The memory opening fill structures 58 can be located within memory openings that vertically extend through each layer within the first-tier alternating stack (132, 146), the second-tier alternating stack (232, 246), and the optional third-tier alternating stack (332, 346), if present, which are located between a respective neighboring pair of lateral isolation trench fill structures 76.

In one embodiment, each of the memory opening fill structures 58 comprises a vertical stack of memory elements (e.g., portions of a memory film or vertically separated, discrete memory elements) located at levels of the electrically conductive layers 46 and a vertical semiconductor channel 60 that is electrically connected to a respective overlying metal interconnect structure (such as a bit line). In one embodiment, the inter-array region 200 is free of any memory stack structure that is electrically contacted by any metal interconnect structure (such as a bit line).

Each memory opening fill structure 58 includes a respective memory stack structure, which includes a respective memory film and a respective vertical semiconductor channel. The memory openings and the memory opening fill structures 58 are formed in region in which each layer of a first-tier alternating stack and each layer of the second-tier alternating stack are present. For each area within which a continuous combination of a first-tier alternating stack (132, 146), a second-tier alternating stack (232, 246), and an optional third-tier alternating stack (332, 346) continuously laterally extends, first memory stack structures can be located within a respective first memory array region 100A and second memory stack structures can be located within a respective second memory array region 100B. The second memory array region 100B can be connected to the first memory array region 100A through a respective inter-array region 200, in which a first-tier retro-stepped dielectric material portion 165, a second-tier retro-stepped dielectric material portion 265, and an optional third-tier retro-stepped dielectric material portion 365 are located.

A first-tier retro-stepped dielectric material portion 165 can be located between each neighboring pair of lateral isolation trench fill structures 76. Each first-tier retro-stepped dielectric material portion 165 overlies first stepped surfaces of a respective first-tier alternating stack (132, 146). Each first-tier retro-stepped dielectric material portion 165 can have a sidewall that laterally extends along the first horizontal direction hd1 and contacts a respective lateral isolation trench fill structure 76. The first stepped surfaces comprise vertical steps of the first-tier alternating stack (132, 146) that are laterally spaced apart along the first horizontal direction hd1 and vertically offset from each other.

A second-tier retro-stepped dielectric material portion 265 can be located between each neighboring pair of lateral isolation trench fill structures 76. Each second-tier retro-stepped dielectric material portion 265 overlies second stepped surfaces of a respective second-tier alternating stack (232, 246). Each second-tier retro-stepped dielectric material portion 265 can have a sidewall that laterally extends along the second horizontal direction hd1 and contacts a respective lateral isolation trench fill structure 76. The second stepped surfaces comprise vertical steps of the second-tier alternating stack (232, 246) that are laterally spaced apart along the first horizontal direction hd1 and vertically offset from each other. In one embodiment, each second-tier retro-stepped dielectric material portion 265 overlies, and contacts, a respective one of the first-tier retro-stepped dielectric material portions 165.

A third-tier retro-stepped dielectric material portion 365 can be located between each neighboring pair of lateral isolation trench fill structures 76. Each third-tier retro-stepped dielectric material portion 365 overlies third stepped surfaces of a respective third-tier alternating stack (332, 346). Each third-tier retro-stepped dielectric material portion 365 can have a sidewall that laterally extends along the second horizontal direction hd2 and contacts a respective lateral isolation trench fill structure 76. The third stepped surfaces comprise vertical steps of the third-tier alternating stack (332, 346) that are laterally spaced apart along the second horizontal direction hd2 and vertically offset from each other. In one embodiment, each third-tier retro-stepped dielectric material portion 365 overlies, and contacts, a respective one of the second-tier retro-stepped dielectric material portions 265.

Lateral isolation trenches can laterally extend along the first horizontal direction hd1. Each lateral isolation trench can be filled with a lateral isolation trench fill structure 76, which may include a combination of a backside contact via structure and an insulating spacer that laterally surround the backside contact via structure. Alternatively, each lateral isolation trench fill structure 76 may consist of an insulating fill structure. Each vertical stack of a first-tier alternating stack (132, 146), a second-tier alternating stack (232, 246), and an optional third-tier alternating stack (332, 346) can be located between a neighboring pair of lateral isolation trench fill structure 76.

Generally, at least the first-tier alternating stack (132, 146) can be formed, and the second-tier alternating stack (232, 246) and/or the third-tier alternating stack (332, 346) may be formed above the first-tier alternating stack (132, 146). The set of all alternating stack(s) in the first exemplary structure may be referred to as at least one alternating stack (32, 46). In one embodiment, each of the electrically conductive layers 46 except the topmost electrically conductive layer 46 may have a first thickness in each area that underlies any other electrically conductive layer 46, and may optionally be locally thickened in each area that does not underlie any other electrically conductive layer 46 to provide a respective locally thickened region having a second thickness. The topmost electrically conductive layer 46 may have the second thickness only within the areas of the stepped surfaces in a top-down view.

A contact-level dielectric layer 80 can be formed over the at least one alternating stack (32, 46). In one embodiment, layer contact via structures 86 vertically extend through a respective subset of the at least one retro-stepped dielectric material portion 65 (which may be a plurality of retro-stepped dielectric material portions 65), through a thickened portion of a respective electrically conductive layer 46, and through underlying electrically conductive layers 46. Each such layer contact via structure 86 can contact a cylindrical sidewall of the optionally thickened portion of the respective electrically conductive layer 46, and can be electrically isolated from at least one of the underlying electrically conductive layers by a lower tubular dielectric spacer 82W. The optional thickened portions of the electrically conductive layers 46 can be formed by locally thickening sacrificial material layers, and by replacing the sacrificial material layers, during which the electrically conductive layers are formed with local thickening at locations at which the sacrificial material layers are previously thickened. Formation of the lower tubular dielectric spacers 82W and formation of the layer contact via structures 86 in a manner that provides direct contact with cylindrical sidewalls of openings through the electrically conductive layers 46 are described in detail in subsequent sections of the present disclosure. Each layer contact via structure 86 may be laterally surrounded by a respective upper tubular dielectric spacer 82U and a respective lower tubular dielectric spacer 82W, and may be contacted by an annular thinned region of a respective one of the electrically conductive layers 46.

The inter-array region 200 includes strips of the first-tier insulating layers 132, the first-tier electrically conductive layers 146, the second-tier insulating layers 232, the second-tier electrically conductive layers 246, the third-tier insulating layers 332, and the third-tier electrically conductive layers 346 located between each laterally neighboring pair of lateral isolation trench fill structures 76. Such strips are located in a respective strip-shaped connection regions 240 (i.e., bridge regions) of the inter-array regions 200, which are located adjacent to a respective first-tier retro-stepped dielectric material portion 165, a respective second-tier retro-stepped dielectric material portion 265, or a respective third-tier retro-stepped dielectric material portions 365. The strips have a narrower width along the second horizontal direction hd2 than portions of the alternating stacks (132, 146, 232, 246, 332, 346) located in the memory array regions 100, and portions of the strips located in the remaining portions of the inter-array regions 200 outside of the respective strip-shaped connection regions 240.

For each vertical stack of a first-tier alternating stack (132, 146), a second-tier alternating stack (232, 246), and an optional third-tier alternating stack (332, 346), first memory opening fill structures 58 can be located within a first memory array region 100A in which each layer of the first-tier alternating stack (132, 146), the second-tier alternating stack (232, 246), and the optional third-tier alternating stack (332, 346) is present. Further, second memory opening fill structures 58 can be located within a second memory array region 100B that is laterally offset along the first horizontal direction hd1 from the first memory array region 100A by the first-tier retro-stepped dielectric material portion 165, the second-tier retro-stepped dielectric material portion 265, and the optional third-tier retro-stepped dielectric material portion 365. Each layer of the first-tier alternating stack (132, 146), the second-tier alternating stack (232, 246), and the optional third-tier alternating stack (332, 346) is present within the second memory array region 100B. Each of the electrically conductive layers 46 within the vertical stack may continuously extend from the first memory array region 100A to the second memory array region 100B through a strip-shaped connection region 240 (which is also referred to as a bridge region). Each strip-shaped connection region 240 is located within an inter-array region 200, and may be located between the lateral isolation trench fill structure 76 and the first-tier retro-stepped dielectric material portion 165 at the level of the first-tier alternating stack (132, 146), or between a lateral isolation trench fill structures 76 and the second-tier retro-stepped dielectric material portion 265 at the level of the second-tier alternating stack (232, 246), or between a lateral isolation trench fill structures 76 and the third-tier retro-stepped dielectric material portion 365 at the level of the third-tier alternating stack (332, 346).

Staircases including first stepped surfaces of a first-tier alternating stack (132, 146), optionally second stepped surfaces of a second-tier alternating stack (232, 246), and optionally third stepped surfaces of a third-tier alternating stack (332, 346) can ascend (i.e., rise) from the substrate along the first horizontal direction hd1, or along the opposite direction of the first horizontal direction hd1. Each region including the staircases is herein referred to as a staircase region. In one embodiment, the direction of rise of the staircases can change for every other pair of vertical stacks of a respective first-tier alternating stack (132, 146), a respective second-tier alternating stack (232, 246), and a respective third-tier alternating stack (332, 346). In other words, the direction of rise is staggered in adjacent alternating stacks that are separated along the second horizontal direction

Optional laterally-isolated vertical interconnection structures (484, 486) can be formed through the inter-array region 200. Each laterally-isolated vertical interconnection structure (484, 486) can include a through-memory-level conductive via structure 486 and a tubular insulating spacer 484 that laterally surrounds the conductive via structure 486. The laterally-isolated vertical interconnection structures (484, 486) vertically extend through the strip portions of the first-tier alternating stack (132, 146), the second-tier alternating stack (232, 246), and the third-tier alternating stack (332, 346), and can contact the substrate 9. Alternatively, the laterally-isolated vertical interconnection structures (484 and/or 486) are omitted.

Drain contact via structures 88 can contact an upper portion of a respective memory opening fill structure 58 (such as a drain region within the respective memory opening fill structure 58). Bit lines (not illustrated) can laterally extend along the second horizontal direction hd2, and can contact top surfaces of a respective subset of the drain contact via structures. Additional metal interconnect structures embedded in overlying dielectric material layers (not shown) may be employed to provide electrical connection among the various nodes of the three-dimensional memory device located in the semiconductor die 1000.

Each lateral isolation trench fill structure 76 includes an insulating material portion. In one embodiment, each insulating material portion may comprise an insulating spacer that laterally surrounds a layer contact via structure such as a backside contact via structure (not expressly shown). In another embodiment, each insulating material portion may comprise a dielectric wall structure which takes up the entire volume of the respective lateral isolation trench fill structure 76. In one embodiment, each sidewall of the first alternating stacks (132, 146) can be contacted by a sidewall of an insulating material portion of a respective one of the lateral isolation trench fill structures 76.

In one embodiment, each plane 300 within the exemplary semiconductor die 1000 includes a three-dimensional memory device, which includes alternating stacks of insulating layers 32 and electrically conductive layers 46. Each of the alternating stacks {(132, 146), (232, 246), (332, 346)} laterally extends along a first horizontal direction hd1 through a first memory array region 100A and a second memory array region 100B that are laterally spaced apart by an inter-array region 200. Each of the alternating stacks {(132, 146), (232, 246), (332, 346)} includes a set of stepped surfaces (i.e., a staircase) in the inter-array region 200. Each plane 300 within the exemplary semiconductor die 1000 includes retro-stepped dielectric material portions (165, 265, 365) overlying a respective set of stepped surfaces of the alternating stacks {(132, 146), (232, 246), (332, 346)}. Each plane 300 within the exemplary semiconductor die 1000 includes clusters of memory stack structures located within memory opening fill structures 58. Each of the memory stack structures vertically extends through a respective one of the alternating stacks {(132, 146), (232, 246), (332, 346)} and is located within the first memory array region 100A or the second memory array region 100B. Each memory stack structure can include a respective vertical semiconductor channel and a vertical stack of memory elements (e.g., a memory film) located at levels of the electrically conductive layers 46.

Each of the retro-stepped dielectric material portions 65 comprises a respective stepped bottom surface. Each region of the alternating stacks (32, 46) that underlies a respective retro-stepped dielectric material portion 65 constitutes a staircase region. A strip-shaped connection region 240 including each layer within an alternating stack (32, 46) is provided adjacent to each staircase region, and is herein referred to as a bridge region. Each strip-shaped connection region 240 laterally extends along the first horizontal direction hd1, and provides electrically conductive paths between a respective portion located in the first memory array region 100A and a respective portion located in the second memory array region 100B for each electrically conductive layer 46. The strip region has a lesser width (i.e., narrower width along the second horizontal direction hd2) than the portions of the electrically conductive layer 46 located in the first memory array region 100A or in the second memory array region 100B. The portions of the electrically conductive layer 46 located in the first memory array region 100A or in the second memory array region 100B have a width along the second horizontal direction hd2 that is the same as a lateral distance between a neighboring pair of lateral isolation trench fill structures 76.

In contrast, each strip portion of the electrically conductive layer 46 in the strip-shaped connection region 240 has a width along the second horizontal direction hd2 that is the same as the difference between the lateral distance between a neighboring pair of lateral isolation trench fill structures 76 and the width of an adjoining retro-stepped dielectric material portion (165 or 265) along the second horizontal direction hd2. Each electrical connection between a layer contact via structure 86 and a most proximal portion of the second memory array region 100B includes a narrow strip portion of an electrically conductive layer 46 in the strip-shaped connection region 240, while electrical connection between the layer contact via structure 86 and a most proximal portion of the first memory array region 100A does not include any narrow strip portion of the electrically conductive layer 46 because the first memory array region 100A is not separated from the layer contact via structures 86 by the strip-shaped connection region 240.

In one embodiment, the alternating stacks {(132, 146), (232, 246), (332, 346)} are laterally spaced apart along the second horizontal direction hd2 by line trenches (such as lateral isolation trenches) that laterally extend along the first horizontal direction hd1. The line trenches are filled with lateral isolation trench fill structures 76 having dielectric surfaces (such as surfaces of insulating spacers or dielectric wall structures) that contact sidewalls of the alternating stacks {(132, 146), (232, 246), (332, 346)}. In one embodiment, upon sequentially numbering the lateral isolation trench fill structures 76 with positive integers along the second horizontal direction hd2, odd-numbered lateral isolation trench fill structures 76 (e.g., 761) may contact a respective pair of retro-stepped dielectric material portions (165, 265, 365) (which are located on either side of a respective odd-numbered lateral isolation trench fill structure 76), and even-numbered lateral isolation trench fill structures 76 (e.g., 762) do not contact any retro-stepped dielectric material portion (165, 265, 365), or alternatively, even-numbered lateral isolation trench fill structures 76 (e.g., 762) may contact a respective pair of retro-stepped dielectric material portions (165, 265, 365) and odd-numbered lateral isolation trench fill structures 76 (e.g., 761) do not contact any retro-stepped dielectric material portion (165, 265, 365).

In one embodiment, strip widths of the first-tier electrically conductive layers 146 decrease with a respective vertical distance from the substrate 9. Strip widths of the second-tier electrically conductive layers 246 decrease with a respective vertical distance from the substrate 9. Strip widths of the third-tier electrically conductive layers 346 decrease with a respective vertical distance from the substrate 9. A bottommost second electrically conductive layer 246 within the second-tier alternating stack (232, 246) has a greater strip width than a topmost first electrically conductive layer 146 within the first-tier alternating stack (132, 146). A bottommost third electrically conductive layer 346 within the third-tier alternating stack (332, 346) has a greater strip width than a topmost second electrically conductive layer 246 within the second-tier alternating stack (232, 246).

According to an aspect of the present disclosure shown in FIG. 1E, a set of a first-tier retro-stepped dielectric material portion 165, a second-tier retro-stepped dielectric material portion 265, and a third-tier retro-stepped dielectric material portion 365 can be formed between a neighboring pair of lateral isolation trench fill structures 76, which are herein referred to as a first lateral isolation trench fill structure 761 and a second lateral isolation trench fill structure 762. The width of each strip of an electrically conductive layer 46 along the second horizontal direction in the strip-shaped connection region 240 is herein referred to as a strip width or a bridge width. Generally, embedding of the retro-stepped dielectric material portions (165, 265, 365) in alternating stacks of insulating layers 32 and electrically conductive layers 46 may induce cracking due to voids formed in the retro-stepped dielectric material portions (165, 265, 365) and/or due to incline of the alternating stacks into the lateral isolation trenches due to unbalanced electrically conductive layer material filling. While the illustrated configuration of the first exemplary structure illustrated in FIGS. 1A-1E includes three tier levels, embodiments are expressly contemplated herein in which one tier level, two tier levels, or four or more tier levels are used in an alternative configuration.

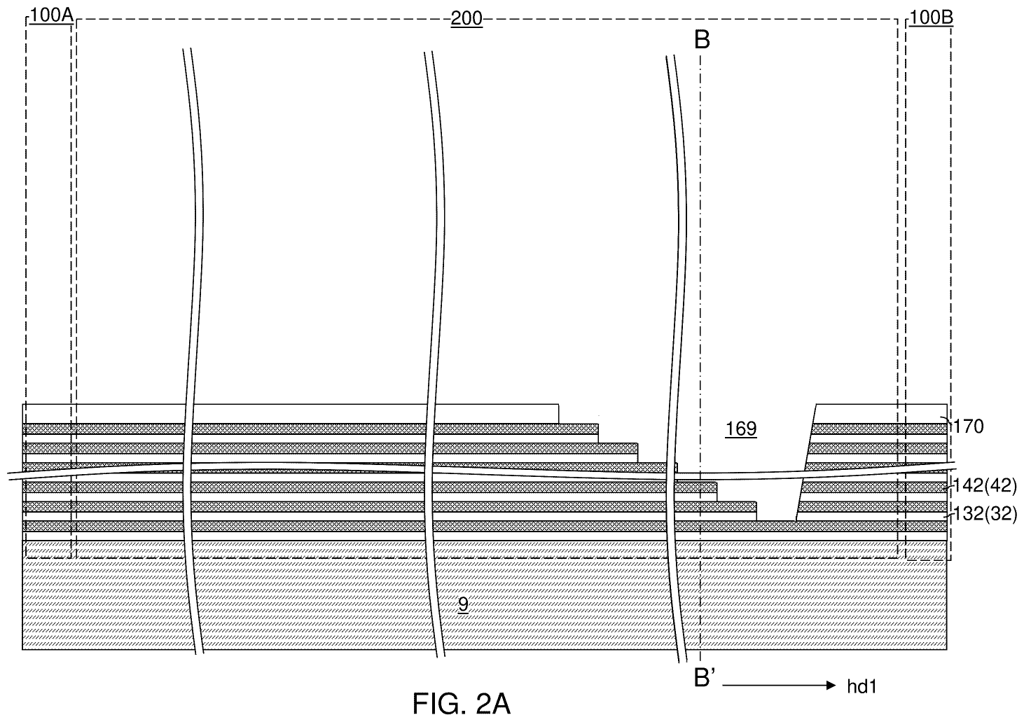

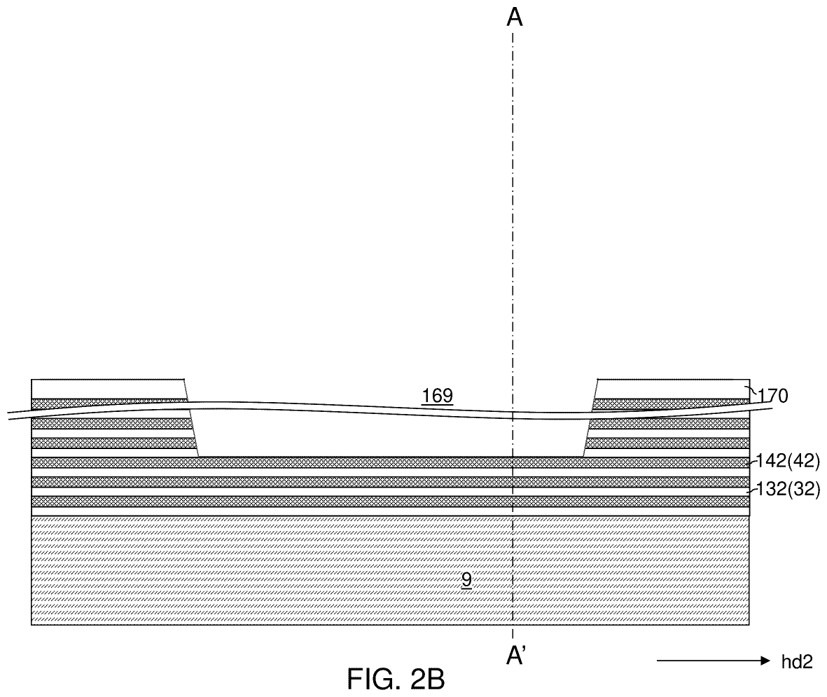

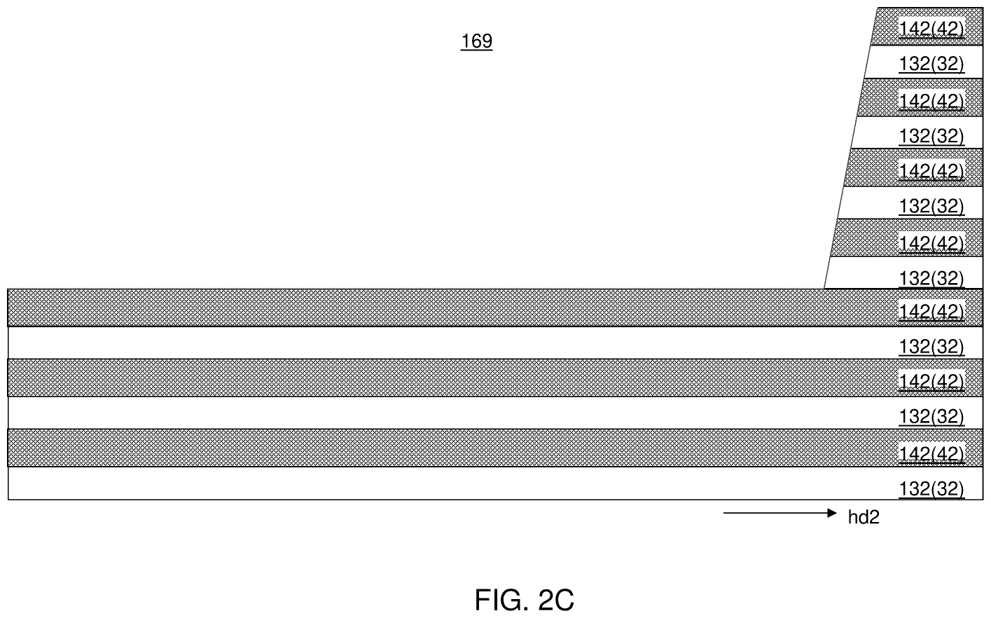

Referring to FIGS. 2A-2C, a first exemplary structure according to the first embodiment of the present disclosure is illustrated, which can be employed to form a semiconductor die such as the semiconductor die 1000 illustrated in FIGS. 1A-1E. A first vertically alternating sequence of first-tier insulating layers 132 and first-tier sacrificial material layers 142 can be formed over a substrate 9. As used herein, a vertically alternating sequence refers to a sequence of multiple instances of a first element and multiple instances of a second element that is arranged such that an instance of a second element is located between each vertically neighboring pair of instances of the first element, and an instance of a first element is located between each vertically neighboring pair of instances of the second element.

The first-tier insulating layers 132 can be composed of the first material, and the first-tier sacrificial material layers 142 can be composed of the second material, which is different from the first material. Each of the first-tier insulating layers 132 is an insulating layer that continuously extends over the entire area of the substrate 9, and may have a uniform thickness throughout. Each of the first-tier sacrificial material layers 142 may be a sacrificial material layer, which includes a dielectric material and continuously extends over the entire area of the substrate 9, and may have a uniform thickness throughout. Insulating materials that may be used for the first-tier insulating layers 132 include, but are not limited to silicon oxide (including doped or undoped silicate glass), silicon nitride, silicon oxynitride, organosilicate glass (OSG), spin-on dielectric materials, dielectric metal oxides that are commonly known as high dielectric constant (high-k) dielectric oxides (e.g., aluminum oxide, hafnium oxide, etc.) and silicates thereof, dielectric metal oxynitrides and silicates thereof, and organic insulating materials. In one embodiment, the first material of the first-tier insulating layers 132 may be silicon oxide.

The second material of the first-tier sacrificial material layers 142 is a dielectric material, which is a sacrificial material that may be removed selectively to the first material of the first-tier insulating layers 132. As used herein, removal of a first material is “selective to” a second material if the removal process removes the first material at a removal rate that is at least twice the removal rate for the second material. The ratio of the rate of removal of the first material to the rate of removal of the second material is herein referred to as a “selectivity” of the removal process for the first material with respect to the second material.

The thickness of each first-tier insulating layer 132 may be in a range from 12 nm to 50 nm, such as from 15 nm to 30 nm, although lesser and greater thicknesses may also be employed. The thickness of each first-tier sacrificial material layer 142 may be in a range from 15 nm to 50 nm, such as from 20 nm to 30 nm, although lesser and greater thicknesses may also be employed. The second material of the first-tier sacrificial material layers 142 may be subsequently replaced with electrically conductive electrodes which may function, for example, as control gate electrodes of a vertical NAND device. In one embodiment, the first-tier sacrificial material layers 142 may comprise silicon nitride.

Generally, a vertically alternating sequence of unit layer stacks is formed over a substrate. Each of the unit layer stacks comprises a first insulating layer (such as a first insulating layer 132) and a first spacer material layer (such as a first-tier sacrificial material layer 142). Generally, the first spacer material layers are formed as, or are subsequently replaced with, first-tier electrically conductive layers. While the present disclosure is described employing an embodiment in which the first spacer material layers are formed as first-tier sacrificial material layers 142 that are subsequently replaced with first-tier electrically conductive layers, embodiments are expressly contemplated herein in which the first spacer material layers are formed as first-tier electrically conductive layers. In such embodiments, steps for replacing the material of the first spacer material layers with an electrically conductive material can be omitted.

A first-tier insulating cap layer 170 can be formed over the first vertically alternating sequence (132, 142). The first-tier insulating cap layer 170 comprises an insulating material, which may be the same material as the material of the first-tier insulating layers 132. First stepped surfaces can be formed within the staircase regions of the inter-array region 200 by patterning the first-tier insulating cap layer 170 and the first vertically alternating sequence (132, 142). For example, a combination of a sacrificial hard mask layer and a trimming mask layer may be employed to form the first stepped surfaces. In one embodiment, a row of multiple first staircase regions can be formed within each area that corresponds to a combination of the area of a laterally-neighboring pair of first-tier retro-stepped dielectric material portions 165 and an intervening area. In this case, the multiple first staircase regions can be vertically offset by different depths by subsequently performing area recess etch processes.

A first-tier stepped cavity 169 can be formed over each contiguous set of first stepped surfaces of the first vertically alternating sequence (132, 142). The lateral extents of the first-tier sacrificial material layers 142 vary with a vertical distance from the substrate 9. Generally, an alternating stack (32, 42) of insulating layers 32 and sacrificial material layers 42 may be formed over a substrate 9, and first stepped surfaces can be formed by patterning the alternating stack (32, 42) such that lateral extents of the sacrificial material layers 42 vary with a vertical distance from the substrate 9 in a staircase region.

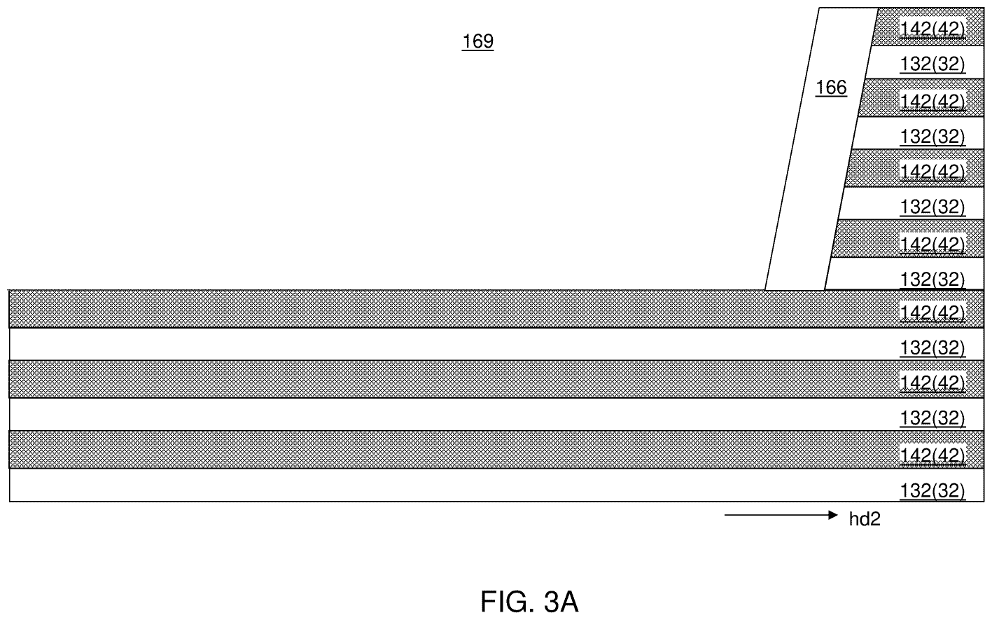

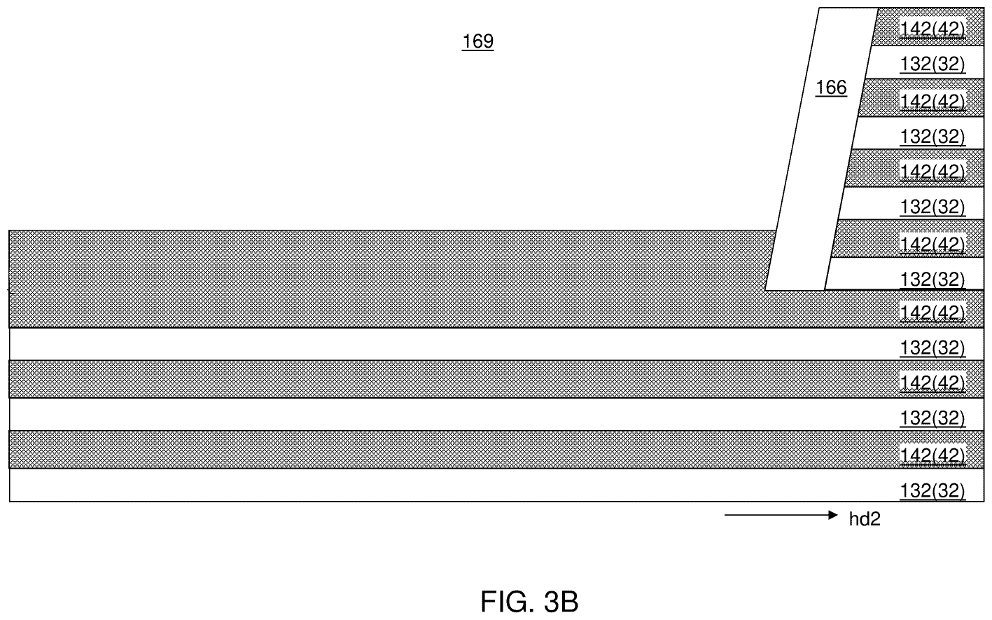

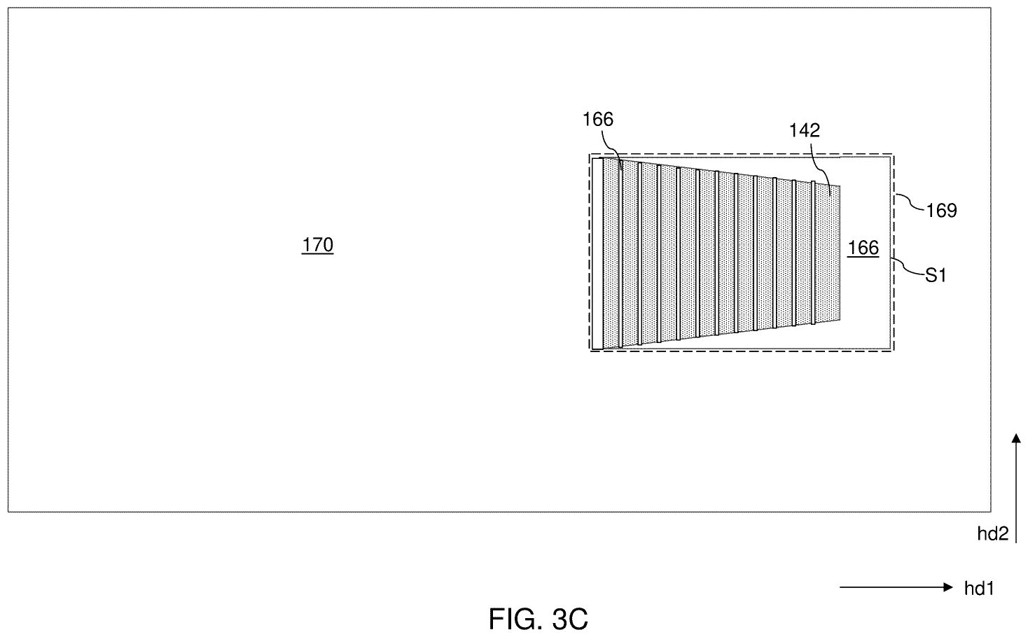

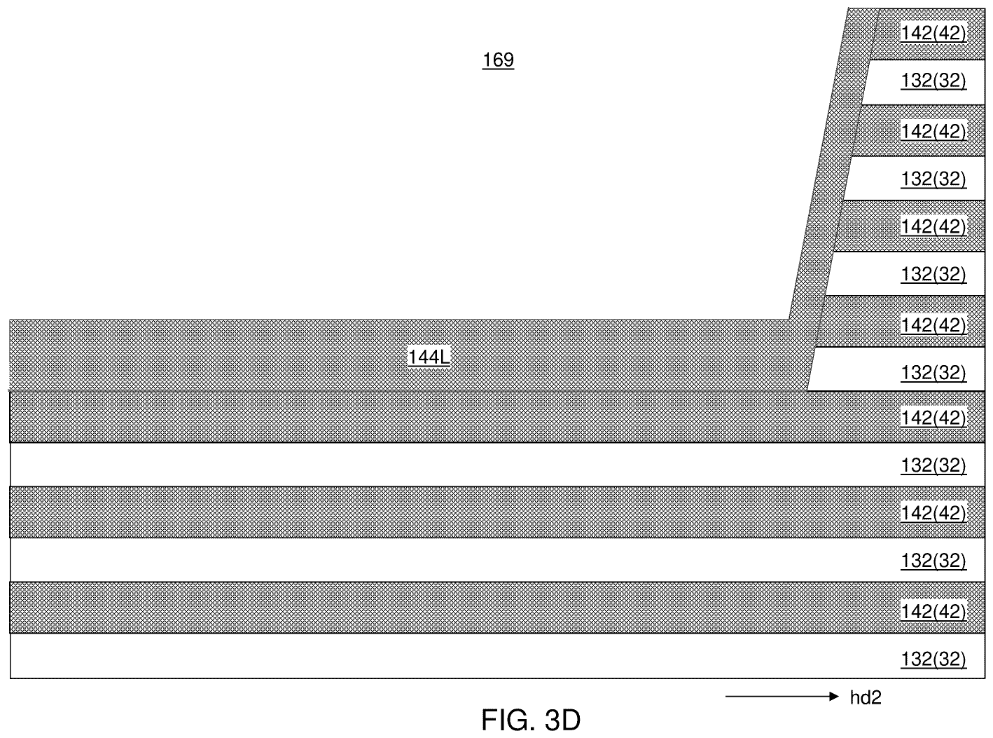

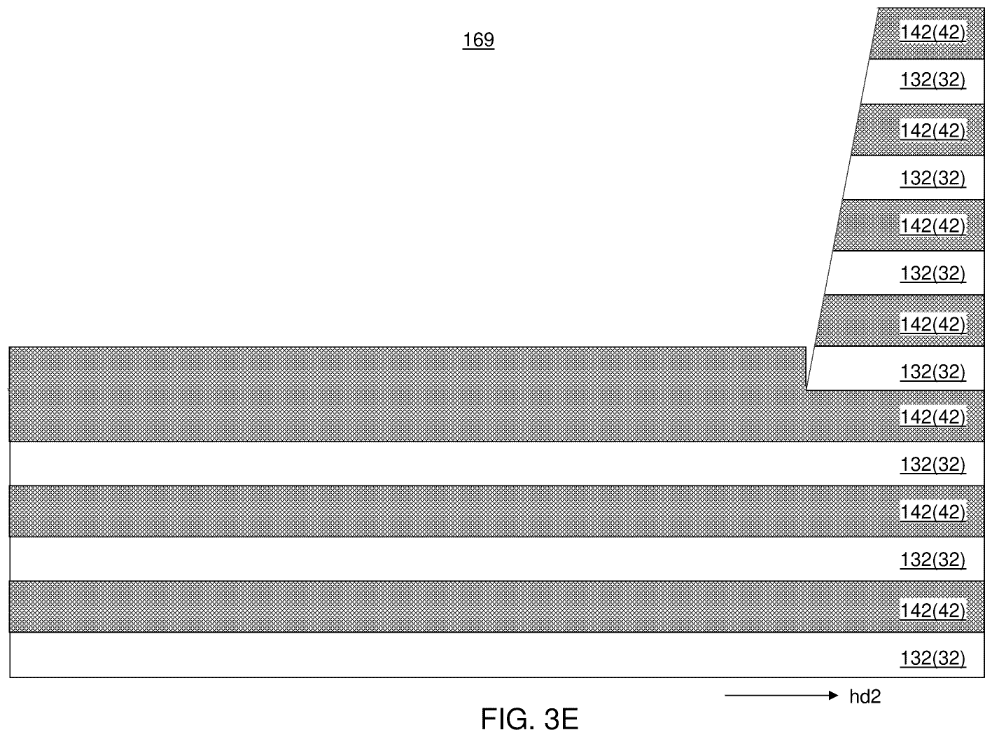

In one embodiment shown in FIGS. 3A-3C, exposed portions of sacrificial material layers are thickened by selective growth of additional sacrificial material on the exposed portions. Referring to FIG. 3A, an insulating material layer can be conformally deposited over the first vertically alternating sequence (132, 142). The insulating material layer comprises an insulating material, such as silicon oxide, and may comprise a same material as the first-tier insulating layers 132. An anisotropic etch process can be performed to etch horizontally-extending portions of the insulating material layer. Remaining portions of the insulating material layer comprise first insulating sidewall spacers 166 that are formed on sidewalls of the first stepped surfaces that underlie the first-tier stepped cavity 169. Referring to FIG. 3B, a selective material deposition process can be performed to grow a same material as the sacrificial material of the first-tier sacrificial material layers 142 from the physically exposed surfaces of the first-tier sacrificial material layers 142. For example, if the first-tier sacrificial material layers 142 comprise silicon nitride, the physically exposed portions of the first-tier sacrificial material layers 142 can be thickened by selectively growing silicon nitride from physically exposed surfaces of the first-tier sacrificial material layers 142. The thickened portions of the first-tier sacrificial material layers 142 can have a thickness in a range from 150% to 400% of the thickness of the unthickened portions of the first-tier sacrificial material layers 142. Referring to FIG. 3C, a region of the first exemplary structure is illustrated after locally thickening the first-tier sacrificial material layers 142. First vertical steps S1 of the first stepped surfaces that are perpendicular to the first horizontal direction hd1 are illustrated.

In an alternative embodiment shown in FIGS. 3D-3E, portions of sacrificial material layers are thickened by non-selective deposition of an additional sacrificial material layer followed by etching back the additional sacrificial material layer. In this embodiment, the first insulating sidewall spacers 166 are omitted. Referring to FIG. 3D, an anisotropic material deposition process can be performed to anisotropically deposit a same material as the material of the first-tier sacrificial material layers 142 to form a non-conformal sacrificial material layer 144L. In one embodiment, the first-tier sacrificial material layers 142 comprise silicon nitride, and the anisotropic material deposition process may deposit a silicon nitride material anisotropically. The non-conformal sacrificial material layer 144L is deposited by a non-conformal deposition process, such as a plasma-enhanced chemical vapor deposition (PECVD) process. Preferably, the deposition of the sacrificial material of the non-conformal sacrificial material layer 144L is highly anisotropic such that the thickness of each horizontally-extending portion of the non-conformal sacrificial material layer 144L is greater than (e.g., at least twice) the thickness of non-horizontally-extending portions of the non-conformal sacrificial material layer 144L. In one embodiment the thickness of the horizontally-extending portions of the non-conformal sacrificial material layer 144L may be in a range from 50% to 300% of the thickness of each first-tier sacrificial material layer 142.

Referring to FIG. 3E, an isotropic etch process can be performed to isotropically recess the non-conformal sacrificial material layer 144L. The duration of the isotropic etch process can be selected such that the non-horizontally-extending portions of the non-conformal sacrificial material layer 144L are removed by the isotropic etch process. Remaining horizontally-extending portions of the non-conformal sacrificial material layer 144L overlying a top surface segment of a respective one of the first-tier sacrificial material layers 142 can be incorporated into the respective one of the first-tier sacrificial material layers 142. Thus, physically-exposed portions of the sacrificial material layers 42 (such as the first-tier sacrificial material layers 142) in the staircase region can be thickened such that the thickened portions of the sacrificial material layers 142 has a thickness in a range from 125% to 250%, such as from 150% to 200%, of the unthickened portion of the first-tier sacrificial material layers 142 (which is the same as the original thickness of each first-tier sacrificial material layers 142).

In summary, an alternating stack of insulating layers 32 and sacrificial material layers 42 can be patterned in a staircase region such that top surfaces of the sacrificial material layers 42 are physically exposed, and physically exposed portions of the sacrificial material layers 42 may be locally thickened by any method known in the art. Each of the sacrificial material layers 42 comprises a respective nominal thickness region (i.e., an unthickened portion having an original thickness) and a respective thickened region that are physically exposed in the staircase region.

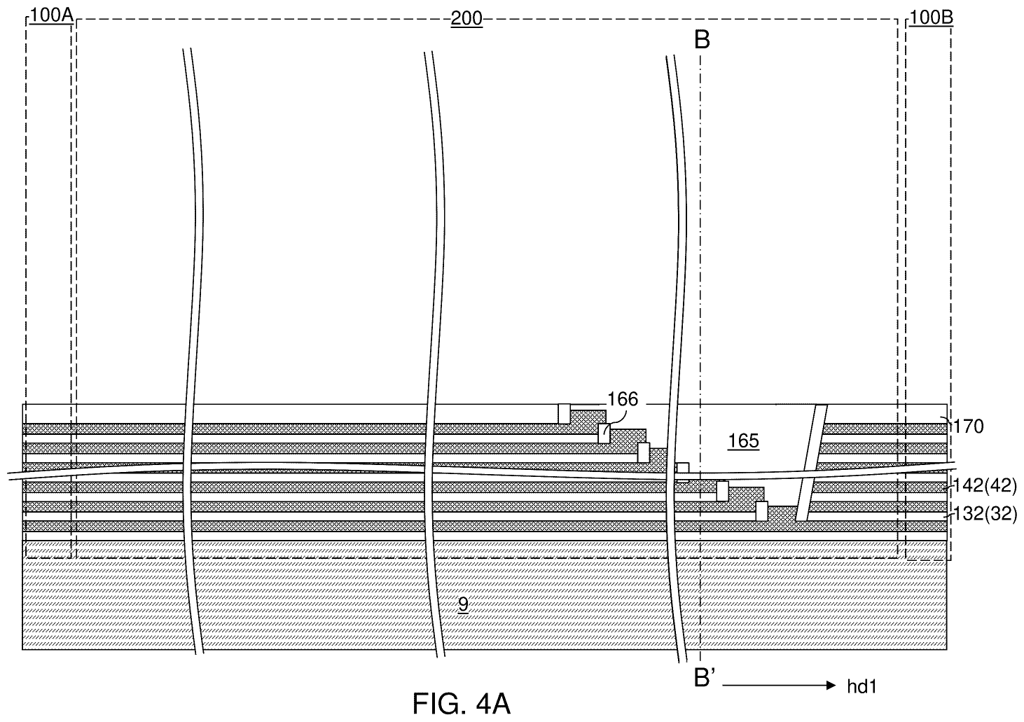

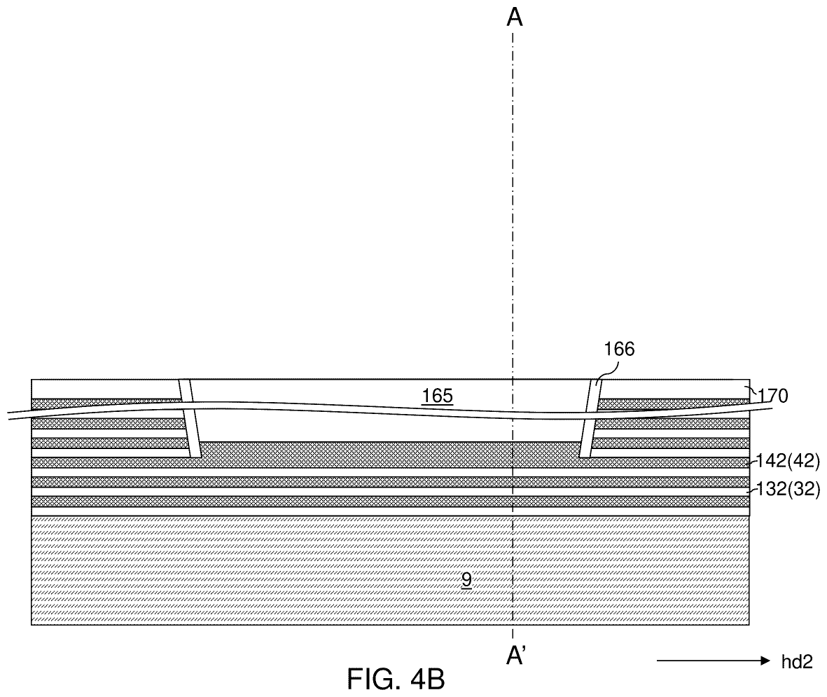

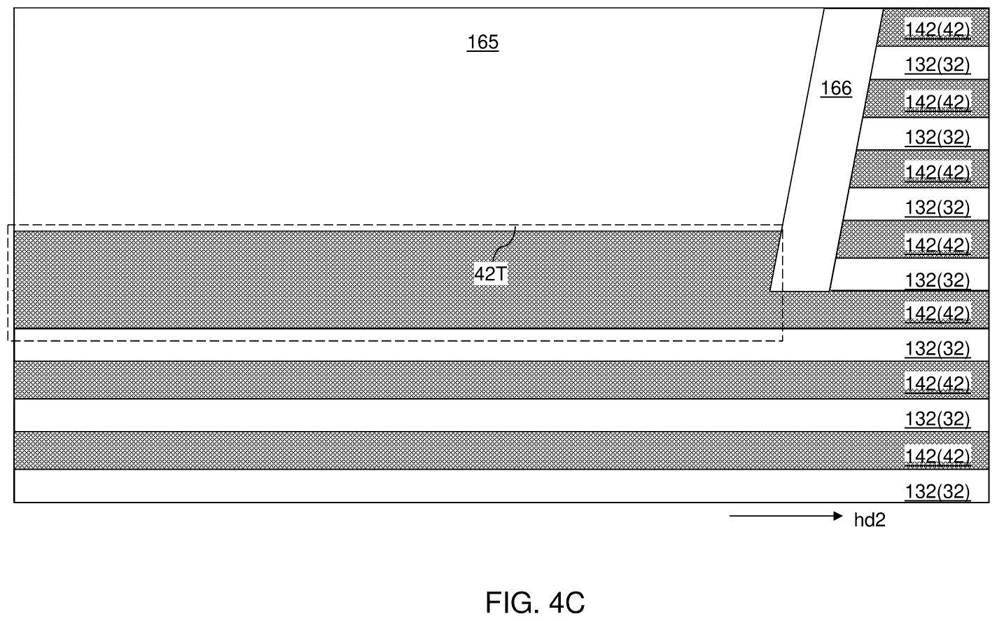

Referring to FIGS. 4A-4C, a first dielectric fill material (such as undoped silicate glass (i.e., silicon oxide) or a doped silicate glass) can be deposited in each first-tier stepped cavity 169. The first dielectric fill material can be planarized to remove excess portions of the first dielectric fill material from above the horizontal plane including the topmost surface of the first vertically alternating sequence (132, 142). Each remaining portion of the first dielectric fill material that fills a respective first-tier stepped cavity 169 constitutes a first-tier retro-stepped dielectric material portion 165. Generally, the first-tier retro-stepped dielectric material portions 165 can be formed in inter-array regions 200 located between a respective first memory array region 100A and a respective second memory array region 100B that are laterally spaced apart along the first horizontal direction hd1. The planar top surface of each first-tier retro-stepped dielectric material portion 165 can be located within a horizontal plane including the top surface of the first-tier insulating cap layer 170.

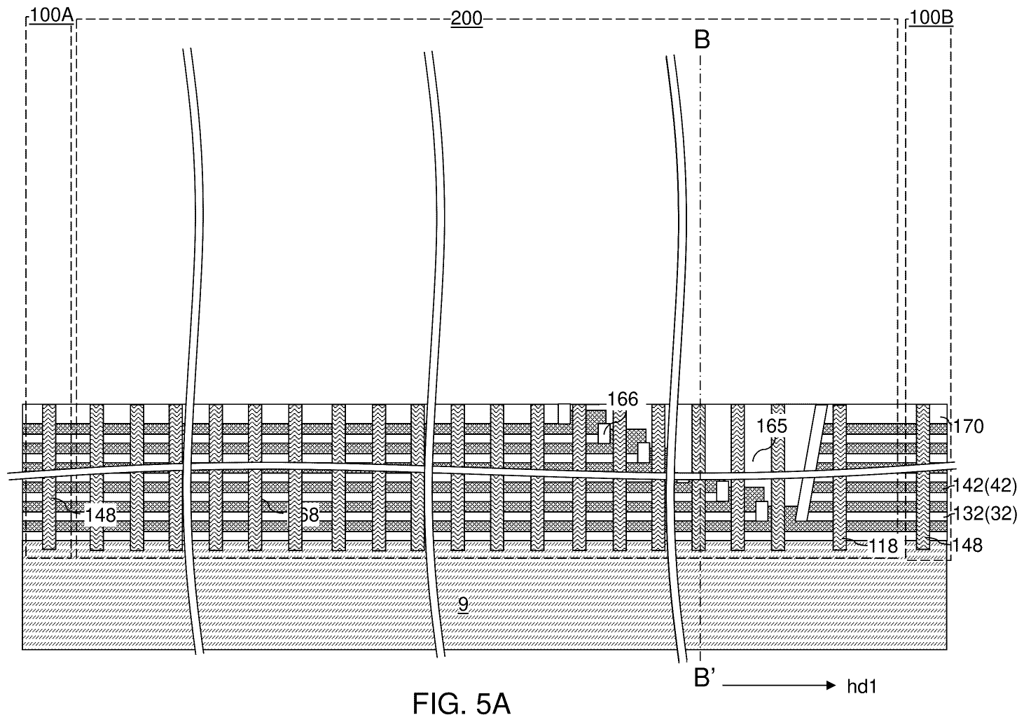

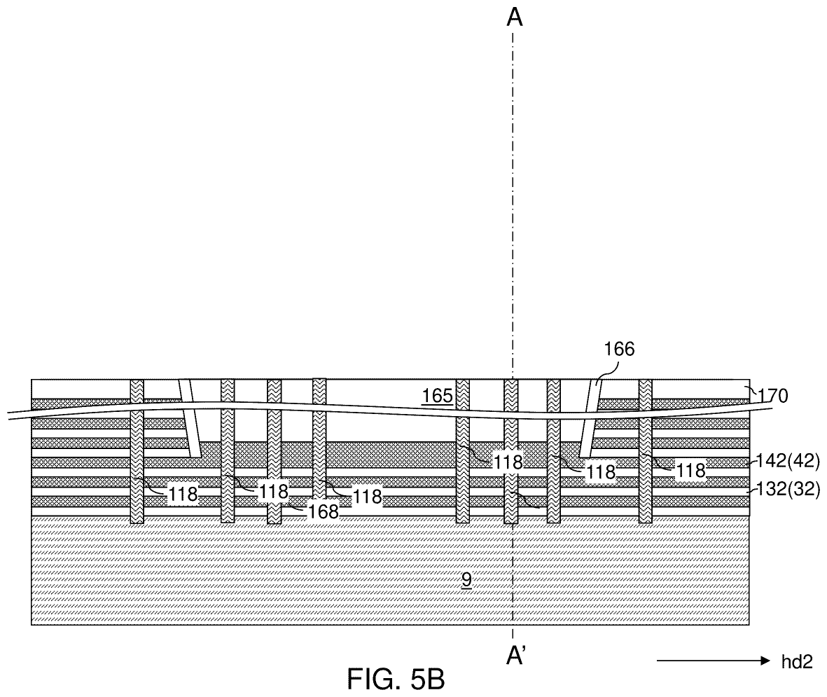

Referring to FIGS. 5A and 5B, various first-tier openings may be formed through the first vertically alternating sequence (132, 142) and into the substrate 9. A photoresist layer (not shown) may be applied over the first vertically alternating sequence (132, 142), and may be lithographically patterned to form various openings therethrough. The pattern of openings in the photoresist layer may be transferred through the first vertically alternating sequence (132, 142) and into the substrate 9 by a first anisotropic etch process to form the various first-tier openings concurrently, i.e., during the first isotropic etch process. The various first-tier openings may include first-tier memory openings formed in the memory array regions 100 and first-tier support openings formed in the inter-array regions 200, and first-tier contact openings formed in the staircase regions (which are located within the inter-array regions 200). Each cluster of first-tier memory openings may be formed as a two-dimensional array of first-tier memory openings. The first-tier support openings are openings that are formed in the inter-array region 200, and are subsequently employed to form support pillar structures. Each first-tier contact opening is formed in a respective area in which a respective layer contact via structure 86 is to be subsequently formed. A subset of the first-tier support openings may be formed through a respective horizontally-extending surface segment of the first stepped surfaces. A subset of the first-tier contact openings is formed through a respective horizontally-extending surface segment of the first stepped surfaces.

According to the first embodiment of the present disclosure, each first-tier sacrificial material layer 142 comprises a respective locally thickened portion underneath each first-tier retro-stepped dielectric material portion 165. Each of the first-tier contact openings can be formed through a locally thickened portion of a respective first-tier sacrificial material layer 142.

Sacrificial first-tier opening fill structures (148, 118, 168) may be formed in the various first-tier openings. For example, a sacrificial first-tier fill material is concurrently deposited in each of the first-tier openings. The sacrificial first-tier fill material includes a material that may be subsequently removed selectively to the materials of the first-tier insulating layers 132 and the first-tier sacrificial material layers 142. In one embodiment, the sacrificial first-tier fill material may include a semiconductor material such as silicon (e.g., a-Si or polysilicon), silicon-germanium, germanium, a III-V compound semiconductor material, or a combination thereof. Optionally, a thin etch stop liner (such as a silicon oxide layer or a silicon nitride layer having a thickness in a range from 1 nm to 3 nm) may be used prior to depositing the sacrificial first-tier fill material. The sacrificial first-tier fill material may be formed by a non-conformal deposition or a conformal deposition method.

In another embodiment, the sacrificial first-tier fill material may include a silicon oxide material having a higher etch rate than the material of the first-tier insulating layers 132. For example, the sacrificial first-tier fill material may include borosilicate glass or porous or non-porous organosilicate glass having an etch rate that is at least 100 times higher than the etch rate of densified TEOS oxide (i.e., a silicon oxide material formed by decomposition of tetraethylorthosilicate glass in a chemical vapor deposition process and subsequently densified in an anneal process) in a 100:1 dilute hydrofluoric acid. In this case, a thin etch stop liner (such as a silicon nitride layer having a thickness in a range from 1 nm to 3 nm) may be used prior to depositing the sacrificial first-tier fill material. The sacrificial first-tier fill material may be formed by a non-conformal deposition or a conformal deposition method.

In yet another embodiment, the sacrificial first-tier fill material may include carbon-containing material (such as amorphous carbon or diamond-like carbon) that may be subsequently removed by ashing, or a silicon-based polymer that may be subsequently removed selectively to the materials of the first vertically alternating sequence (132, 142).

Portions of the deposited sacrificial first-tier fill material may be removed from above the topmost layer of the first vertically alternating sequence (132, 142), such as from above the first-tier insulating cap layer 170. For example, the sacrificial first-tier fill material may be recessed to a top surface of the first-tier insulating cap layer 170 using a planarization process. The planarization process may include a recess etch, chemical mechanical planarization (CMP), or a combination thereof. The top surface of the first-tier insulating cap layer 170 may be used as an etch stop layer or a planarization stop layer.

Remaining portions of the sacrificial first-tier fill material comprise sacrificial first-tier opening fill structures (148, 118, 168). Specifically, each remaining portion of the sacrificial first-tier fill material in a first-tier memory opening constitutes a sacrificial first-tier memory opening fill structure 148. Each remaining portion of the sacrificial first-tier fill material in a first-tier support opening constitutes a sacrificial first-tier support opening fill structure 118. Each remaining portion of the sacrificial first-tier fill material in a first-tier contact opening constitutes a sacrificial first-tier contact opening fill structure 168. The various sacrificial first-tier opening fill structures (148, 118, 168) are concurrently formed, i.e., during a same set of processes including the deposition process that deposits the sacrificial first-tier fill material and the planarization process that removes the first-tier deposition process from above the first vertically alternating sequence (132, 142) (such as from above the top surface of the first-tier insulating cap layer 170). The top surfaces of the sacrificial first-tier opening fill structures (148, 118, 168) may be coplanar with the top surface of the first-tier insulating cap layer 170. Each of the sacrificial first-tier opening fill structures (148, 118, 168) may, or may not, include cavities therein. The set of all structures located between the bottommost surface of the first vertically alternating sequence (132, 142) and the topmost surface of the first vertically alternating sequence (132, 142) or embedded within the first vertically alternating sequence (132, 142) constitutes a first-tier structure.

According to an aspect of the present disclosure, each first-tier sacrificial material layer 142 comprises a respective locally thickened portion underneath each first-tier retro-stepped dielectric material portion 165. Each of the first-tier contact openings can be formed through a locally thickened portion of a respective first-tier sacrificial material layer 142. Accordingly, each of the sacrificial first-tier contact opening fill structures 168 can be formed through a locally thickened portion of a respective first-tier sacrificial material layer 142. The sacrificial first-tier contact opening fill structures 168 may vertically extend from a horizontal plane including a top surface of the first-tier alternating stack (132, 142) at least to a horizontal plane including a bottom surface of the first-tier alternating stack (132, 142).

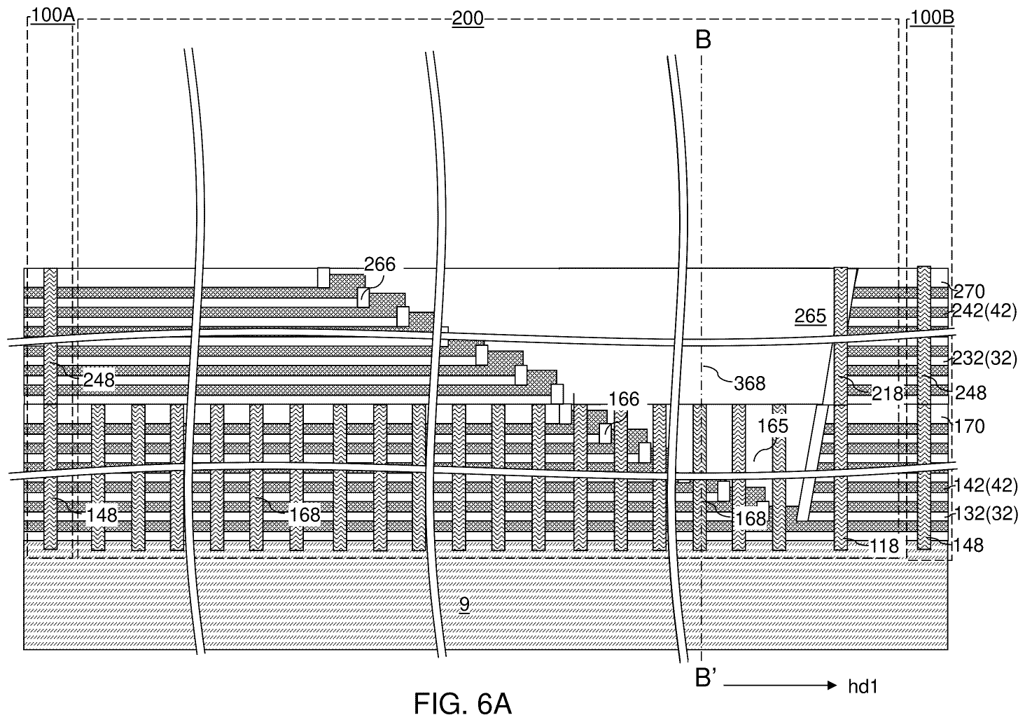

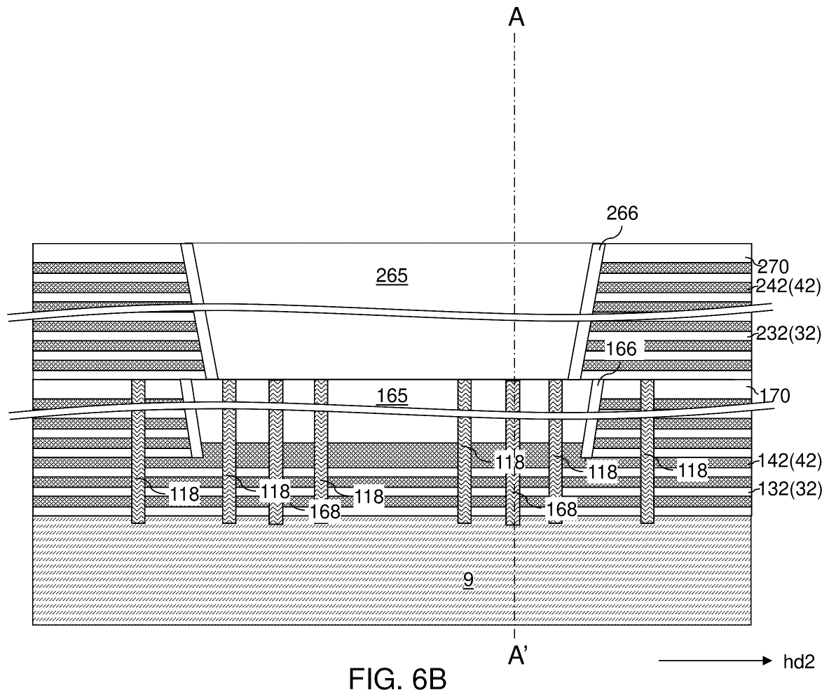

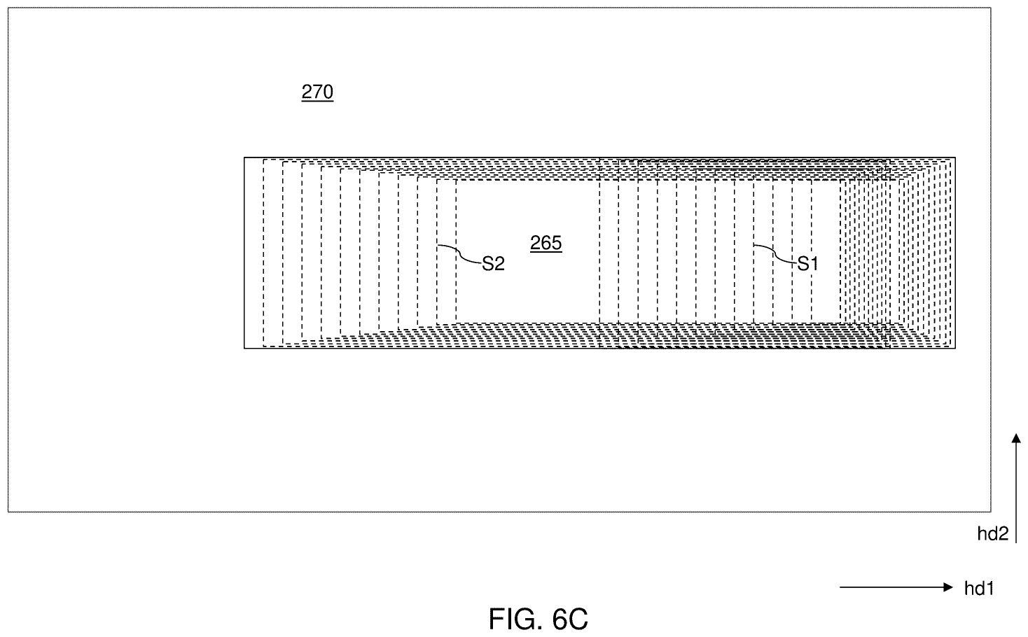

Referring to FIGS. 6A-6C, a second vertically alternating sequence of second-tier insulating layers 232 and second-tier sacrificial material layers 242 can be formed. Each of the second-tier insulating layers 232 is an insulating layer 32 that continuously extends over the entire area of the substrate 9, and may have a uniform thickness throughout. Each of the second-tier sacrificial material layers 242 is a sacrificial material layer 42 that includes a dielectric material and continuously extends over the entire area of the substrate 9, and may have a uniform thickness throughout. The second-tier insulating layers 232 can have the same material composition and the same thickness as the first-tier insulating layers 132. The second-tier sacrificial material layers 242 can have the same material composition and the same thickness as the first-tier sacrificial material layers 142. A second-tier insulating cap layer 270 can be formed over the second vertically alternating sequence (232, 242).

Second stepped surfaces can be formed within the staircase regions of the inter-array region 200. For example, a combination of a sacrificial hard mask layer and a trimming mask layer may be employed to form the second stepped surfaces. Generally, the processing steps described with reference to FIGS. 2A-2C can be performed to form second-tier stepped cavities, under which a respective set of second stepped surfaces of the second vertically alternating sequence (232, 242) are exposed. Each set of second stepped surfaces may be laterally offset relative to an adjacent and underlying set of first stepped surfaces of the first vertically alternating sequence (132, 142) along the first horizontal direction hd1.

The processing steps described with reference to FIG. 3A-3C or 3D-3E can be performed with suitable modifications in the masking pattern to optionally form second insulating sidewall spacers 266 on sidewalls of the second stepped surfaces that underlie second-tier stepped cavities, and to locally thicken physically exposed portions of the second-tier sacrificial material layers 242. The thickened portions of the second-tier sacrificial material layers 242 can have a thickness in a range from 150% to 400% of the thickness of the unthickened portions of the second-tier sacrificial material layers 242.

A second dielectric fill material (such as undoped silicate glass (i.e., silicon oxide) or a doped silicate glass) can be deposited in each second-tier stepped cavity. The second dielectric fill material can be planarized to remove excess portions of the second dielectric fill material from above the horizontal plane including the topmost surface of the second vertically alternating sequence (232, 242). Each remaining portion of the second dielectric fill material that fills a respective second continuous retro-stepped cavity constitutes a second-tier retro-stepped dielectric material portion 265. First vertical steps S1 of the first stepped surfaces that underlie the first-tier retro-stepped dielectric material portion 165 and second vertical steps S2 of the second stepped surfaces that underlie the second-tier retro-stepped dielectric material portion 265 are illustrated. The second vertical steps S2 are perpendicular to the first horizontal direction hd1. Generally, a second-tier structure is formed, which comprises a second vertically alternating sequence of second-tier insulating layers 232 and second-tier sacrificial material layers 242 and second-tier retro-stepped dielectric material portions 265 overlying second stepped surfaces of the second vertically alternating sequence that are located in the inter-array regions 200.

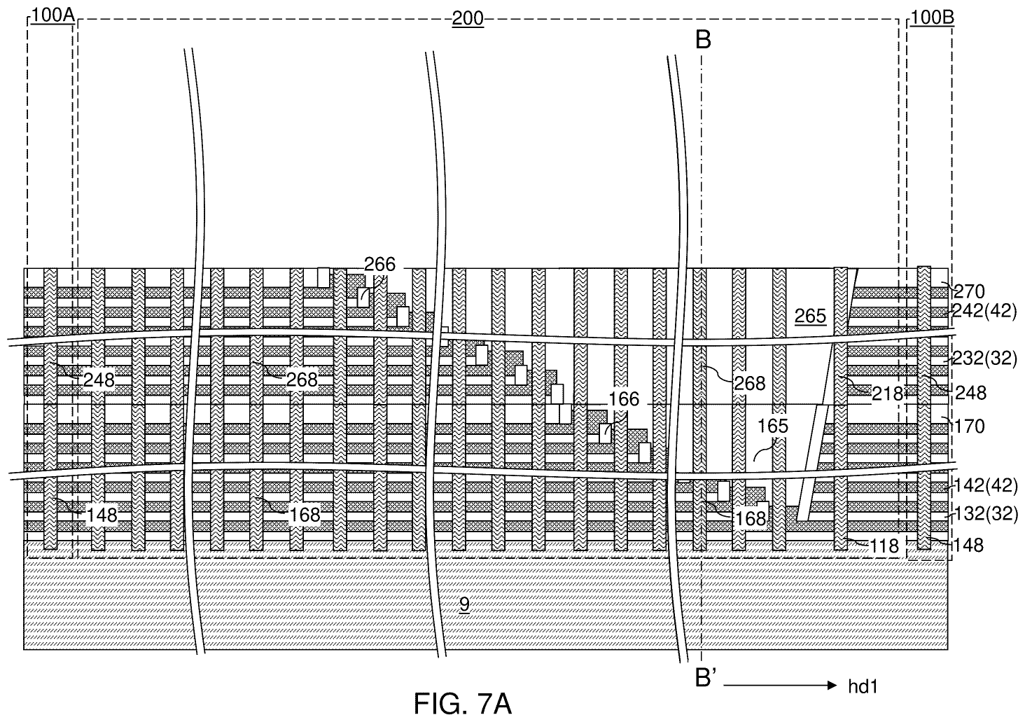

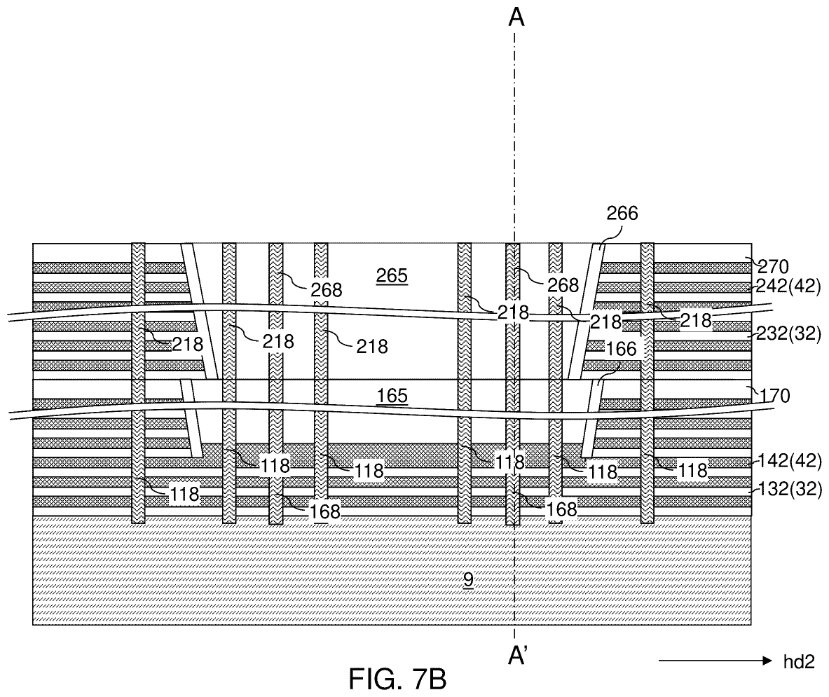

Referring to FIGS. 7A and 7B, various second-tier openings may be formed through the second vertically alternating sequence (232, 242) and over the sacrificial first-tier opening fill structures (148, 118, 168). A photoresist layer (not shown) may be applied over the second vertically alternating sequence (232, 242), and may be lithographically patterned to form various openings therethrough. The pattern of openings in the photoresist layer may be transferred through the second vertically alternating sequence (232, 242) to form the various second-tier openings concurrently, i.e., during the second isotropic recess etch process.

The various second-tier openings may include second-tier memory openings formed in the memory array regions 100, second-tier support openings formed in the inter-array region 200, and second-tier contact openings formed in the staircase region which is located within the inter-array region 200. Each second-tier opening may be formed within the area of a respective one of the sacrificial first-tier opening fill structures (148, 118, 168). Thus, a top surface of a sacrificial first-tier opening fill structure can be physically exposed at the bottom of each second-tier opening. Specifically, each second-tier memory opening can be formed directly over a respective sacrificial first-tier memory opening fill structure 148, each second-tier support opening can be formed directly over a respective sacrificial first-tier support opening fill structure 118, and each second-tier contact opening can be formed directly over a respective sacrificial first-tier contact opening fill structure 168.

Each cluster of second-tier memory openings may be formed as a two-dimensional array of second-tier memory openings. The second-tier support openings are openings that are formed in the inter-array region 200, and are subsequently employed to form support pillar structures. A subset of the second-tier support openings may be formed through a respective horizontally-extending surface segment of the second stepped surfaces. A subset of the second-tier contact openings may be formed through a respective horizontally-extending surface segment of the second stepped surfaces.

Sacrificial second-tier opening fill structures may be formed in the various second-tier openings. For example, a sacrificial first-tier fill material is concurrently deposited in each of the second-tier openings. The sacrificial second-tier fill material can include any material that may be employed for the sacrificial first-tier fill material. Portions of the deposited sacrificial second-tier fill material may be removed from above the topmost layer of the second vertically alternating sequence (232, 242). Remaining portions of the sacrificial second-tier fill material comprise sacrificial second-tier opening fill structures (248, 218, 268).

Specifically, each remaining portion of the sacrificial second-tier fill material in a second-tier memory opening constitutes a sacrificial second-tier memory opening fill structure 248. Each remaining portion of the sacrificial second-tier fill material in a second-tier support opening constitutes a sacrificial second-tier support opening fill structure 218. Each remaining portion of the sacrificial second-tier fill material in a second-tier contact opening constitutes a sacrificial second-tier contact opening fill structure 268. The top surfaces of the sacrificial second-tier opening fill structures (248, 218, 268) may be coplanar with the top surface of the second-tier insulating cap layer 270. Each of the sacrificial second-tier opening fill structures may, or may not, include cavities therein. The set of all structures located between the bottommost surface of the second vertically alternating sequence (232, 242) and the topmost surface of the second vertically alternating sequence (232, 242) or embedded within the second vertically alternating sequence (232, 242) constitutes a second-tier structure.

According to an aspect of the present disclosure, each second-tier sacrificial material layer 242 comprises a respective locally thickened portion underneath each second-tier retro-stepped dielectric material portion 265. Each of the second-tier contact openings can be formed through a locally thickened portion of a respective second-tier sacrificial material layer 242. Accordingly, each of the sacrificial second-tier contact opening fill structures 268 can be formed through a locally thickened portion of a respective second-tier sacrificial material layer 242. The sacrificial second-tier contact opening fill structures 268 may vertically extend from a horizontal plane including a top surface of the second-tier alternating stack (232, 242) at least to a horizontal plane including a bottom surface of the second-tier alternating stack (232, 242).

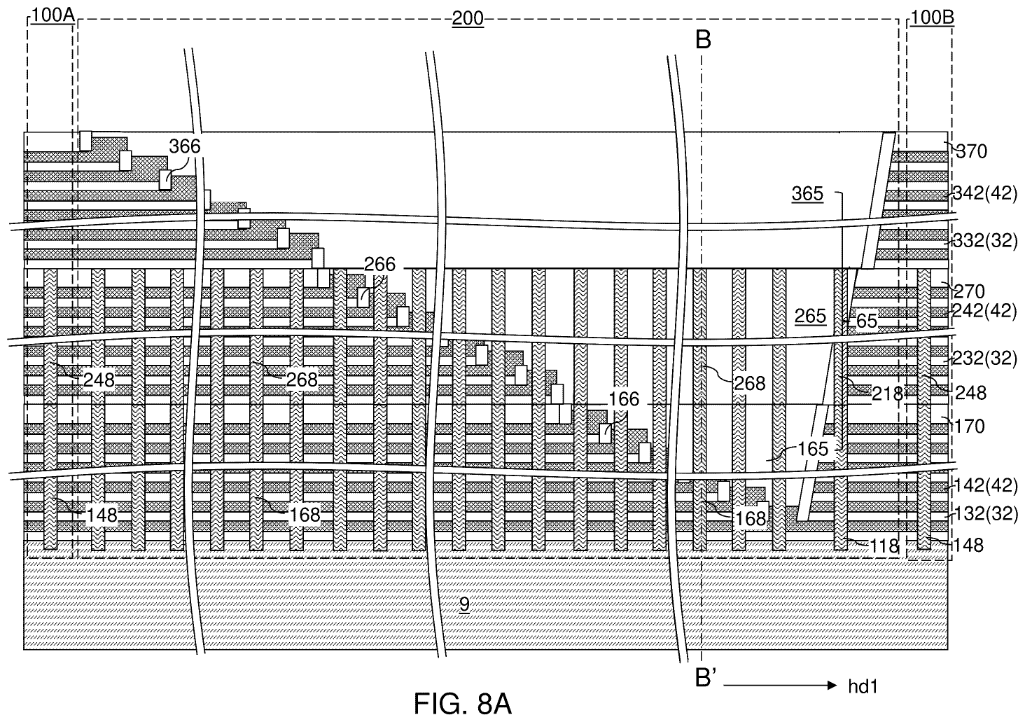

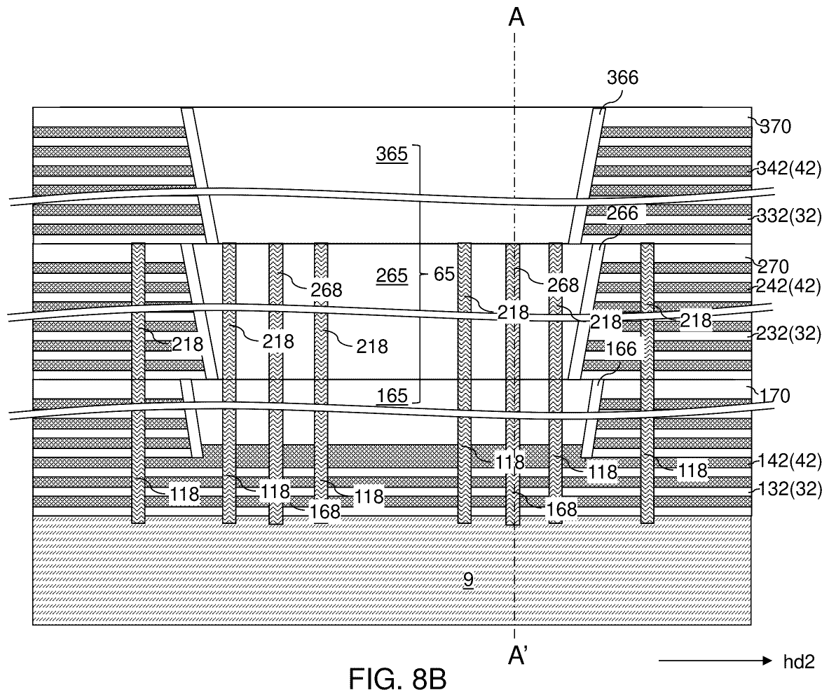

Referring to FIGS. 8A and 8B, a third vertically alternating sequence of third-tier insulating layers 332 and third-tier sacrificial material layers 342 can be formed. Each of the third-tier insulating layers 332 is an insulating layer 32 that continuously extends over the entire area of the substrate 9, and may have a uniform thickness throughout. Each of the third-tier sacrificial material layers 342 is a sacrificial material layer 42 that includes a dielectric material and continuously extends over the entire area of the substrate 9, and may have a uniform thickness throughout. The third-tier insulating layers 332 can have the same material composition and the same thickness as the first-tier insulating layers 132. The third-tier sacrificial material layers 342 can have the same material composition and the same thickness as the first-tier sacrificial material layers 142. A third-tier insulating cap layer 370 can be formed over the third vertically alternating sequence (332, 342).

Third stepped surfaces can be formed within the staircase regions of the inter-array region 200. For example, a combination of a sacrificial hard mask layer and a trimming mask layer may be employed to form the third stepped surfaces. Generally, the processing steps described with reference to FIGS. 2A-2C can be performed to form third-tier stepped cavities, under which a respective set of third stepped surfaces of the third vertically alternating sequence (332, 342) are exposed. Each set of third stepped surfaces may be laterally offset relative to an adjacent and underlying set of second stepped surfaces of the second vertically alternating sequence (232, 242) and relative to an adjacent and underlying set of first stepped surfaces of the first vertically alternating sequence (132, 142) along the first horizontal direction hd1.

The processing steps described with reference to FIG. 3A-3C or 3D-3E can be performed with suitable modifications in the masking pattern to form optional third insulating sidewall spacers 366 on sidewalls of the third stepped surfaces that underlie third-tier stepped cavities, and to locally thicken physically exposed portions of the third-tier sacrificial material layers 342. The thickened portions of the third-tier sacrificial material layers 342 can have a thickness in a range from 150% to 400% of the thickness of the unthickened portions of the third-tier sacrificial material layers 342.

A third dielectric fill material (such as undoped silicate glass (i.e., silicon oxide) or a doped silicate glass) can be deposited in each third continuous retro-stepped cavity. The third dielectric fill material can be planarized to remove excess portions of the third dielectric fill material from above the horizontal plane including the topmost surface of the third vertically alternating sequence (332, 342). Each remaining portion of the third dielectric fill material that fills a respective third continuous retro-stepped cavity constitutes a third-tier retro-stepped dielectric material portion 365.

Generally, at least one tier structure is formed. Each tier structure comprises a respective vertically alternating sequence of insulating layers 32 and sacrificial material layers 42. Each sacrificial material layer 42 may comprise a respective locally thickened portion that underlies (i.e., is located lower than) a respective contiguous set of stepped surfaces of the vertically alternating sequence. Each tier structure may comprise a respective retro-stepped dielectric material portions (165, 265, or 365) overlying the locally thickened portions of the sacrificial material layers 42.

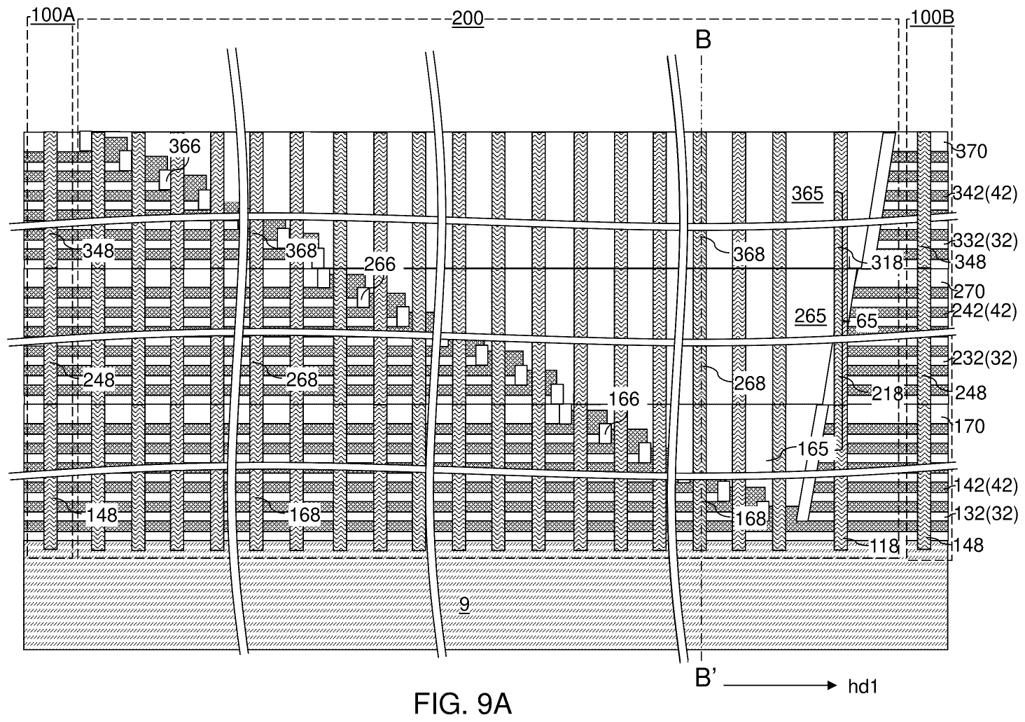

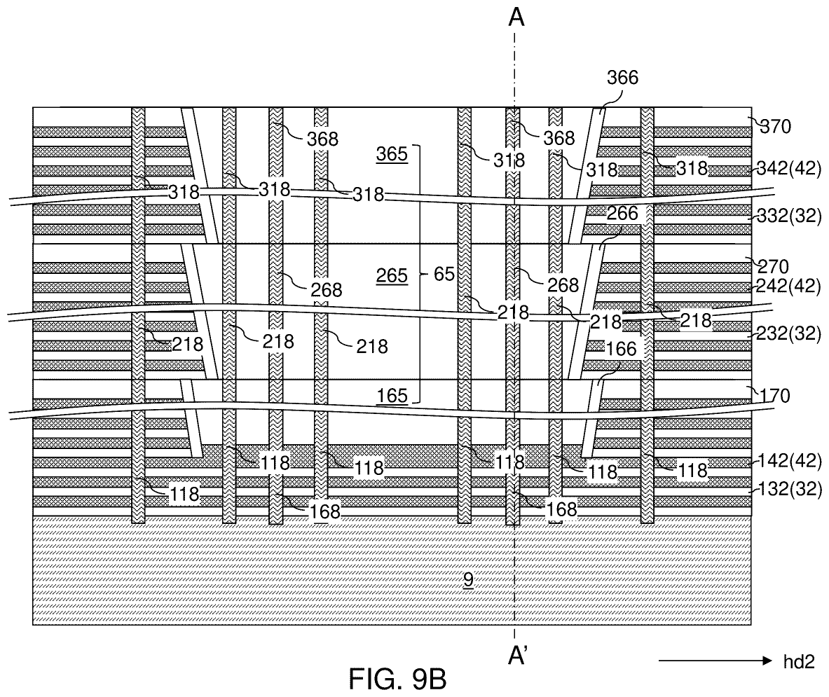

Referring to FIGS. 9A and 9B, various third-tier openings may be formed through the third vertically alternating sequence (332, 342) and over the sacrificial second-tier opening fill structures (248, 218, 268). A photoresist layer (not shown) may be applied over the third vertically alternating sequence (332, 342), and may be lithographically patterned to form various openings therethrough. The pattern of openings in the photoresist layer may be transferred through the third vertically alternating sequence (332, 342) to form the various third-tier openings concurrently, i.e., during the third isotropic etch process.

The various third-tier openings may include third-tier memory openings formed in the memory array regions 100, third-tier support openings formed in the inter-array region 200, and third-tier contact openings formed in the staircase region which is located within the inter-array region 200. Each third-tier opening may be formed within the area of a respective one of the sacrificial second-tier opening fill structures (248, 218, 268). Thus, a top surface of a sacrificial second-tier opening fill structure can be physically exposed at the bottom of each third-tier opening. Specifically, each third-tier memory opening can be formed directly over a respective sacrificial second-tier memory opening fill structure 248, each third-tier support opening can be formed directly over a respective sacrificial second-tier support opening fill structure 218, and each third-tier contact opening can be formed directly over a respective sacrificial second-tier contact opening fill structure 268. Each cluster of third-tier memory openings may be formed as a two-dimensional array of third-tier memory openings. The third-tier support openings are openings that are formed in the inter-array region 200, and are subsequently employed to form support pillar structures. A subset of the third-tier support openings may be formed through a respective horizontally-extending surface segment of the third stepped surfaces. A subset of the third-tier contact openings may be formed through a respective horizontally-extending surface segment of the third stepped surfaces.

Sacrificial third-tier opening fill structures may be formed in the various third-tier openings. For example, a sacrificial second-tier fill material is concurrently deposited in each of the third-tier openings. The sacrificial third-tier fill material can include any material that may be employed for the sacrificial second-tier fill material. Portions of the deposited sacrificial third-tier fill material may be removed from above the topmost layer of the third vertically alternating sequence (332, 342). Remaining portions of the sacrificial third-tier fill material comprise sacrificial third-tier opening fill structures (348, 318, 368). Specifically, each remaining portion of the sacrificial third-tier fill material in a third-tier memory opening constitutes a sacrificial third-tier memory opening fill structure 348. Each remaining portion of the sacrificial third-tier fill material in a third-tier support opening constitutes a sacrificial third-tier support opening fill structure 318. Each remaining portion of the sacrificial third-tier fill material in a third-tier contact opening constitutes a sacrificial third-tier contact opening fill structure 368. The top surfaces of the sacrificial third-tier opening fill structures (348, 318, 368) may be coplanar with the top surface of the third-tier insulating cap layer 370. Each of the sacrificial third-tier opening fill structures may, or may not, include cavities therein. The set of all structures located between the bottommost surface of the third vertically alternating sequence (332, 342) and the topmost surface of the third vertically alternating sequence (332, 342) or embedded within the third vertically alternating sequence (332, 342) constitutes a third-tier structure.

According to an aspect of the present disclosure, each third-tier sacrificial material layer 342 optionally comprises a respective locally thickened portion underneath each third-tier retro-stepped dielectric material portion 365. Each of the third-tier contact openings can be formed through a locally thickened portion of a respective third-tier sacrificial material layer 342. Accordingly, each of the sacrificial third-tier contact opening fill structures 368 can be formed through a locally thickened portion of a respective third-tier sacrificial material layer 342. The sacrificial third-tier contact opening fill structures 368 may vertically extend from a horizontal plane including a top surface of the third-tier alternating stack (332, 342) at least to a horizontal plane including a bottom surface of the third-tier alternating stack (332, 342).

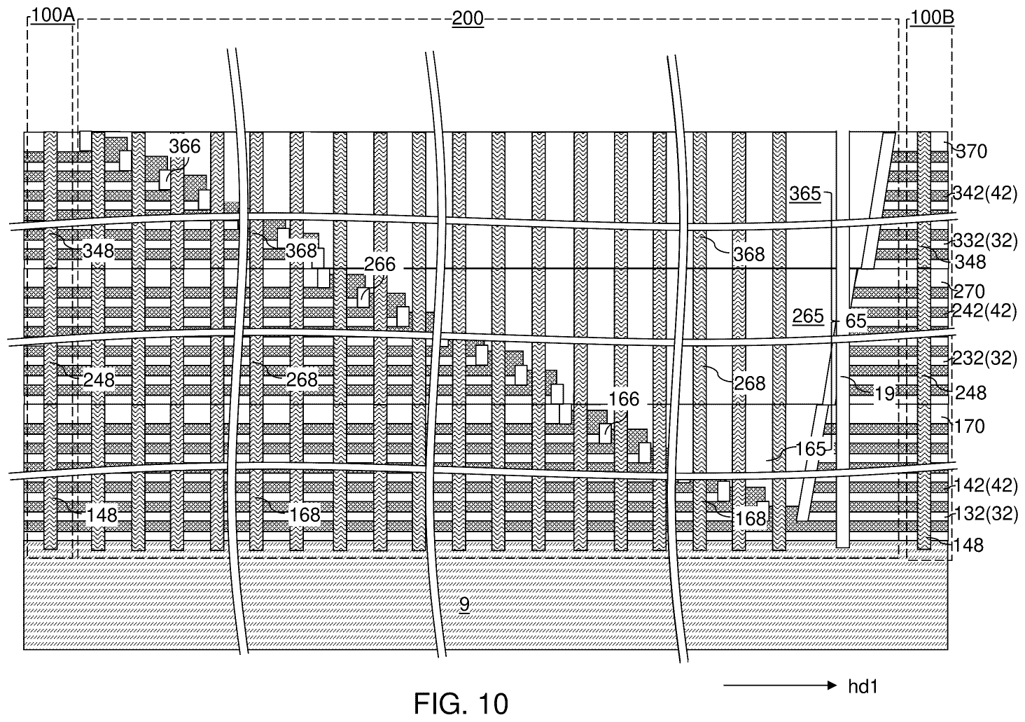

Referring to FIG. 10, a photoresist layer (not shown) can be applied over the third-tier structure, and can be lithographically patterned to form openings over the areas of the sacrificial third-tier support opening fill structures 318. The sacrificial fill materials of the sacrificial third-tier support opening fill structures 318, the sacrificial second-tier support opening fill structures 218, and the sacrificial first-tier support opening fill structures 118 can be removed selectively to the materials of the retro-stepped dielectric material portions 65, the insulating layers 32, and the sacrificial material layers 42. Support pillar cavities can be formed in the volumes from which the materials of the sacrificial third-tier support opening fill structures 318, the sacrificial second-tier support opening fill structures 218, and the sacrificial first-tier support opening fill structures 118 are removed. The photoresist layer can be subsequently removed, for example, by ashing.

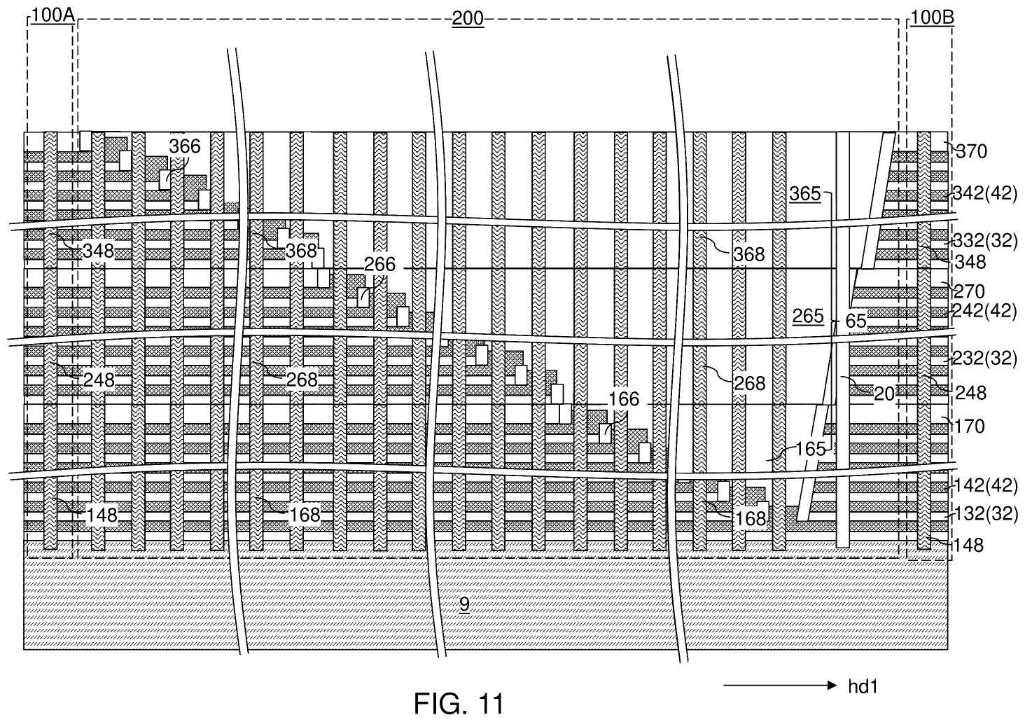

Referring to FIG. 11, a dielectric fill material can be deposited in the support pillar cavities by performing a conformal deposition process. The dielectric fill material comprises a dielectric material that is different from the material of the sacrificial material layers 42. For example, the dielectric fill material may comprise undoped silicate glass or a doped silicate glass. Excess portions of the dielectric fill material can be removed from above the horizontal plane including the top surface of the topmost retro-stepped dielectric material portions 65 (such as the third-tier retro-stepped dielectric material portion 365). Each remaining portion of the dielectric fill material that fills a respective support pillar cavity constitutes a support pillar structure 20. The support pillar structures 20 can be formed in the inter-array region 200, and may vertically extend from the substrate 9 to a horizontal plane including the topmost surfaces of the retro-stepped dielectric material portions 65 and the third-tier insulating cap layer 370.

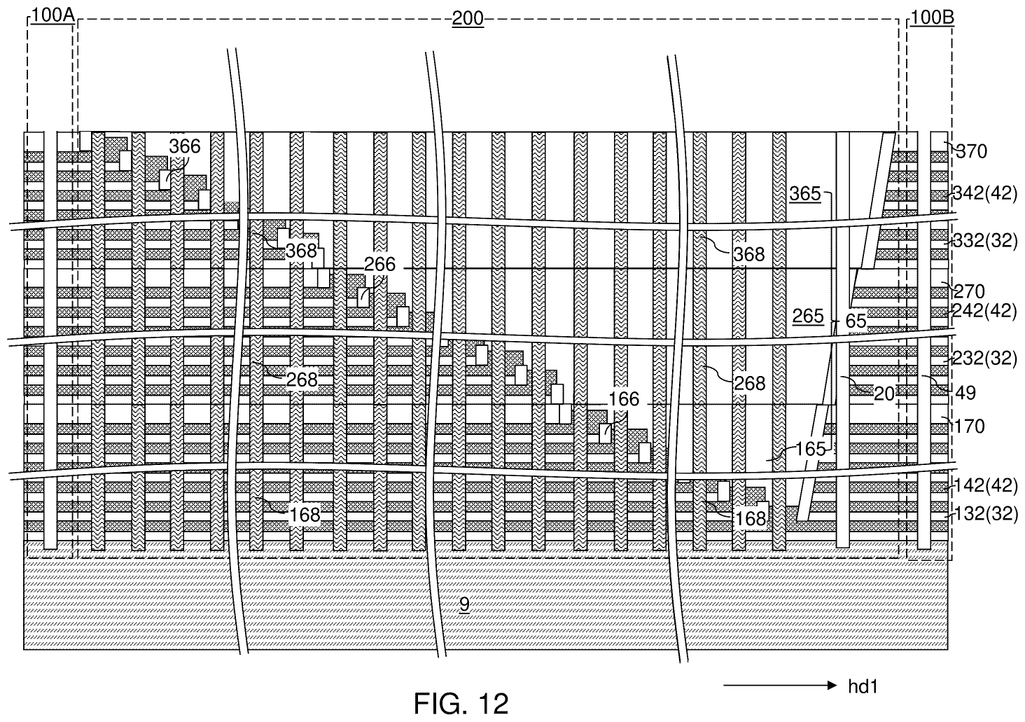

Referring to FIG. 12, a photoresist layer (not shown) can be applied over the third-tier structure, and can be lithographically patterned to cover the inter-array regions 200 without covering the memory array regions 100. The sacrificial fill materials of the sacrificial memory opening fill structures (148, 248, 348) can be removed selectively to the materials of the insulating layers 32, the sacrificial material layers 42, and the substrate 9. Memory openings 49 are formed in the voids from which the sacrificial fill materials of the sacrificial memory opening fill structures (148, 248, 348) are removed.

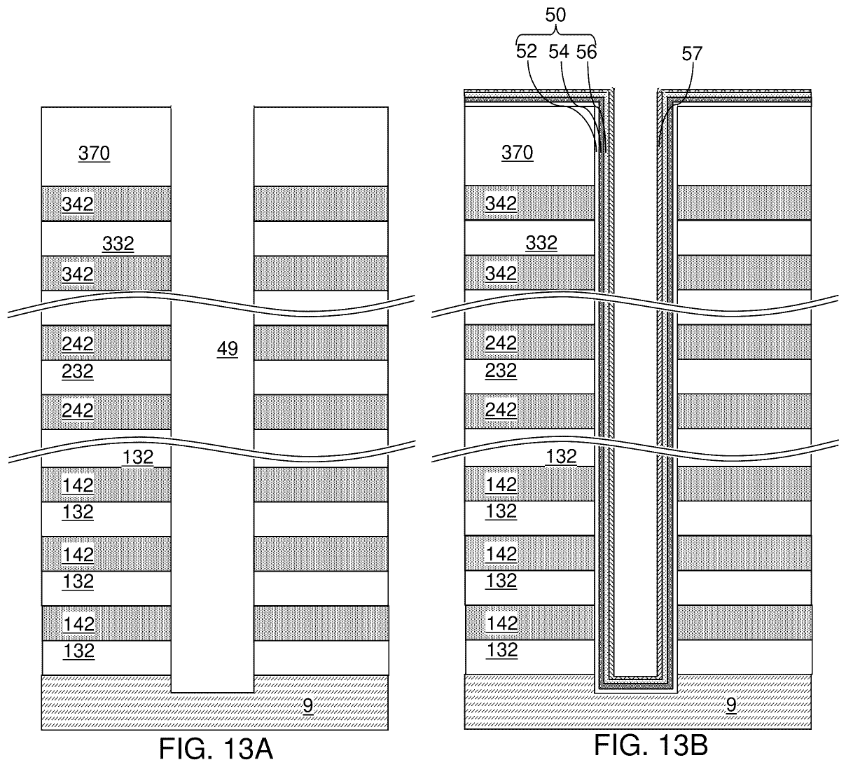

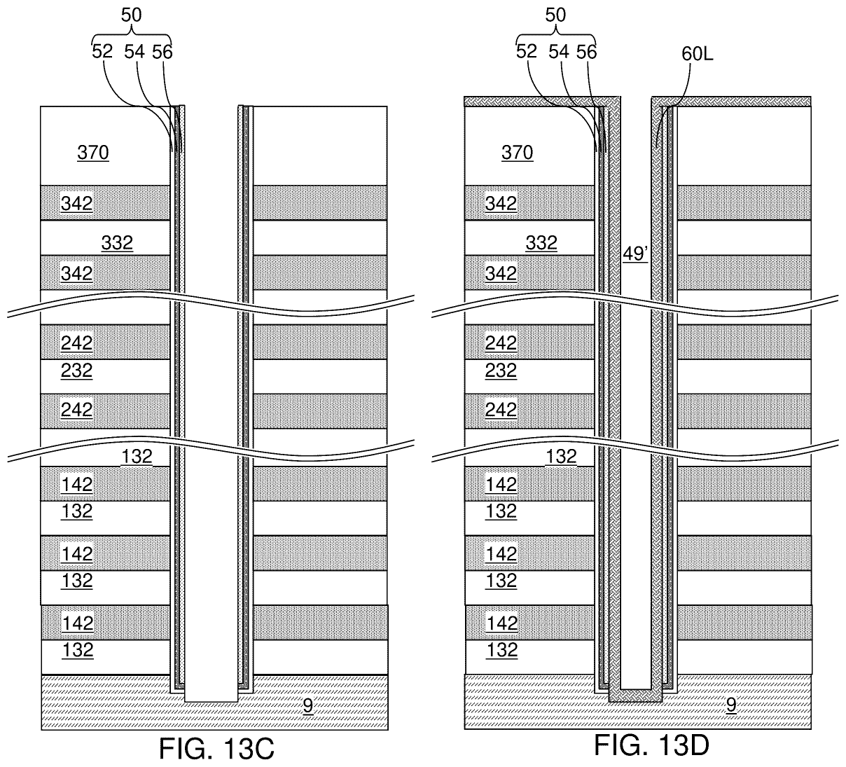

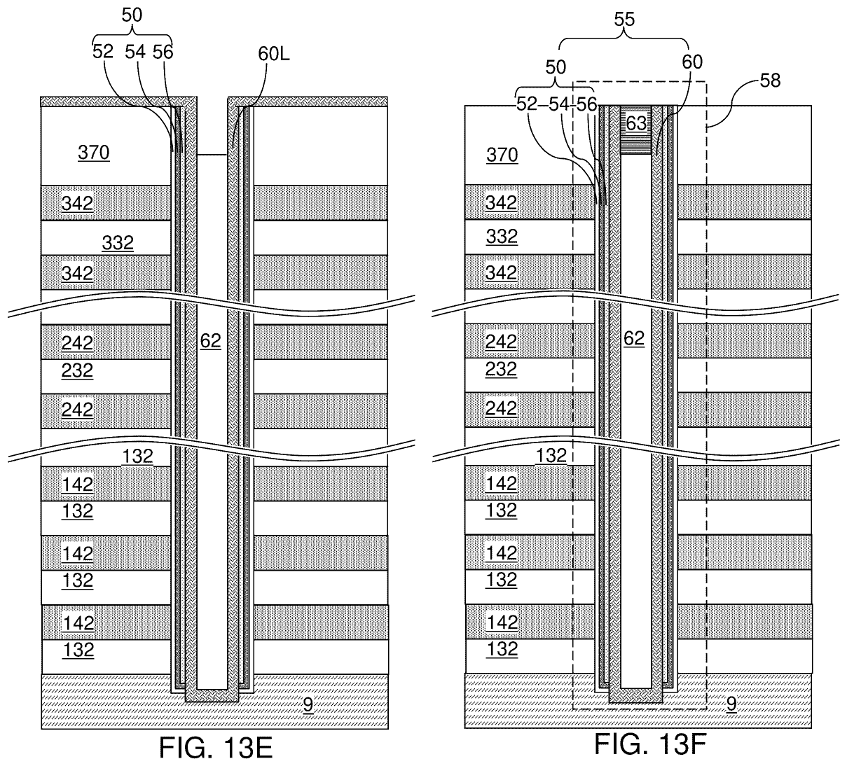

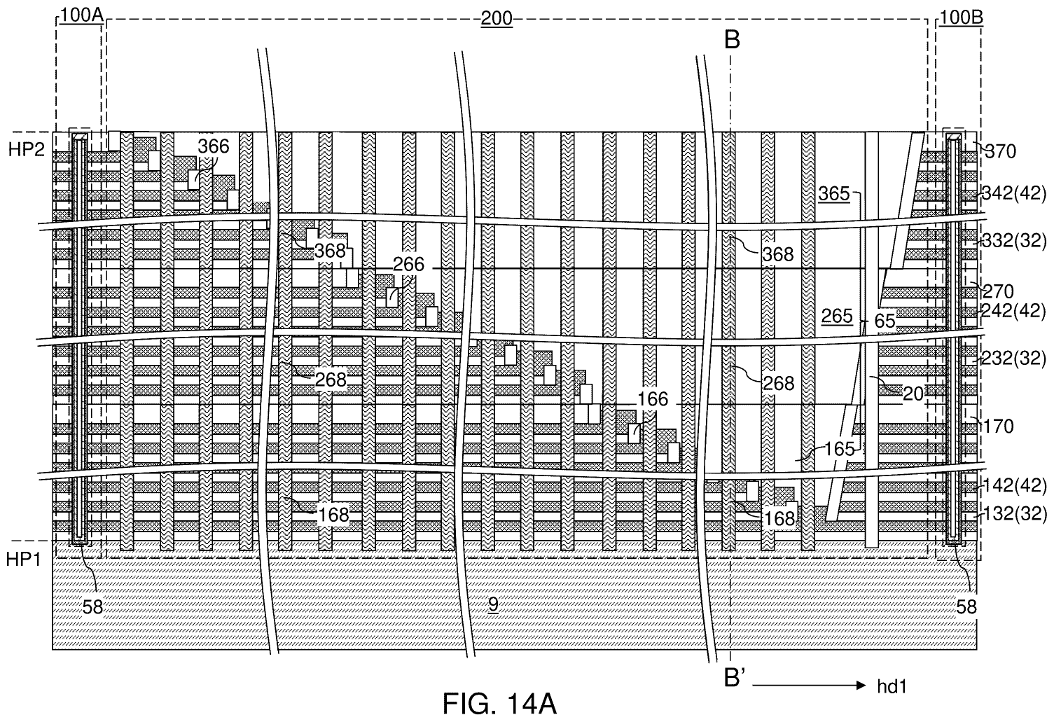

FIGS. 13A-13F illustrate sequential vertical cross-sectional views of a memory opening during formation of a memory opening fill structure according to the first embodiment of the present disclosure.

Referring to FIG. 13A, a memory opening 49 in the first exemplary structure of FIG. 12 is illustrated.

Referring to FIG. 13B, a stack of layers including a blocking dielectric layer 52, a memory material layer 54, a dielectric liner 56, and an optional sacrificial cover layer 57 may be sequentially deposited in the inter-tier memory openings 49. The blocking dielectric layer 52 may include a single dielectric material layer or a stack of a plurality of dielectric material layers. In one embodiment, the blocking dielectric layer 52 may include a dielectric metal oxide layer consisting essentially of a dielectric metal oxide. As used herein, a dielectric metal oxide refers to a dielectric material that includes at least one metallic element and at least oxygen. The dielectric metal oxide may consist essentially of the at least one metallic element and oxygen, or may consist essentially of the at least one metallic element, oxygen, and at least one non-metallic element such as nitrogen. In one embodiment, the blocking dielectric layer 52 may include a dielectric metal oxide having a dielectric constant greater than 7.9, i.e., having a dielectric constant greater than the dielectric constant of silicon nitride. The thickness of the dielectric metal oxide layer may be in a range from 1 nm to 20 nm, although lesser and greater thicknesses may also be used. The dielectric metal oxide layer may subsequently function as a dielectric material portion that blocks leakage of stored electrical charges to control gate electrodes. In one embodiment, the blocking dielectric layer 52 includes aluminum oxide. Alternatively or additionally, the blocking dielectric layer 52 may include a dielectric semiconductor compound such as silicon oxide, silicon oxynitride, silicon nitride, or a combination thereof.

Subsequently, the memory material layer 54 may be formed. Generally, the memory material layer 54 may comprise any memory material known in the art. In one embodiment, the memory material layer 54 may be a continuous layer or patterned discrete portions of a charge trapping material including a dielectric charge trapping material, which may be, for example, silicon nitride. Alternatively, the memory material layer 54 may include a continuous layer or patterned discrete portions of a conductive material such as doped polysilicon or a metallic material that is patterned into multiple electrically isolated portions (e.g., floating gates), for example, by being formed within lateral recesses into sacrificial material layers 42. In one embodiment, the memory material layer 54 includes a silicon nitride layer. In one embodiment, the sacrificial material layers 42 and the insulating layers 32 may have vertically coincident sidewalls, and the memory material layer 54 may be formed as a single continuous layer. Alternatively, the sacrificial material layers 42 may be laterally recessed with respect to the sidewalls of the insulating layers 32, and a combination of a deposition process and an anisotropic etch process may be used to form the memory material layer 54 as a plurality of memory material portions that are vertically spaced apart. The thickness of the memory material layer 54 may be in a range from 2 nm to 20 nm, although lesser and greater thicknesses may also be used.

The dielectric liner 56 includes a dielectric material. In one embodiment, the dielectric liner 56 may comprise a tunneling dielectric layer through which charge tunneling may be performed under suitable electrical bias conditions. The charge tunneling may be performed through hot-carrier injection or by Fowler-Nordheim tunneling induced charge transfer depending on the mode of operation of the monolithic three-dimensional NAND string memory device to be formed. The dielectric liner 56 may include silicon oxide, silicon nitride, silicon oxynitride, dielectric metal oxides (such as aluminum oxide and hafnium oxide), dielectric metal oxynitride, dielectric metal silicates, alloys thereof, and/or combinations thereof. In one embodiment, the dielectric liner 56 may include a stack of a first silicon oxide layer, a silicon oxynitride layer, and a second silicon oxide layer, which is commonly known as an ONO stack. In one embodiment, the dielectric liner 56 may include a silicon oxide layer that is substantially free of carbon or a silicon oxynitride layer that is substantially free of carbon. The thickness of the dielectric liner 56 may be in a range from 2 nm to 20 nm, although lesser and greater thicknesses may also be used. The stack of the blocking dielectric layer 52, the memory material layer 54, and the dielectric liner 56 constitutes a memory film 50 that stores memory bits.

The sacrificial cover layer 57 may comprise a sacrificial material that may be subsequently removed selectively to the material of the dielectric liner 56. For example, the sacrificial cover layer may comprise a semiconductor material (e.g., amorphous silicon), silicon oxide, or a carbon-based material (such as amorphous carbon or diamond-like carbon). The thickness of the sacrificial cover layer may be in a range from 1 nm to 10 nm, although lesser and greater thicknesses may also be employed.

Referring to FIG. 13C, an anisotropic etch process may be performed to remove horizontal portions of the sacrificial cover layer 57, the dielectric liner 56, the memory material layer 54, and the blocking dielectric layer 52. Remaining cylindrical portions of the sacrificial cover layer 57 may be removed selectively to the material of the dielectric liner 56 during the anisotropic etch process, or by an isotropic etch process (such as a wet etch process) or by ashing. Alternatively, if the sacrificial cover layer 57 comprises a semiconductor material (e.g., amorphous silicon), then it may be retained.

Referring to FIG. 13D, a semiconductor channel material layer 60L can be deposited by a conformal deposition process. The semiconductor channel material layer 60L includes a p-doped semiconductor material such as at least one elemental semiconductor material, at least one III-V compound semiconductor material, at least one II-VI compound semiconductor material, at least one organic semiconductor material, or other semiconductor materials known in the art. In one embodiment, the semiconductor channel material layer 60L may have a uniform doping. In one embodiment, the semiconductor channel material layer 60L has a p-type doping in which p-type dopants (such as boron atoms) are present at an atomic concentration in a range from 1.0×10¹²/cm³ to 1.0×10¹⁸/cm³, such as from 1.0×10¹⁴/cm³ to 1.0×10¹⁷/cm³. In one embodiment, the semiconductor channel material layer 60L includes, and/or consists essentially of, boron-doped amorphous silicon or boron-doped polysilicon. In another embodiment, the semiconductor channel material layer 60L has an n-type doping in which n-type dopants (such as phosphor atoms or arsenic atoms) are present at an atomic concentration in a range from 1.0×10¹²/cm³ to 1.0×10¹⁸/cm³, such as from 1.0×10¹⁴/cm³ to 1.0×10¹⁷/cm³. The semiconductor channel material layer 60L may be formed by a conformal deposition method such as a low pressure chemical vapor deposition (LPCVD) process. The thickness of the semiconductor channel material layer 60L may be in a range from 2 nm to 10 nm, although lesser and greater thicknesses may also be used. A cavity 49′ is formed in the volume of each inter-tier memory opening 49 that is not filled with the deposited material layers (52, 54, 56, 60L).

Referring to FIG. 13E, if the cavity 49′ in each memory opening 49 is not completely filled by the semiconductor channel material layer 60L, a dielectric core layer may be deposited in the cavity 49′ to fill any remaining portion of the cavity 49′ within each memory opening 49. The dielectric core layer includes a dielectric material such as silicon oxide or organosilicate glass. The dielectric core layer may be deposited by a conformal deposition method such as a low pressure chemical vapor deposition (LPCVD) process, or by a self-planarizing deposition process such as spin coating. The horizontal portion of the dielectric core layer overlying the third-tier insulating cap layer 370 may be removed, for example, by a recess etch. The recess etch continues until top surfaces of the remaining portions of the dielectric core layer are recessed to a height between the top and bottom surfaces of the third-tier insulating cap layer 370. Each remaining portion of the dielectric core layer constitutes a dielectric core 62.

Referring to FIG. 13F, a doped semiconductor material having a doping of a second conductivity type may be deposited in cavities overlying the dielectric cores 62. The second conductivity type is the opposite of the first conductivity type. For example, if the first conductivity type is p-type, the second conductivity type is n-type, and vice versa. Portions of the deposited doped semiconductor material, the semiconductor channel material layer 60L, the dielectric liner 56, the memory material layer 54, and the blocking dielectric layer 52 that overlie the horizontal plane including the top surface of the third-tier insulating cap layer 370 may be removed by a planarization process such as a chemical mechanical planarization (CMP) process.

Each remaining portion of the doped semiconductor material of the second conductivity type constitutes a drain region 63. The dopant concentration in the drain regions 63 may be in a range from 5.0×10¹⁸/cm³ to 2.0×10²¹/cm³, although lesser and greater dopant concentrations may also be used. The doped semiconductor material may be, for example, doped polysilicon.

Each remaining portion of the semiconductor channel material layer 60L constitutes a vertical semiconductor channel 60 through which electrical current may flow when a vertical NAND device including the vertical semiconductor channel 60 is turned on. A dielectric liner 56 is surrounded by a memory material layer 54, and laterally surrounds a vertical semiconductor channel 60. Each adjoining set of a blocking dielectric layer 52, a memory material layer 54, and a dielectric liner 56 collectively constitute a memory film 50, which may store electrical charges with a macroscopic retention time. In some embodiments, a blocking dielectric layer 52 may not be present in the memory film 50 at this step, and a blocking dielectric layer may be subsequently formed after formation of lateral recesses. As used herein, a macroscopic retention time refers to a retention time suitable for operation of a memory device as a permanent memory device such as a retention time in excess of 24 hours.

Each combination of a memory film 50 and a vertical semiconductor channel 60 within an inter-tier memory opening 49 constitutes a memory stack structure 55. The memory stack structure 55 is a combination of a vertical semiconductor channel 60, a dielectric liner 56, a plurality of memory elements comprising portions of the memory material layer 54, and an optional blocking dielectric layer 52. The memory stack structures 55 can be formed through memory array regions 100 of the first and second vertically alternating sequences in which all layers of the first and second vertically alternating sequences are present. Each combination of a memory stack structure 55, a dielectric core 62, and a drain region 63 within an inter-tier memory opening 49 constitutes a memory opening fill structure 58. Generally, memory opening fill structures 58 are formed within the memory openings 49. Each of the memory opening fill structures 58 comprises a respective memory film 50 and a respective vertical semiconductor channel 60.

In one embodiment, each of the memory stack structures 55 comprises vertical NAND string including the respective vertical stack of memory elements (comprising portions of a memory material layer 54 located at levels of the sacrificial material layers 42) and a vertical semiconductor channel 60 that vertically extend through the sacrificial material layers 42 adjacent to the respective vertical stack of memory elements.

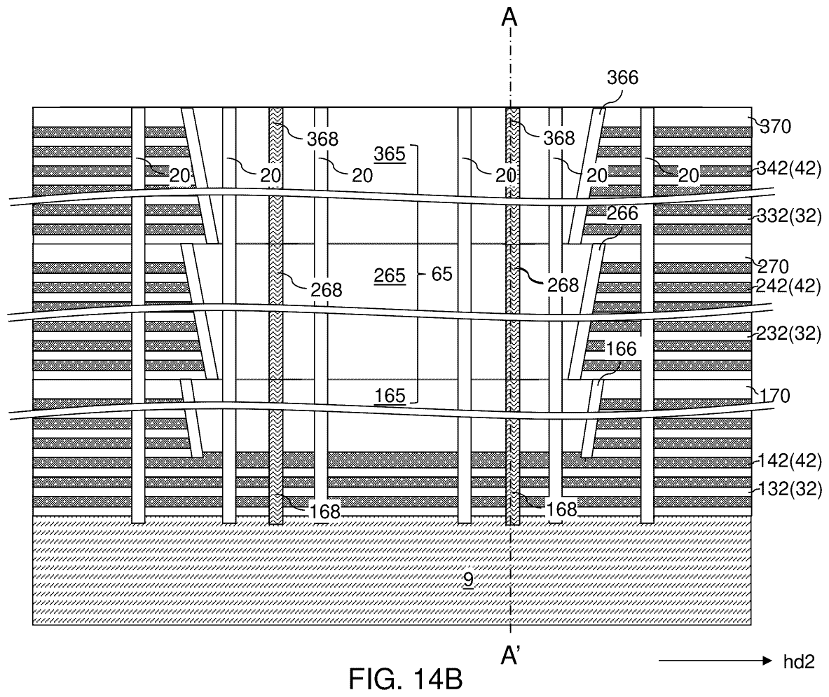

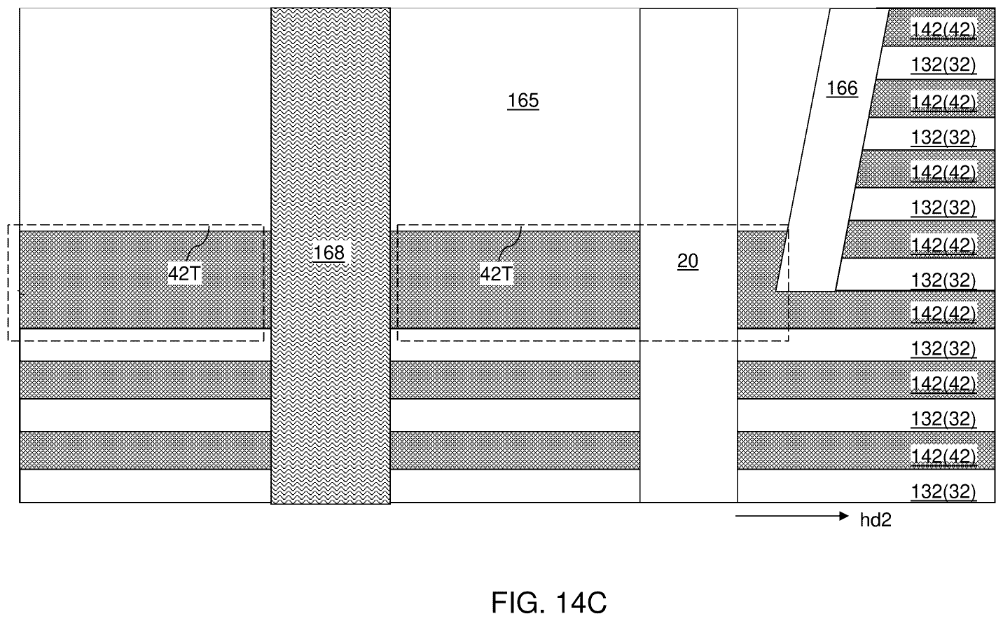

Referring to FIGS. 14A-14C, the first exemplary structure is illustrated after the processing steps of FIG. 13F, i.e., after formation of the memory opening fill structures 58 in the memory openings 49. In one embodiment, support pillar structures (not shown) may be formed in the support openings. Generally, each of the memory opening fill structures 58 comprises a respective vertical stack of memory elements located at levels of the electrically conductive layers 46 within the plurality of tier structures, and further comprises a respective vertical semiconductor channel 60 that vertically extends through the plurality of tier structures. Each memory opening fill structure 58 vertically extends from below a first horizontal plane HP1 including a bottommost surface of the at least one alternating stack (32, 42) to a second horizontal plane HP2 including the top surfaces of the memory opening fill structures 58.

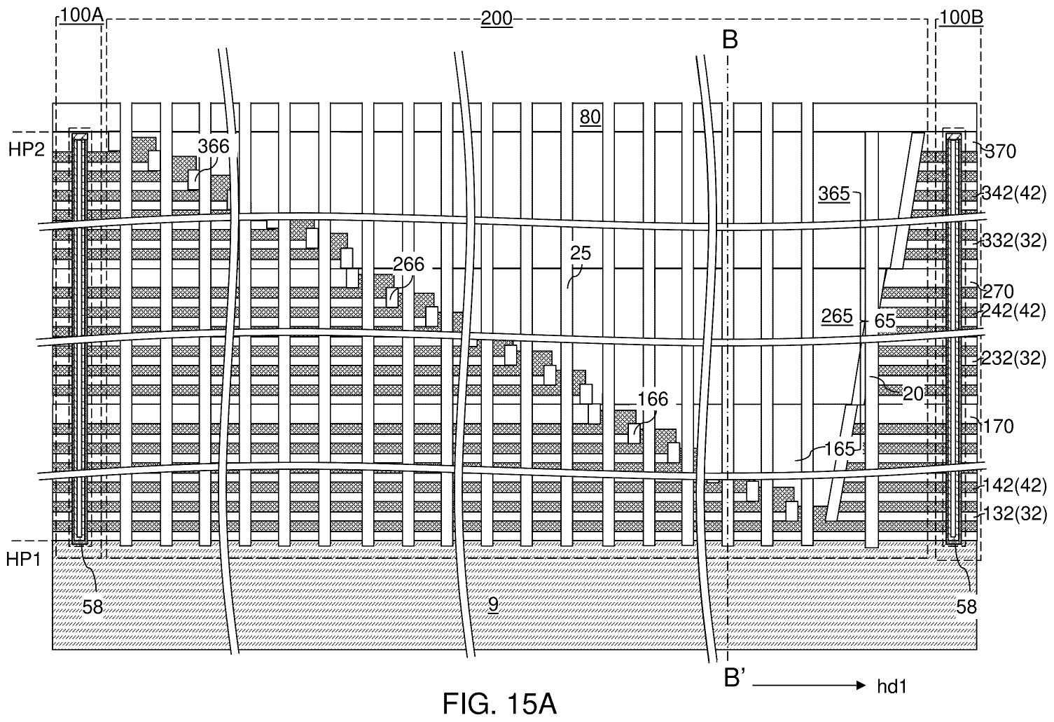

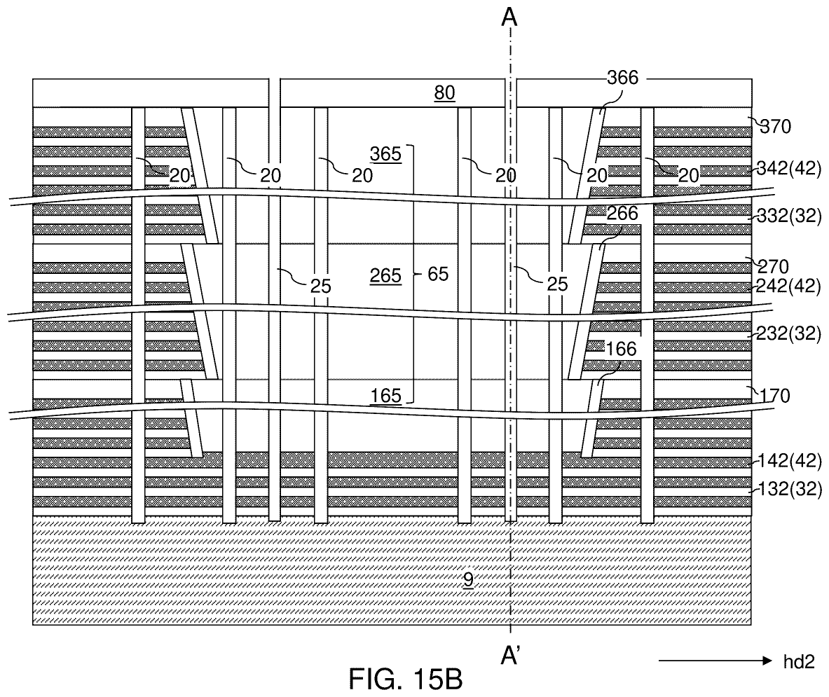

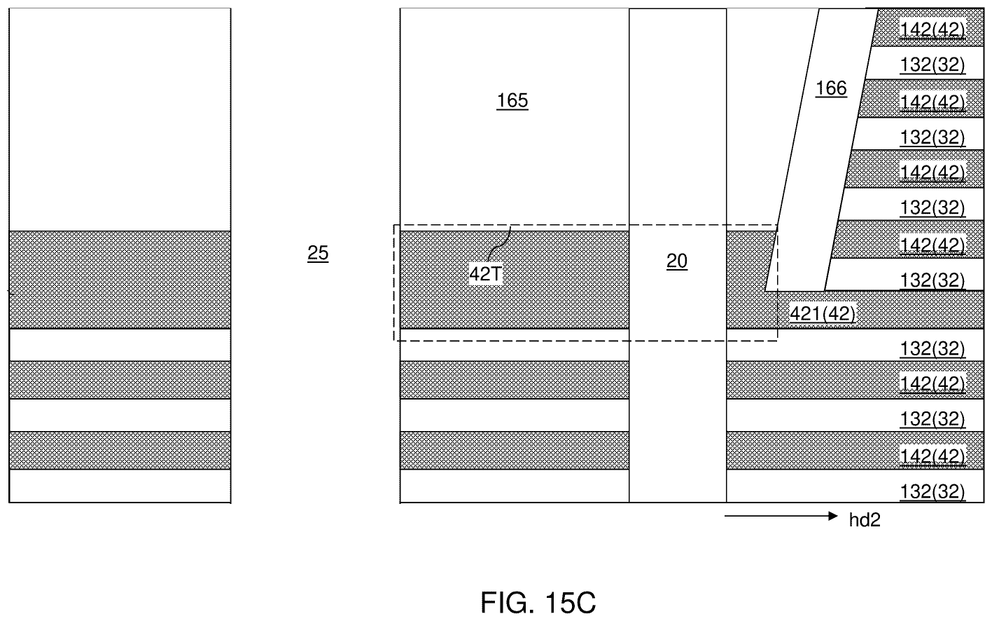

Referring to FIGS. 15A-15C, a contact-level dielectric layer 80 can be deposited over the third-tier insulating cap layer 370 and the third-tier retro-stepped dielectric material portions 365. The contact-level dielectric layer 80 comprises a dielectric material such as silicon oxide, and may have a thickness in a range from 100 nm to 800 nm, although lesser and greater thicknesses may also be employed.

Connection via openings can be formed through the contact-level dielectric layer 80 over the sacrificial third-tier contact opening fill structures 368. For example, a photoresist layer (not shown) can be applied over the contact-level dielectric layer 80, and can be lithographically patterned to form openings within the areas of the sacrificial third-tier contact opening fill structures 368. An anisotropic etch process can be performed to transfer the pattern of the openings in the photoresist layer through the contact-level dielectric layer 80. Subsequently, the sacrificial fill materials of the sacrificial third-tier contact opening fill structures 368, the sacrificial second-tier contact opening fill structures 268, and the sacrificial first-tier contact opening fill structures 168 can be removed selectively to the materials of the retro-stepped dielectric material portions 65, the insulating layers 32, the sacrificial material layers 42, and the support pillar structures 20. The photoresist layer may be removed simultaneously with, or after, removal of the sacrificial third-tier contact opening fill structures 368, the sacrificial second-tier contact opening fill structures 268, and the sacrificial first-tier contact opening fill structures 168. Contact via cavities 25 are formed in the volumes from which the materials of the sacrificial third-tier contact opening fill structures 368, the sacrificial second-tier contact opening fill structures 268, and the sacrificial first-tier contact opening fill structures 168 are removed. Each contact via cavity 25 vertically extends from the horizontal plane including the planar top surfaces of the third-tier retro-stepped dielectric material portion 365 to the substrate 9. Each contact via cavity 25 may vertically extend through a respective set of at least one insulating layer 32 and a respective set of at least one sacrificial material layer 42 of an alternating stack of insulating layers 32 and sacrificial material layers 42. Each contact via cavity 25 vertically extends through a thickened portion of the topmost sacrificial material layer within the respective set of at least one sacrificial material layer 42. Each contact via cavity 25 may have a width (e.g., diameter) in a range from 100 nm to 400 nm, although lesser and greater widths may also be employed.

Each contact via cavity 25 vertically extends through at least one retro-stepped dielectric material portion 65 and a subset of the sacrificial material layers 42 within the alternating stack (32, 42). In this case, the subset of the sacrificial material layers 42 comprises a first sacrificial material layer 421 which is a topmost sacrificial material layer 42 of the subset of the sacrificial material layers 42 and further comprises at least one second sacrificial material layer 42 (which may be a plurality of second sacrificial material layers 42) that underlie the first sacrificial material layer 421, as illustrated in FIG. 15C.

Each contact via cavity 25 can be formed through at least one retro-stepped dielectric material portion (165, 265, and/or 365), a respective subset of the sacrificial material layers 42 within an alternating stack (32, 42), and a respective subset of the insulating layers 32 within the alternating stack (32, 41). For each contact via cavity 25, the topmost layer among the subset of the sacrificial material layers 42 through which the contact via cavity 25 vertically extends comprises a first sacrificial material layer 421 having a first thickened region 42T. As noted above, the insulating sidewall spacers (166, 266, 366) may be either present or omitted, depending on which sacrificial material layer 42 thickening method is used in the prior steps.

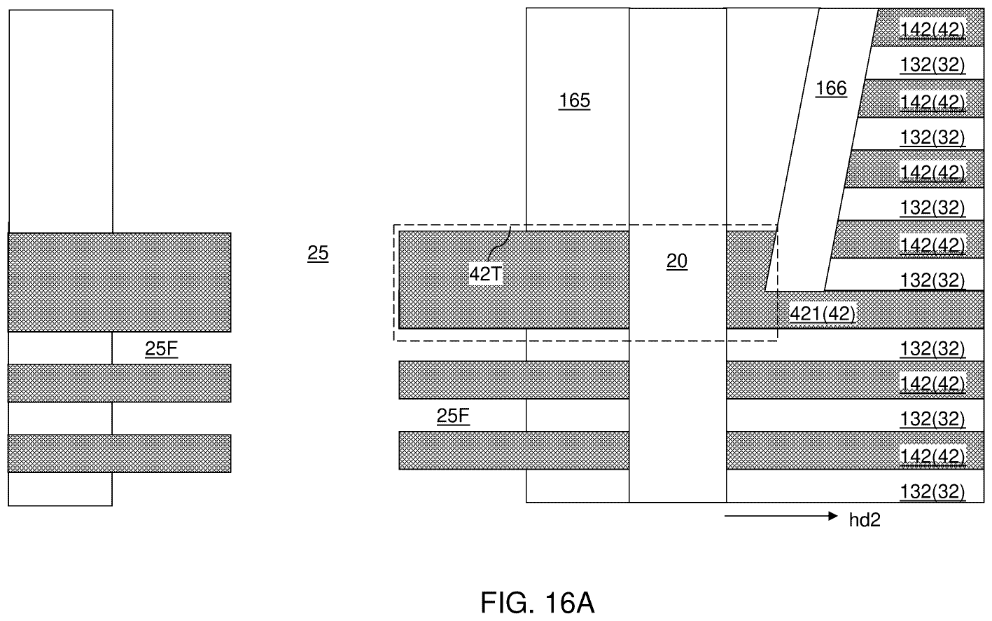

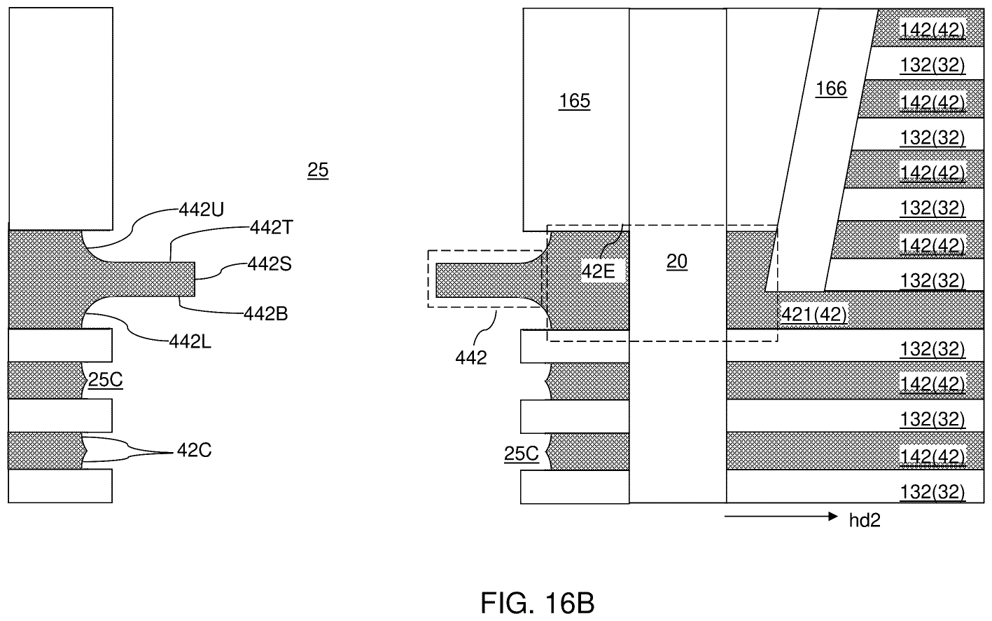

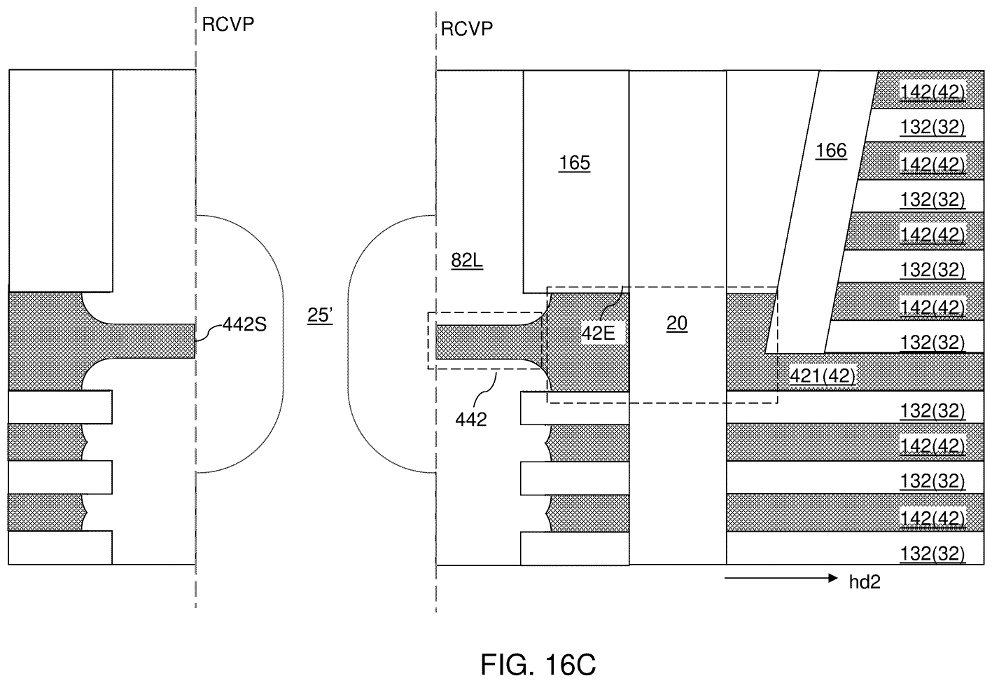

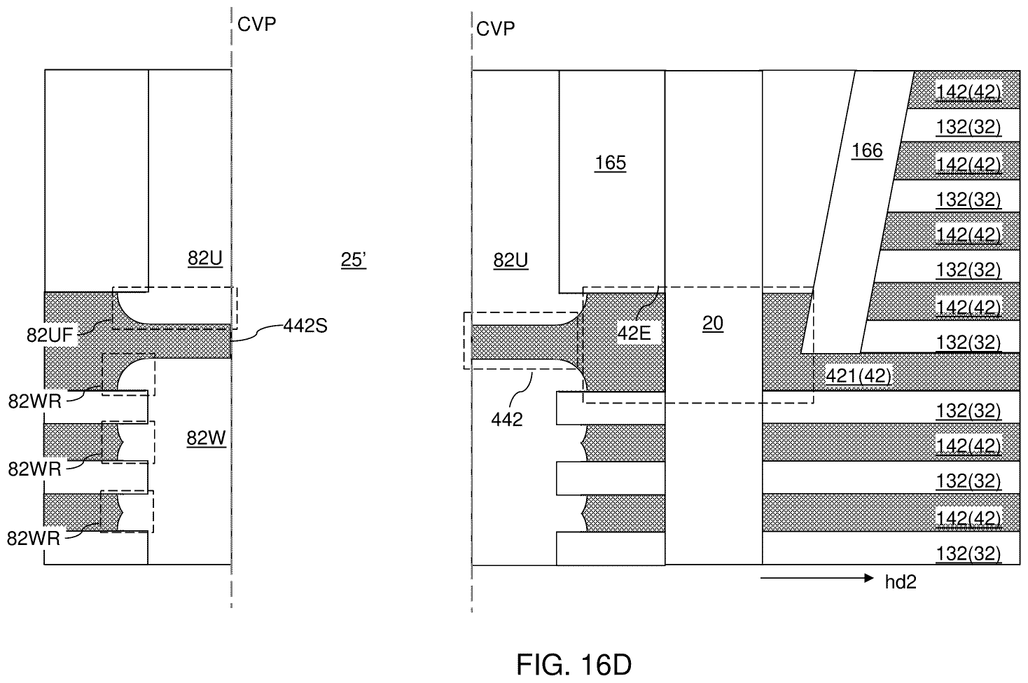

FIGS. 16A-16D are sequential vertical cross-sectional views of a region of the first exemplary structure during a sequence of processing steps for isotropically recessing the insulating layers 32 and the retro-stepped dielectric material portions (165, 265, or 365), for isotropically recessing the sacrificial material layers 42, and for formation of tubular dielectric spacers (82U, 82W) according to the first embodiment of the present disclosure.

Referring to FIG. 16A, a first isotropic etch process can be performed to isotropically etch the material of the insulating layers 32 selectively to the material of the sacrificial material layers 42. For example, if the insulating layers 32 comprise a silicate glass material, the first isotropic etch process may comprise a wet etch process employing dilute hydrofluoric acid. The duration of the first isotropic etch process may be selected such that the etch distance of the first isotropic etch process is in a range from 80% to 1,000%, such as from 150% to 500%, of the thickness of each insulating layer 32. Each of the insulating layers 32 can be laterally recessed around each of the contact via cavities 25. In one embodiment, each of the at least one retro-stepped dielectric material portion (165, 265, and 365) comprises a silicate glass material, physically exposed cylindrical sidewalls of the at least one retro-stepped dielectric material portion (165, 265, and 365) may be collaterally laterally recessed during the first isotropic etch process. In one embodiment, if the at least one retro-stepped dielectric material portion (165, 265, and 365) comprises a same silicate glass material as the insulating layers 32, the lateral recess distance for the sidewalls of the at least one retro-stepped dielectric material portion (165, 265, and 365) may be the same as the lateral recess distance of the cylindrical sidewalls of the insulating layers 32 that are exposed to the contact via cavity 25. Each of the contact via cavities 25 may comprise a respective set of at least one fin-shaped annular cavity portion 25F that is formed by lateral recessing of at least one insulating layer 32. The widths of the fin-shaped annular cavity portions 25F may be in a range from 50 nm to 150 nm, although lesser and greater widths may also be employed.

Referring to FIG. 16B, a second isotropic etch process can be performed to etch the material of the sacrificial material layers 42 selectively to the materials of the insulating layers 32 and the at least one retro-stepped dielectric material portion (165, 265, and/or 365). For example, if the sacrificial material layers 42 comprise silicon nitride and if the insulating layers 32 comprise silicon oxide, the second isotropic etch process may comprise a wet etch process employing hot phosphoric acid. In one embodiment, the etch distance of the second isotropic etch process for the material of the sacrificial material layers 42 is greater than one half of the thickness of the nominal thickness regions of the sacrificial material layers 42, and is less than one half of the thickness of the thickened regions 42T of the sacrificial material layers 42. In one embodiment, the sacrificial material layers 42 may be recessed by a greater amount than the insulating layers 32 such that fin-shaped annular cavity portions 25F at levels of the insulating layers 32 between the sacrificial material layers 42 are eliminated. Instead, new fin-shaped annular cavity portions 25C are formed at levels of the sacrificial material layers 42 between the insulating layers 32.

For each contact via cavity 25, a respective first sacrificial material layer 421 having a respective first thickened region 42T can be physically exposed to the contact via cavity 25. After the second isotropic etch process, a remaining portion of the first thickened region 42T comprises an annular thinned region 442 that is laterally surrounded by an enclosure region 42E which comprises a portion of the first thickened region 42T that is not thinned by the second isotropic etch process. The thickness of the annular thinned region 442 may be in a range from 15 nm to 50 nm, although lesser and greater thicknesses may also be employed. Each annular thinned region 442 may comprise a cylindrical sidewall 442S, a planar annular top surface 442T segment having an inner periphery that is adjoined to a top periphery of the cylindrical sidewall 442S, a planar annular bottom surface segment 442B having an inner periphery that is adjoined to a bottom periphery of the cylindrical sidewall 442S, a tapered concave upper surface segment 442U having a vertically-concave profile and a horizontally concave profile and having a bottom periphery that is adjoined to an outer periphery of the planar annular top surface segment 442T, and a tapered concave lower surface segment 442L having a vertically-concave profile and a horizontally concave profile and having a top periphery that is adjoined to an outer periphery of the planar annular bottom surface segment 442B. In one embodiment, the radius of curvature of the vertically-concave profiles of the tapered concave upper surface segment 442U and the tapered concave lower surface segment 442L may be the same as the etch distance of the second isotropic etch process for the material of the sacrificial material layers 42.

For each contact via cavity 25, a subset of the sacrificial material layers 42 are physically exposed to the contact via cavity 25. A topmost layer within the subset of the sacrificial material layers 42 is referred to herein as the first sacrificial material layer 421 for the contact via cavity 25. In one embodiment, physically exposed surfaces of the sacrificial material layers 42 other than the first sacrificial material layer 421 within the subset of the sacrificial material layers 42 are recessed farther outward relative to sidewalls of the subset of insulating layers 32 after performing the second isotropic etch process. Each of the sacrificial material layers 42 other than the first sacrificial material layer 421 may comprise a pair of tapered concave annular surface segments 42C that are adjoined to each other within a horizontal plane at a circular edge. In one embodiment, each of the tapered concave annular surface segments may have a respective vertically-concave profile and a respective horizontally concave profile.

Referring to FIG. 16C, a dielectric spacer material layer 82L may be conformally deposited in peripheral regions of the contact via cavities 25. The dielectric spacer material layer 82L comprise a dielectric material that is different from the material of the sacrificial material layers 42. In one embodiment, the dielectric spacer material layer 82L comprises silicon oxide. The thickness of the dielectric spacer material layer 82L may be selected such that inner cylindrical surface segments of the dielectric spacer material layer 82L within the volume of a contact via cavity 25 are formed at or inside a respective reference cylindrical vertical plane RCVP that includes a cylindrical sidewall 442S of the annular thinned region 442 around the contact via cavity 25. The dielectric spacer material layer 82L also fills the fin-shaped annular cavity portions 25C. A width of the dielectric spacer material layer 82L may be in a range from 20 nm to 150 nm, although lesser and greater widths may also be employed. A void 25′ having a neck portion can be present within each volume of a contact via cavity 25 after formation of the dielectric spacer material layer 82L.

Referring to FIG. 16D, an anisotropic etch process can be performed to remove unmasked portions of the dielectric spacer material layer 82L. The duration of the anisotropic etch process can be selected such that portions of the dielectric spacer material layer 82L located within each cylindrical volume defined by cylindrical vertical planes CVP containing inner sidewalls of vertically extending portions of the dielectric spacer material layer 82L are removed within each volume of the contact via cavities 25. Remaining portions of the dielectric spacer material layer 82L within the volume of each contact via cavity 25 (as formed at the processing steps of FIG. 16B) comprise an upper tubular dielectric spacer 82U and a lower tubular dielectric spacer 82W. A cylindrical sidewall 442S of an annular thinned region 442 of a respective first sacrificial material layer 421 is exposed between the upper tubular dielectric spacer 82U and the lower tubular dielectric spacer 82W.

Generally, an upper tubular dielectric spacer 82U can be formed within a peripheral region of each contact via cavity 25 (as formed at the processing steps of FIG. 16B) above the annular thinned region 442 of the first sacrificial material layer 421, and a lower tubular dielectric spacer 82W can be formed within the peripheral region of each contact via cavity 25 below the annular thinned region 442 of the first sacrificial material layer 421. In one embodiment, a retro-stepped dielectric material portion (165, 265 or 365) overlies a portion of each alternating stack (32, 42). In one embodiment, the upper tubular dielectric spacer 82U comprises an outer sidewall that vertically extends from a horizontally-extending surface segment of a stepped bottom surface of the retro-stepped dielectric material portion (165, 265, or 365) to a topmost surface of the retro-stepped dielectric material portion (165, 265, or 365).

In one embodiment, the upper tubular dielectric spacer 82U comprises an annular base flange portion 82UF located in the uppermost fin-shaped annular cavity portion 25C. The annular base flange portion 82UF is thicker than the overlying cylindrical portion of the upper tubular dielectric spacer 82U. The annular base flange portion 82UF has an annular planar horizontal top surface, an annular convex tapered sidewall, and an annular planar horizontal bottom surface. In one embodiment, an inner cylindrical sidewall of the lower tubular dielectric spacer 82W and an inner cylindrical sidewall of the upper tubular dielectric spacer 82U are located within a cylindrical vertical plane CVP.

In one embodiment, the lower tubular dielectric spacer 82W comprises annular rib portions 82WR located in the remaining fin-shaped annular cavity portions 25C. The annular rib portions 82WR are thicker than the remaining cylindrical portion of the lower tubular dielectric spacer 82W. Each of the annular rib portions 82WR laterally protrudes outward into the fin-shaped annular cavity portions 25C. In one embodiment, each of the annular rib portions 82WR except a topmost annular rib portion 82WR comprises a pair of annular convex surfaces that are adjoined to each other at a closed edge located within a respective horizontal plane (i.e., adjoined at a point in a vertical plane).

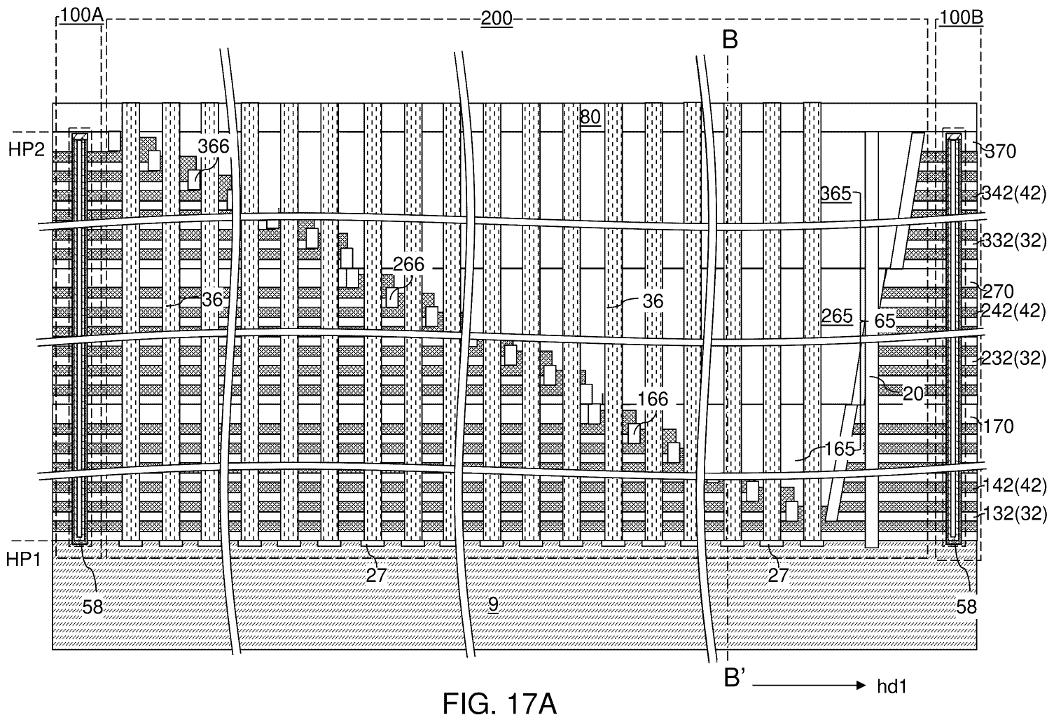

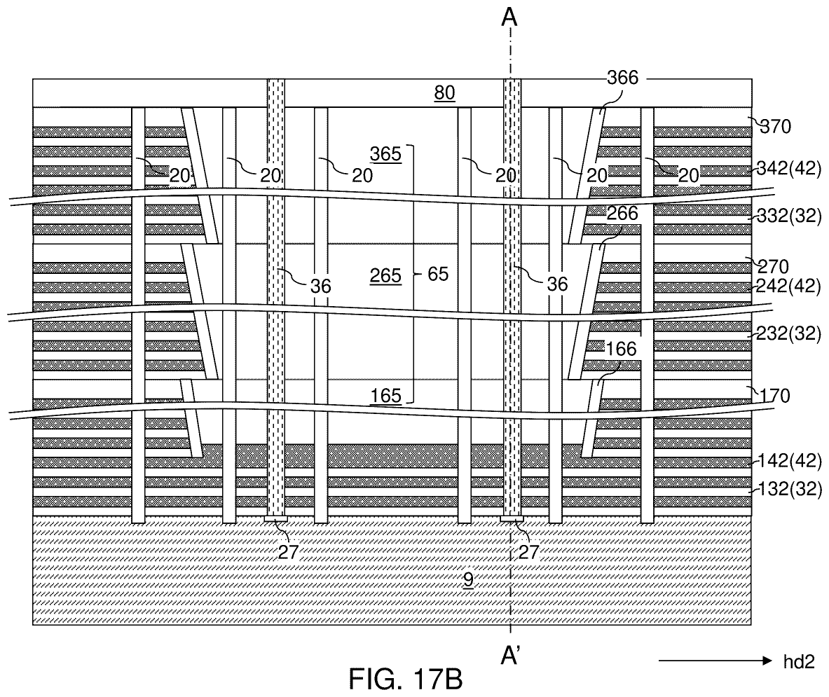

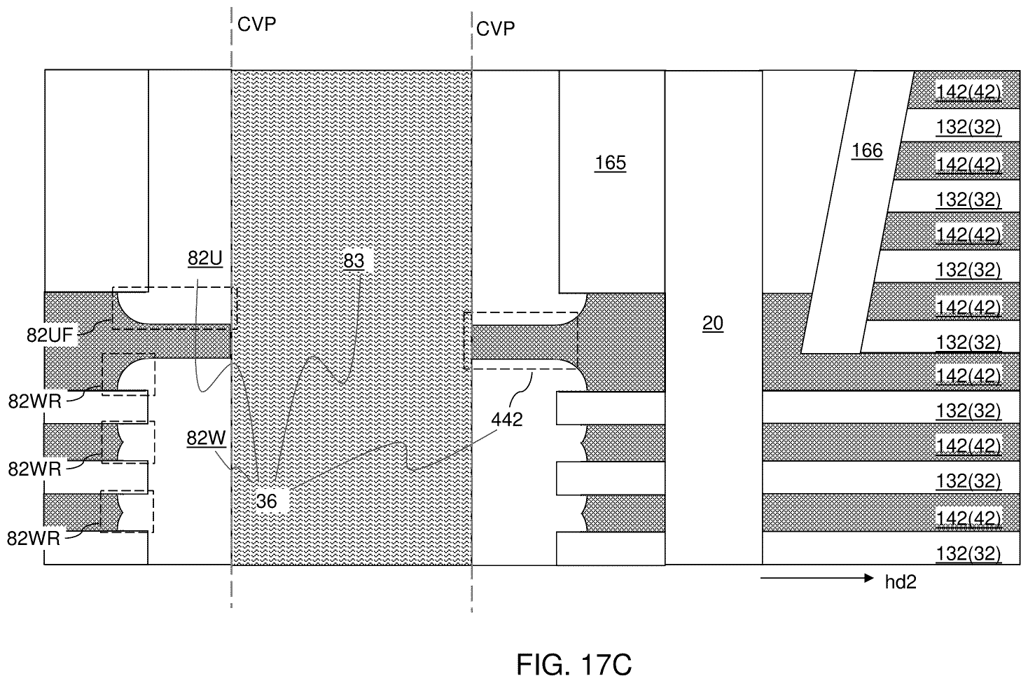

Referring to FIGS. 17A-17C, an optional oxidation process can be performed to convert surface portions of the substrate 9 underlying the voids 25′ into semiconductor oxide plates 27 (such as silicon oxide plates). A sacrificial via fill material can be deposited in the volumes of the voids in the contact via cavities. Excess portions of the sacrificial via fill material can be removed from above the horizontal plane including the top surface of the contact-level dielectric layer 80. Each remaining portion of the sacrificial via fill material constitutes a sacrificial via fill structure 83. The sacrificial via fill structures 83 may comprise a semiconductor material (such as silicon or silicon-germanium, a carbon-based material (such as amorphous carbon or diamond-like carbon), a high-etch-rate silicate glass material (such as porous organosilicate glass), a polymer material, or any other material that may be subsequently removed selectively to the materials of the upper tubular dielectric spacers 82U and the lower tubular dielectric spacers 82W. Each contiguous combination of a sacrificial via fill structure 83, an upper tubular dielectric spacer 82U, a lower tubular dielectric spacer 82W, and an annular thinned region 442 constitutes an in-process contact-via-region assembly 36, as shown in FIG. 17C.

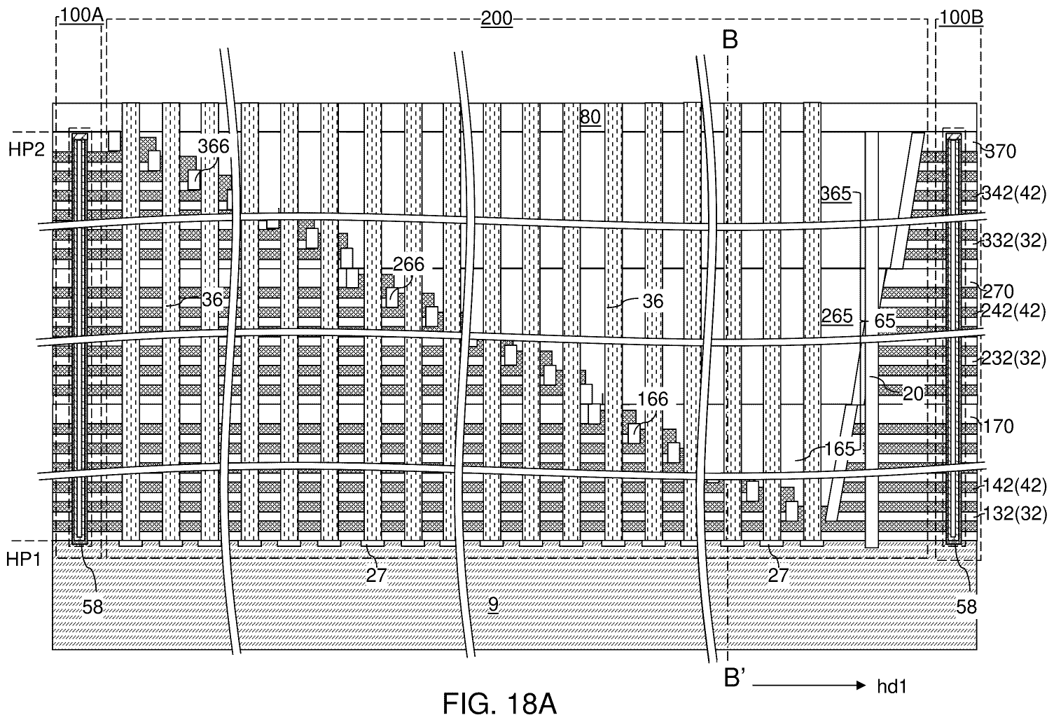

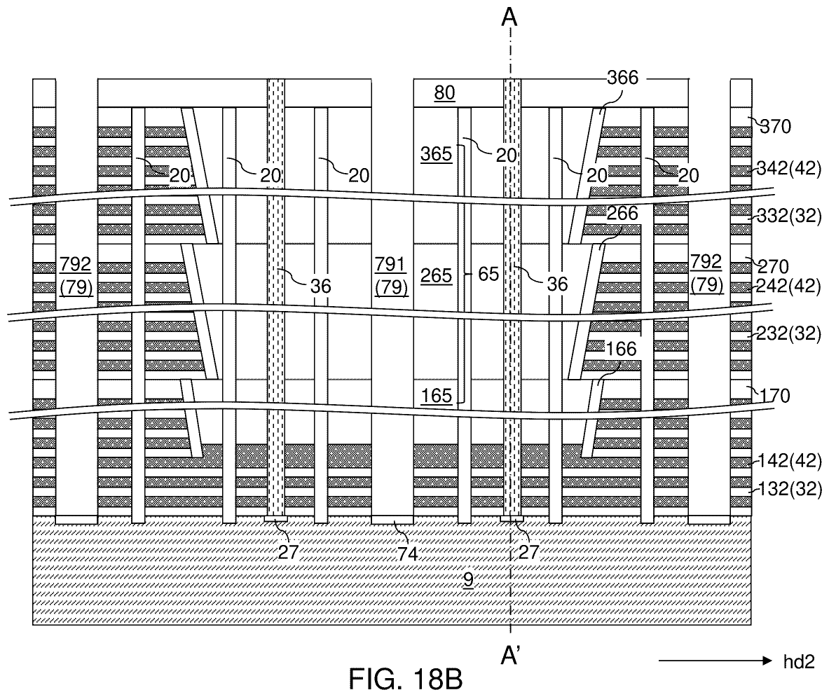

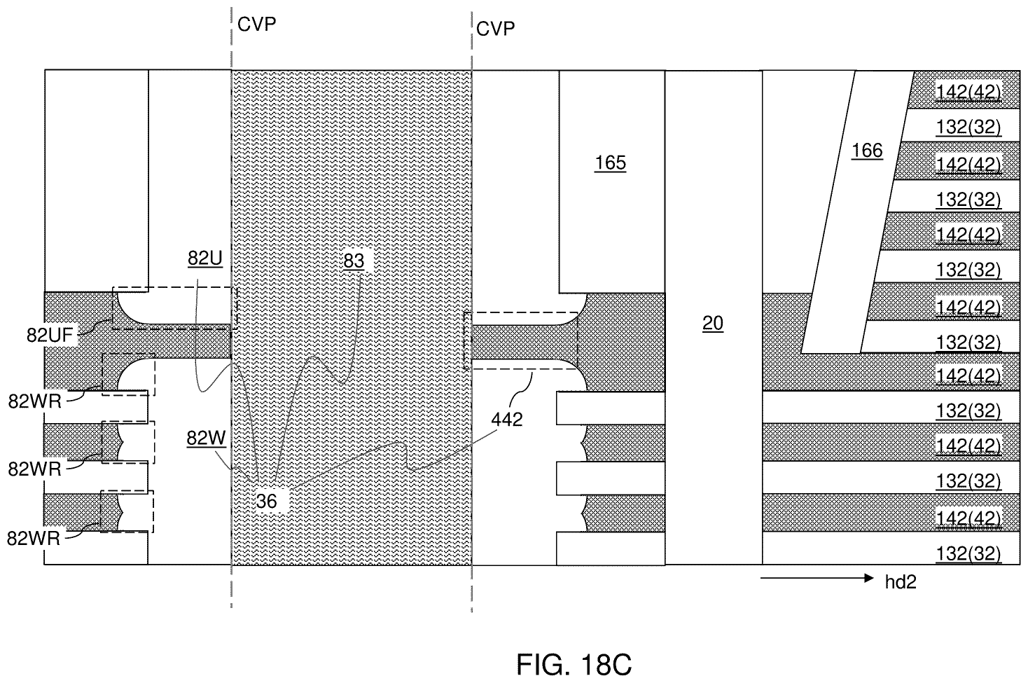

Referring to FIGS. 18A-18C, a masking layer, such as a photoresist layer and/or a carbon patterning film can be applied over the contact-level dielectric layer 80, and can be lithographically patterned to form elongated openings that laterally extend along the first horizontal direction hd1. The elongated openings can be formed in areas in which the memory opening fill structure 58, the support pillar structures 20, and the contact via cavities 25 are not present. An anisotropic etch process can be performed to transfer the pattern of the elongated openings through the contact-level dielectric layer 80 and the vertically alternating sequences (32, 42) of the insulating layers 32 and the sacrificial material layers 42.

Lateral isolation trenches 79 can be formed in the voids formed by removal of the material portions of the contact-level dielectric layer 80 and the vertically alternating sequences. Each of the vertically alternating sequences is divided into a respective set of alternating stacks {(132, 142), (232, 242), (332, 342)} of insulating layers 32 and sacrificial material layers 42 that are laterally spaced apart along a second horizontal direction hd2. For example, the first vertically alternating sequence is divided into first-tier alternating stacks of first-tier insulating layers 132 and first-tier sacrificial material layers 142; the second vertically alternating sequence is divided into second-tier alternating stacks of second-tier insulating layers 232 and second-tier sacrificial material layers 242; and the third vertically alternating sequence is divided into third-tier alternating stacks of third-tier insulating layers 332 and third-tier sacrificial material layers 342. The locations of the lateral isolation trenches 79 may be the same as the locations of the lateral isolation trench fill structures 76 illustrated in FIGS. 1A-1E.

The lateral isolation trenches 79 may comprise first lateral isolation trenches 791 that cut through the retro-stepped dielectric material portion (165, 265, 365) and second lateral isolation trenches 792 that do not cut through the retro-stepped dielectric material portion (165, 265, 365). In one embodiment, each first lateral isolation trench 791 divides each retro-stepped dielectric material portion (165, 265, 365) into a respective pair of retro-stepped dielectric material portions (such as first-tier retro-stepped dielectric material portions 265, second-tier retro-stepped dielectric material portions 265 and/or third-tier retro-stepped dielectric material portions 365). Generally, a plurality of tier structures that are vertically stacked can be formed over a substrate 9. Each tier structure within the plurality of tier structures comprises a respective set of alternating stacks of insulating layers 32 and sacrificial material layers 42. The photoresist layer can be subsequently removed, for example, by ashing.

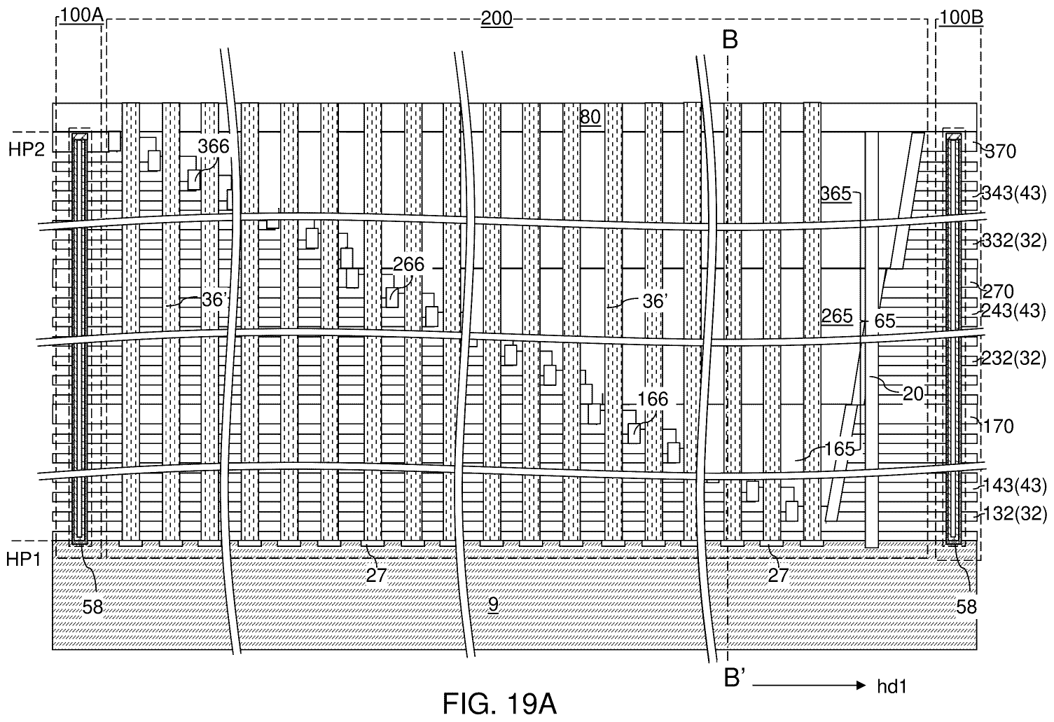

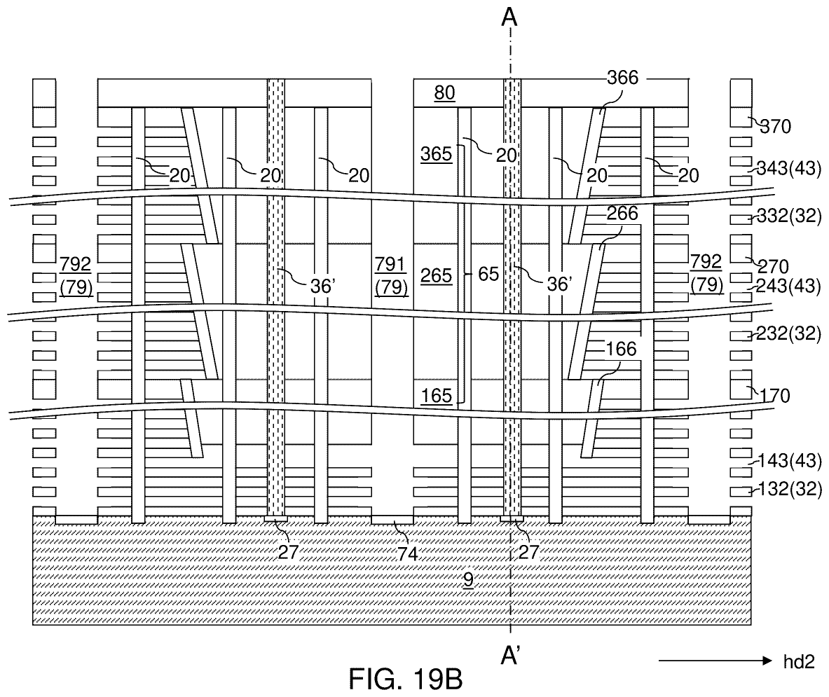

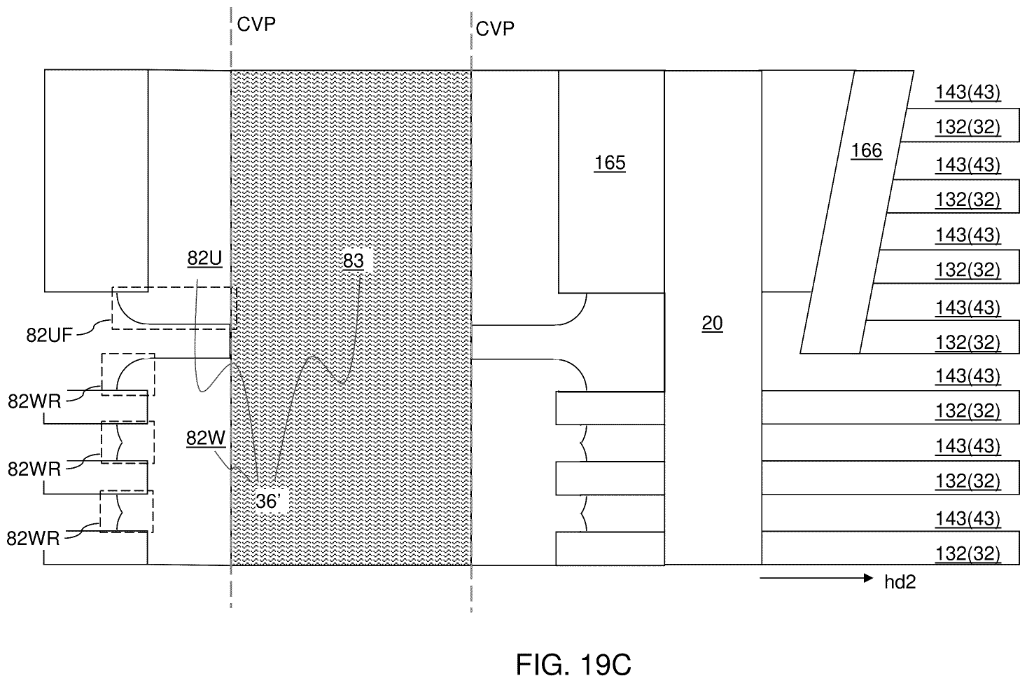

Referring to FIGS. 19A-19C, in case the substrate 9 comprises a semiconductor material, such as silicon, an oxidation process may be performed to convert physically exposed surface portions of the substrate 9 into semiconductor oxide spacer liners 74, such as silicon oxide spacers. The semiconductor oxide spacer liners 74 are formed underneath the lateral isolation trenches 79, and semiconductor oxide spacer liners 27 that are formed underneath the contact via cavities 25. The thickness of the semiconductor oxide spacer liners 74 may be in a range from 3 nm to 8 nm, although lesser and greater thicknesses may also be employed. In one embodiment, collateral oxidation of the physically exposed surfaces of the sacrificial material layers 42 may be minimized by reducing the thickness of the semiconductor oxide spacer liners 74.

The sacrificial material layers 42 may be isotropically etched selectively to the insulating layers 32, the sacrificial via fill structures 83, and the retro-stepped dielectric material portions 65 by supplying an isotropic etchant into the lateral isolation trenches 79. Specifically, the sacrificial material layers 42 may be isotropically etched selectively to the insulating layers 32, the retro-stepped dielectric material portions (165, 265, 365), the sacrificial via fill structures 83, and the substrate 9 by supplying an isotropic etchant into the lateral isolation trenches 79. Thus, the lateral isolation trenches 79 can be employed as conduits for supplying the isotropic etchant of the selective isotropic etch process. In one embodiment, an etchant that selectively etches the materials of the sacrificial material layers 42 with respect to the materials of the insulating layers 32, the retro-stepped dielectric material portions (165, 265, 365), the material of the sacrificial via fill structures 83, and the material of the outermost layer of the memory films 50 may be introduced into the lateral isolation trenches, for example, using an isotropic etch process.

The isotropic etch process may be a wet etch process using a wet etch solution, or may be a gas phase (dry) etch process in which the etchant is introduced in a vapor phase into the lateral isolation trench. For example, if the sacrificial material layers 42 comprise silicon nitride, and if the insulating layers 32, the retro-stepped dielectric material portions (165, 265, 365), and the outermost layer of the memory films 50 comprise silicon oxide materials, the etch process may comprise a wet etch tank employing hot phosphoric acid, which etches silicon nitride selectively to silicon oxide, silicon, and various other materials used in the art.

Lateral recesses 43 are formed in volumes from which the sacrificial material layers 42 are removed. The lateral recesses 43 include first lateral recesses 143 that are formed in volumes from which the first-tier sacrificial material layers 142 are removed, second lateral recesses 243 that are formed in volumes from which the second-tier sacrificial material layers 242 are removed, and third lateral recesses 343 that are formed in volumes from which the third-tier sacrificial material layers 342 are removed. Each of the lateral recesses 43 may be a laterally extending cavity having a greater lateral dimension that is greater than a vertical extent. In other words, the lateral dimension of each of the lateral recesses 43 may be greater than the height of the respective lateral recess. A plurality of lateral recesses 43 may be formed in the volumes from which the material of the sacrificial material layers 42 is removed. Each of the lateral recesses 43 may extend substantially parallel to the top surface of the substrate 9. A lateral recess 43 may be vertically bounded by a top surface of an underlying insulating layer 32 and a bottom surface of an overlying insulating layer 32.

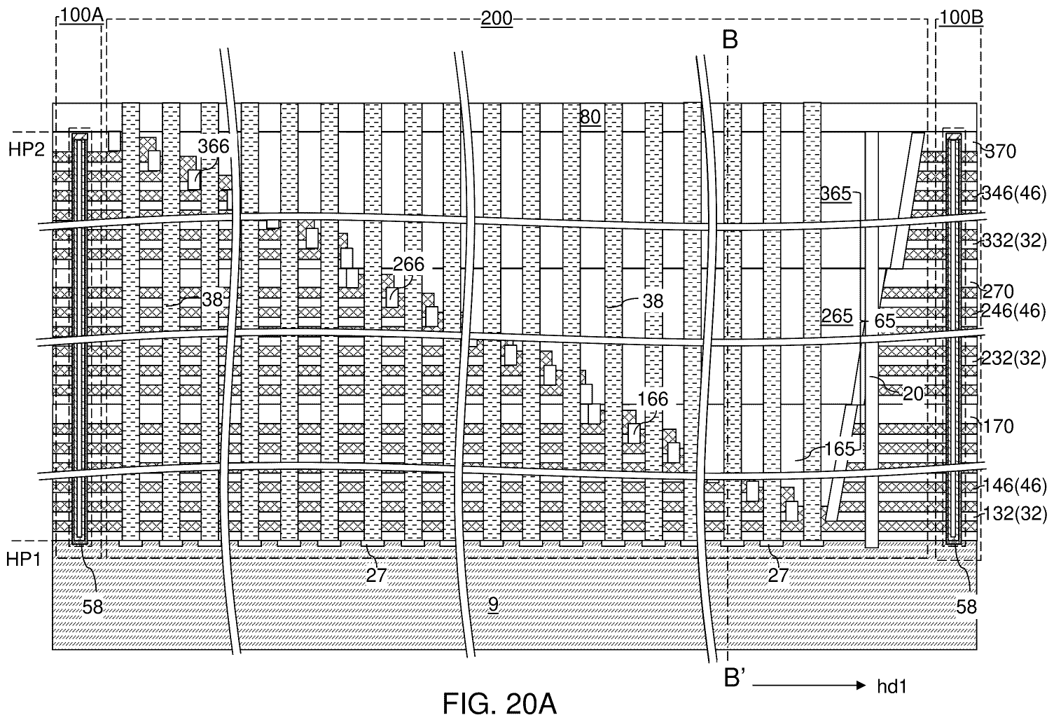

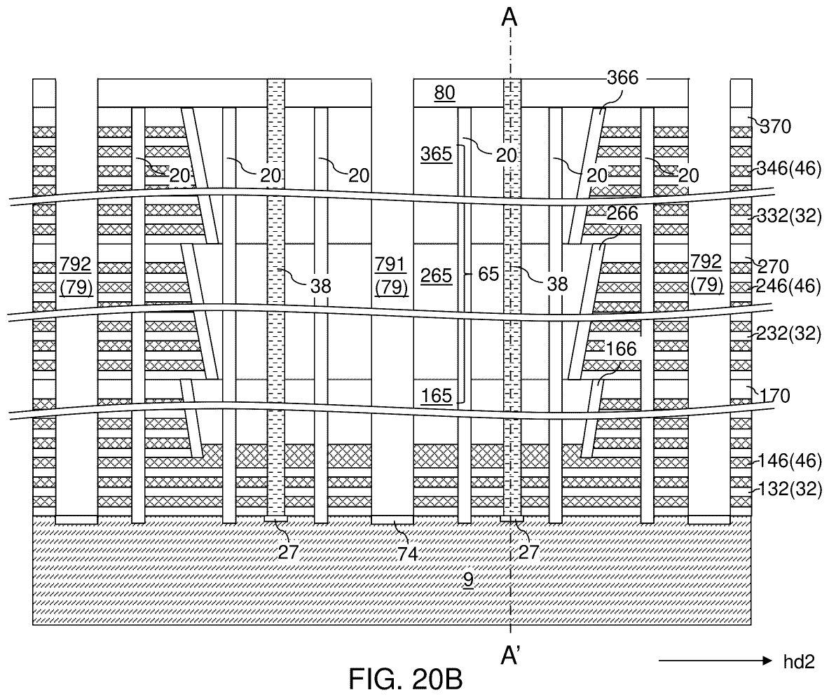

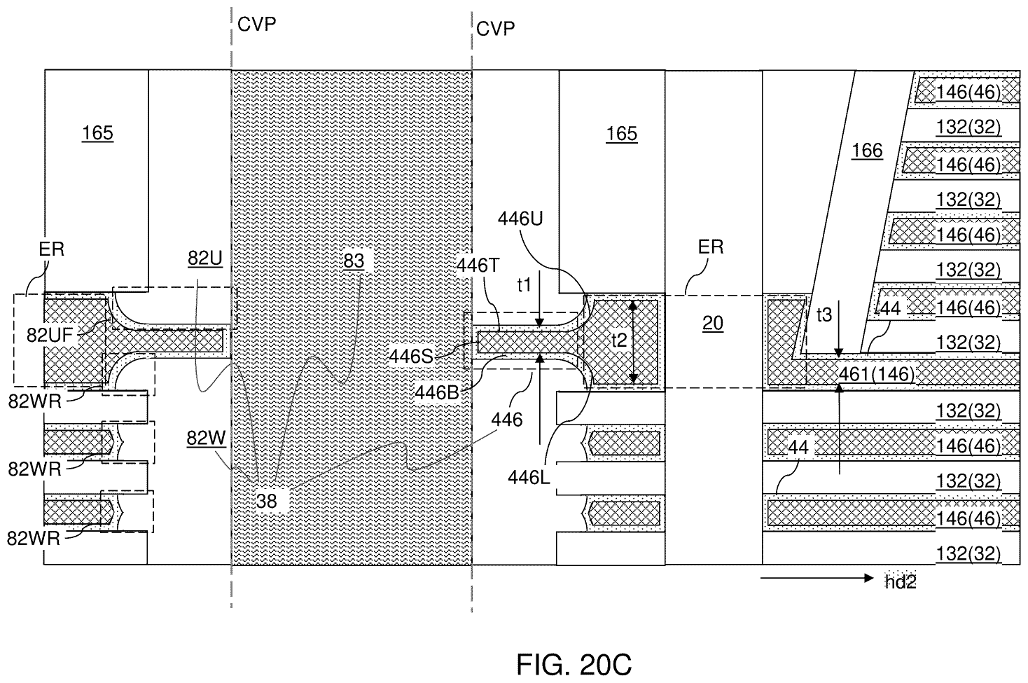

Referring to FIGS. 20A-20C, an outer blocking dielectric layer 44 may be conformally deposited in peripheral portions of the lateral recesses 43 and the lateral isolation trenches 79. The outer blocking dielectric layer 44 includes a dielectric material, such as a dielectric metal oxide (e.g., aluminum oxide, hafnium oxide, etc.). The outer blocking dielectric layer 44 may be formed as a continuous material layer by a conformal deposition process, such as an atomic layer deposition process or a chemical vapor deposition process. The thickness of the outer blocking dielectric layer 44 may be in a range from 2 nm to 10 nm, such as from 3 nm to 8 nm, although lesser and greater thicknesses may also be employed.

At least one electrically conductive material may be conformally deposited on the physically exposed surfaces of the outer blocking dielectric layer 44 in peripheral portions of the lateral recesses 43 and the lateral isolation trenches 79. The at least one electrically conductive material may comprise a combination of a metallic barrier material (such as TiN, TaN, WN, and/or MoN) and a metal fill material (such as W, Ti, Ta, Co, Ru, Mo, Cu, etc.) Portions of the at least one electrically conductive material that are deposited outside the lateral recesses 43 may be removed by performing an etch back process, which may comprise an isotropic etch process and/or an anisotropic etch process.

Remaining portions of at least one electrically conductive material comprise electrically conductive layers 46. The electrically conductive layers 46 comprise first-tier electrically conductive layers 146, second-tier electrically conductive layers 246, and third-tier electrically conductive layers 346. A plurality of first-tier electrically conductive layers 146 may be formed in the plurality of first lateral recesses 143, a plurality of second-tier electrically conductive layers 246 may be formed in the plurality of second lateral recesses 243, and a plurality of third-tier electrically conductive layers 346 may be formed in the plurality of third lateral recesses 343. Each of the electrically conductive layers 46 may include a respective metallic barrier liner and a respective metal fill material portion.

Each sacrificial via fill structure 83 can be contacted by a respective outer blocking dielectric layer 44 which embeds a respective electrically conductive layer 46, which is referred to as a first electrically conductive layer 461 for the sacrificial via fill structure 83. The first electrically conductive layer 461 comprises a respective annular thinned region 446 which contains a uniform-thickness annular region 446 having a first thickness t1, a respective enclosure region ER adjoined to a periphery of and laterally enclosing the respective annular thinned region 446 and having a second thickness t2 that is greater than the first thickness t1, and a respective uniform-thickness portion having a third thickness t3 and laterally surrounding the memory opening fill structures 58. The third thickness t3 may be less than the second thickness t2. The first thickness t1 may be in a range from 15 nm to 50 nm, such as from 20 nm to 40 nm, although lesser and greater thicknesses may also be employed. The second thickness t2 may be in a range from 40 nm to 100 nm, such as from 50 nm to 70 nm, although lesser and greater thicknesses may also be employed. The third thickness t3 may be in a range from 15 nm to 50 nm, such as from 20 nm to 30 nm, although lesser and greater thicknesses may also be employed. Each contiguous combination of a sacrificial via fill structure 83, an upper tubular dielectric spacer 82U, a lower tubular dielectric spacer 82W, an annular thinned region 446 of a respective first electrically conductive layer 461, and a portion of an outer blocking dielectric layer 44 adjacent to the annular thinned region 446 constitutes an in-process contact-via-region assembly 38.

In summary, lateral recesses 43 can be formed by removing the sacrificial material layers 42 selectively to the insulating layers 32 and the sacrificial via fill structures 83. A combination of a respective outer blocking dielectric layer 44 and a respective one of the electrically conductive layers 46 is located in each lateral recess 43. Thus, the sacrificial material layers 42 are replaced with a combination of electrically conductive layers 46 and outer blocking dielectric layers 44. For each sacrificial via fill structure 83, a first sacrificial material layer 421 that is proximal to the sacrificial via fill structure 83 is replaced with a respective first electrically conductive layer 461. The annular thinned region 446 of the first electrically conductive layer 461 may comprise a cylindrical sidewall 446S, a planar annular top surface segment 446T having an inner periphery that is adjoined to a top periphery of the cylindrical sidewall 446S, a planar annular bottom surface segment 446B having an inner periphery that is adjoined to a bottom periphery of the cylindrical sidewall 446S, a tapered concave upper surface segment 446U having a vertically-concave profile and a horizontally concave profile and having a bottom periphery that is adjoined to an outer periphery of the planar annular top surface segment 446T, and a tapered concave lower surface segment 446L having a vertically-concave profile and a horizontally concave profile and having a top periphery that is adjoined to an outer periphery of the planar annular bottom surface segment 446B.

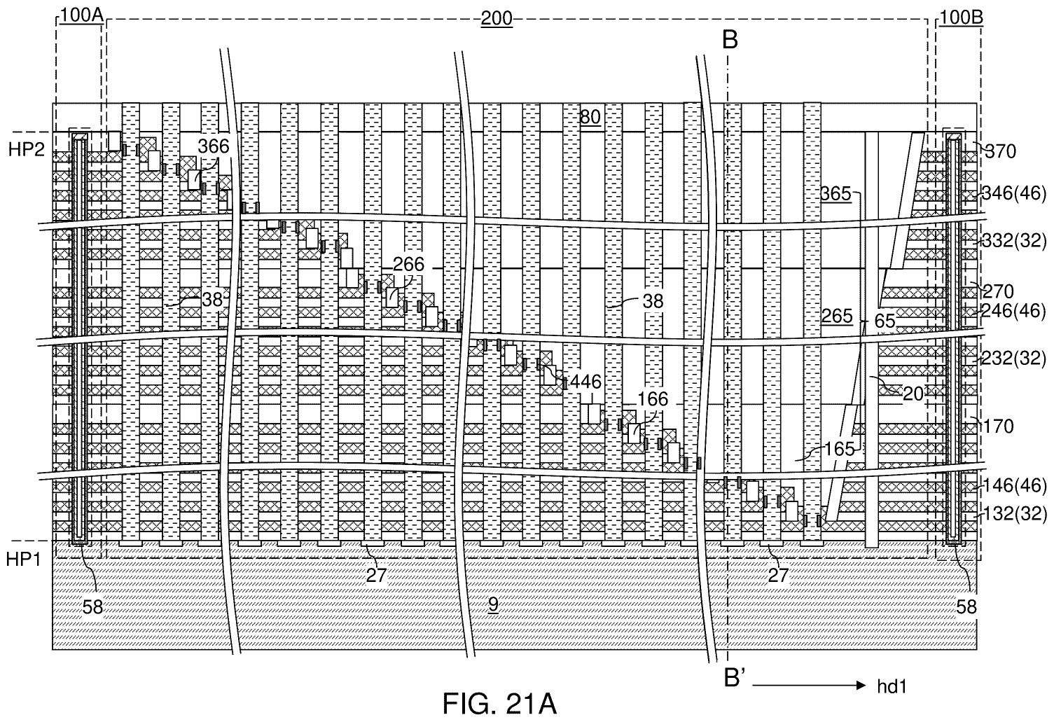

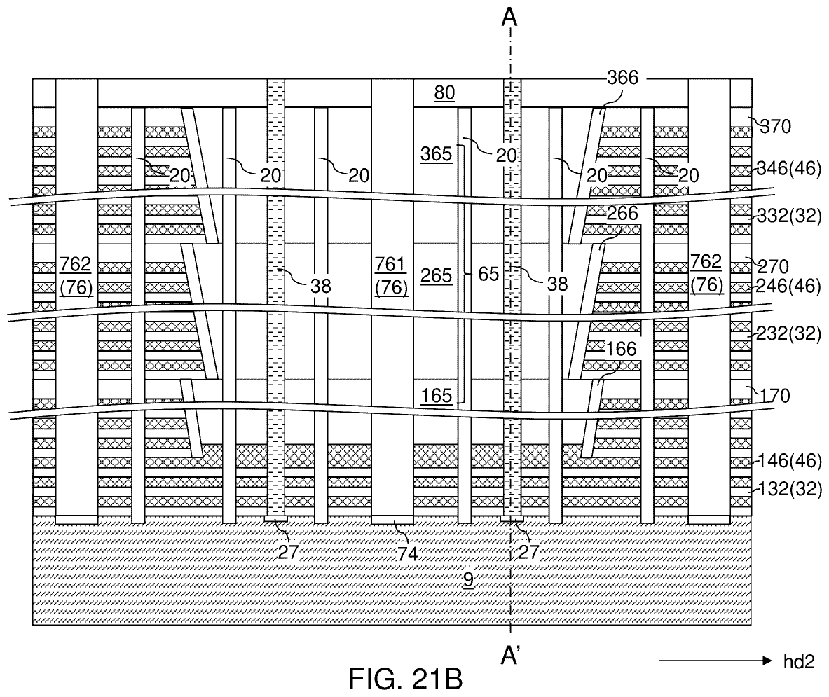

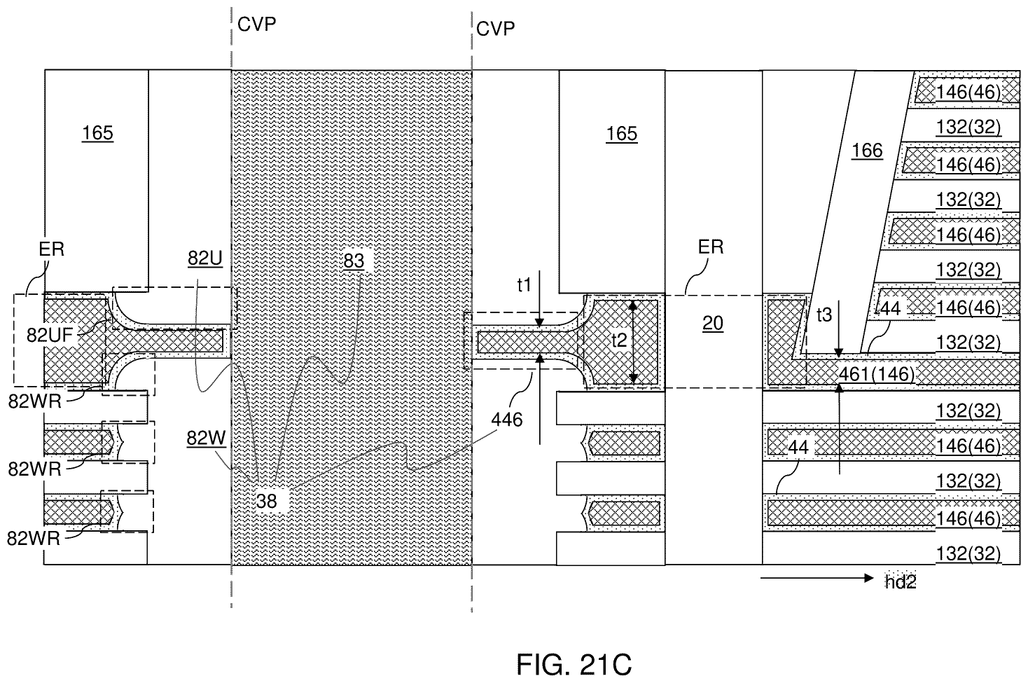

Referring to FIGS. 21A-21C, a dielectric fill material, such as undoped silicate glass or a doped silicate glass can be deposited in the lateral isolation trenches 79 by a conformal deposition process. A planarization process can be performed to remove the portion of the deposited dielectric fill material from above the horizontal plane including the top surface of the contact-level dielectric layer 80. The planarization process may comprise a recess etch process and/or a chemical mechanical polishing process. Each remaining portion of the dielectric fill material that fills a respective one of the lateral isolation trenches 79 constitute a lateral isolation trench fill structure 76.

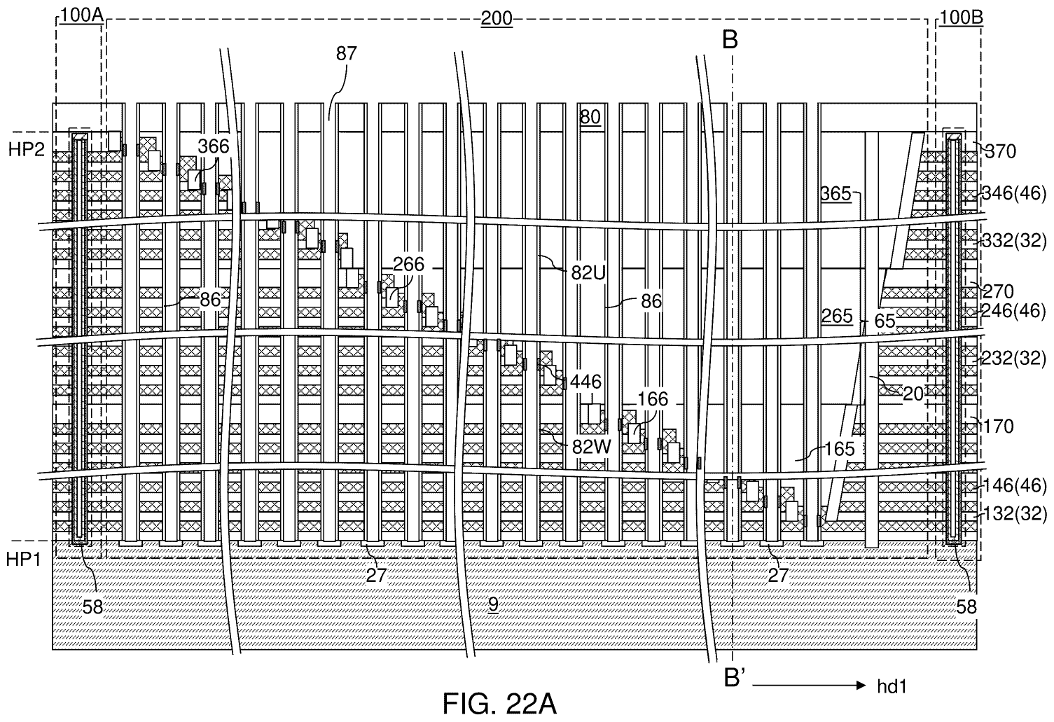

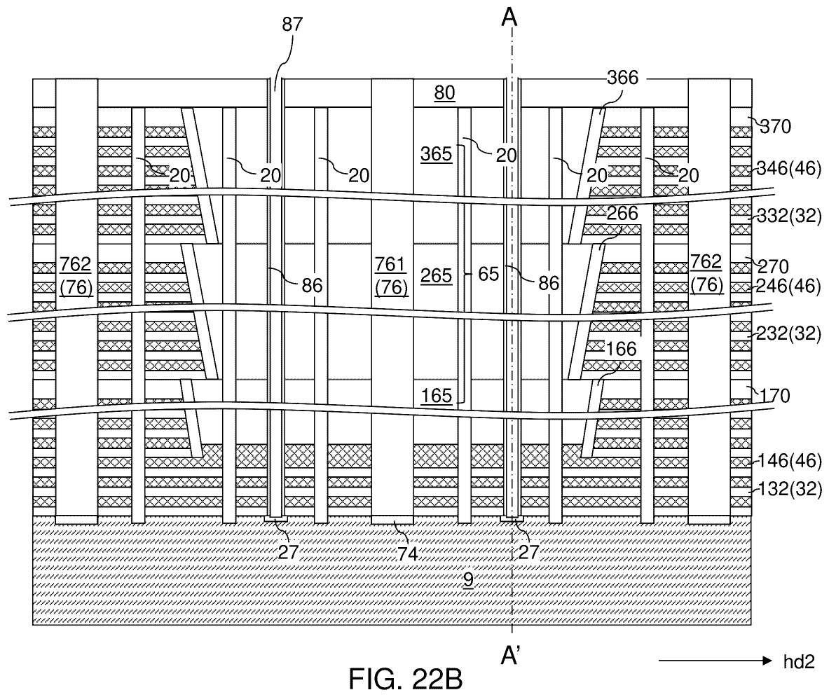

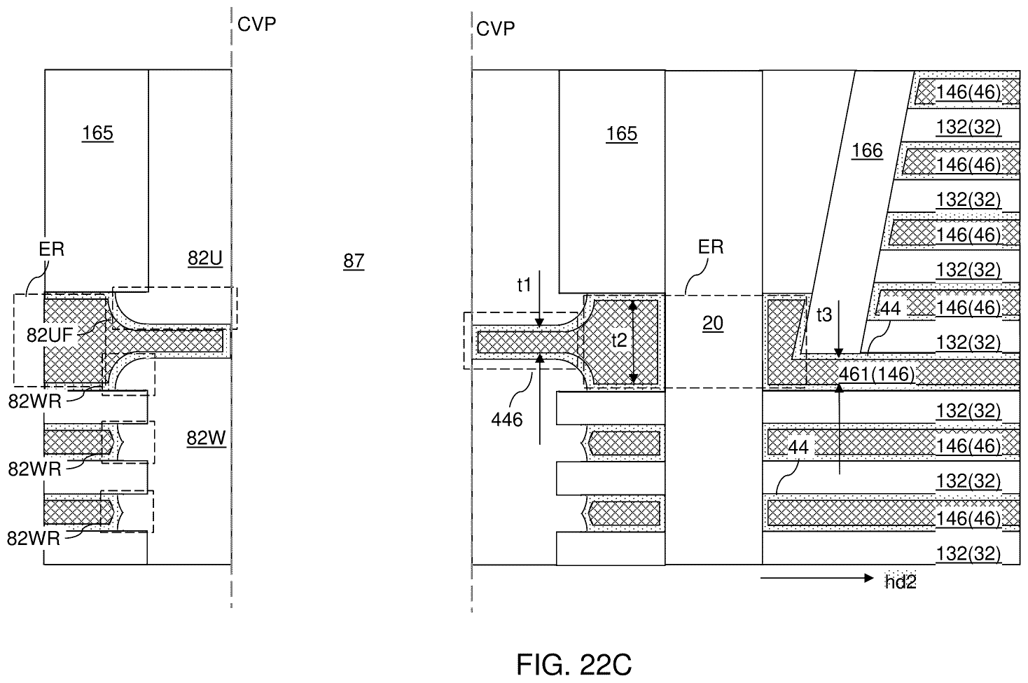

Referring to FIGS. 22A-22C, the sacrificial via fill structures 83 can be removed selectively to the contact-level dielectric layer 80 and the lateral isolation trench fill structures 76 by performing a selective removal process. Voids 87 are formed in the volumes from which the sacrificial via fill structures 83 are removed. The selective removal process may comprise a selective etch process or an ashing process.

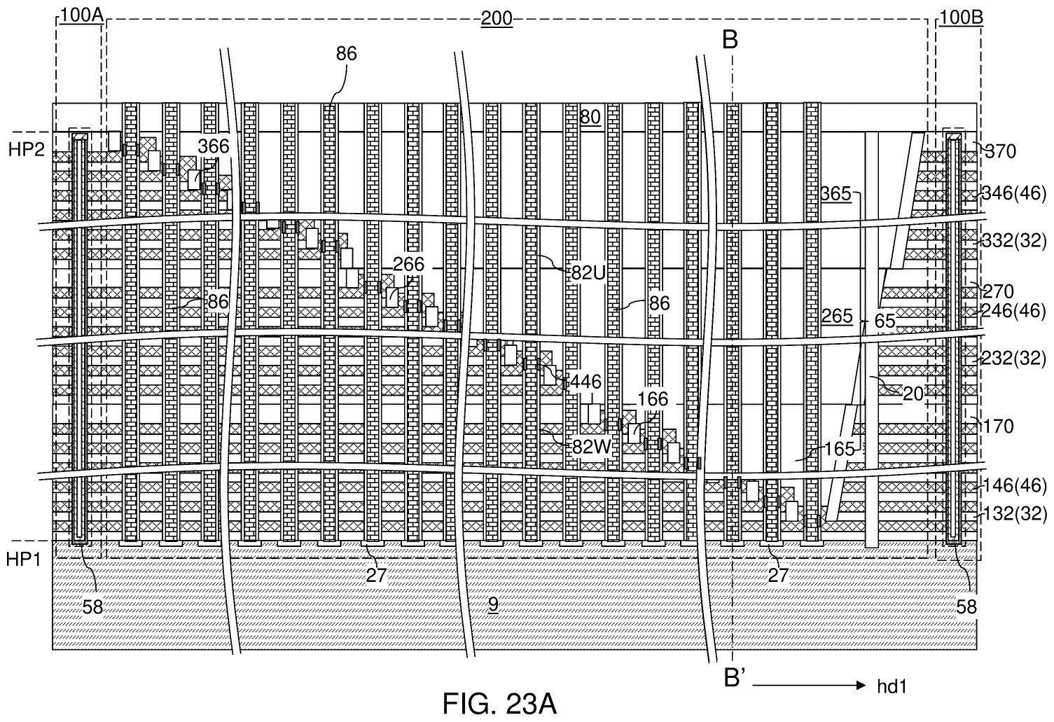

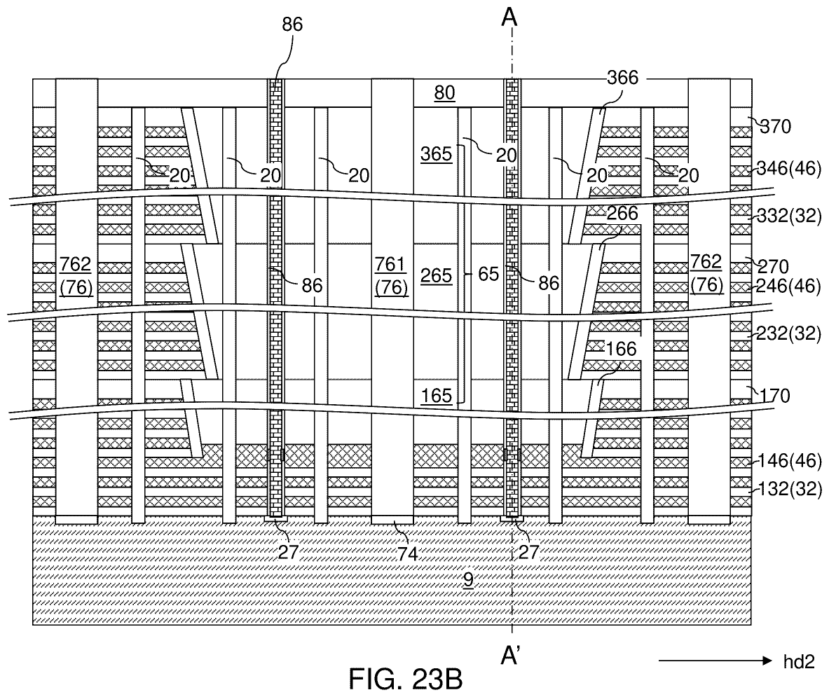

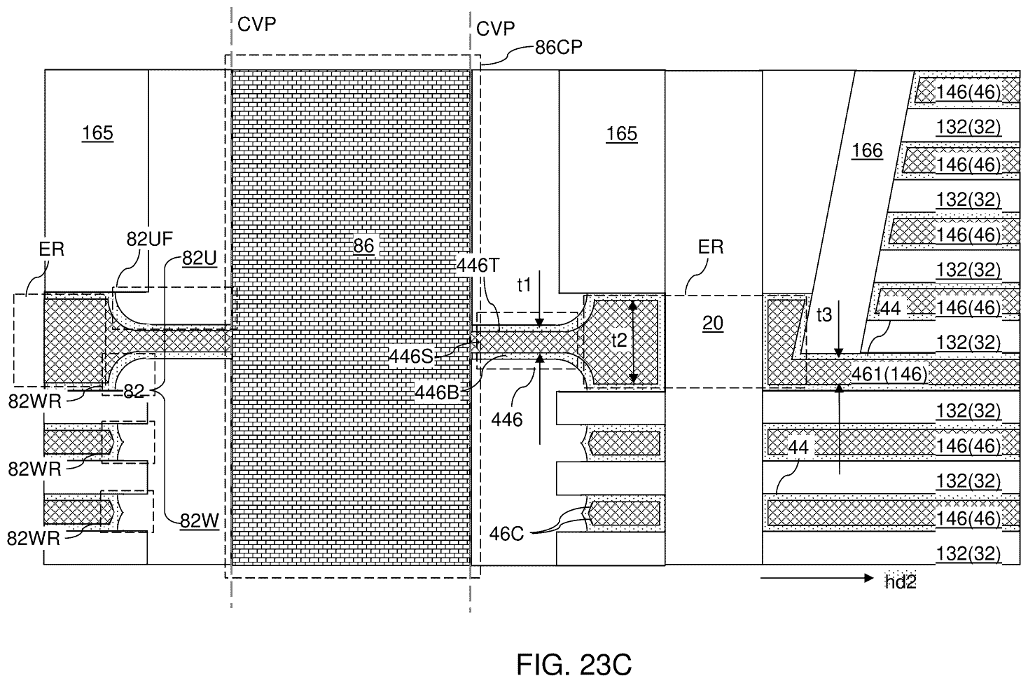

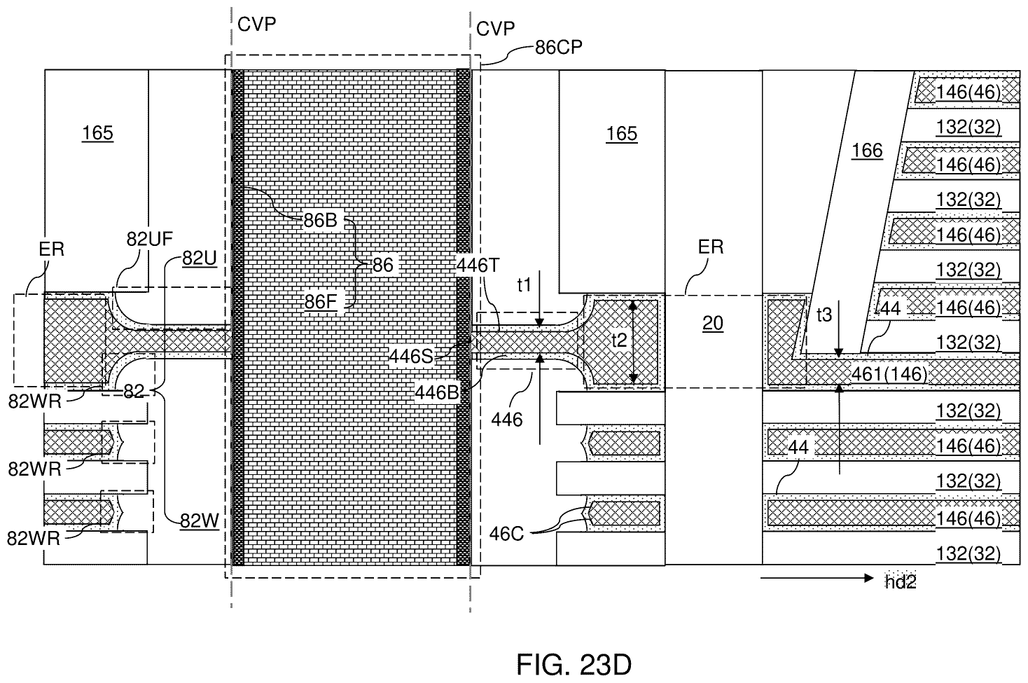

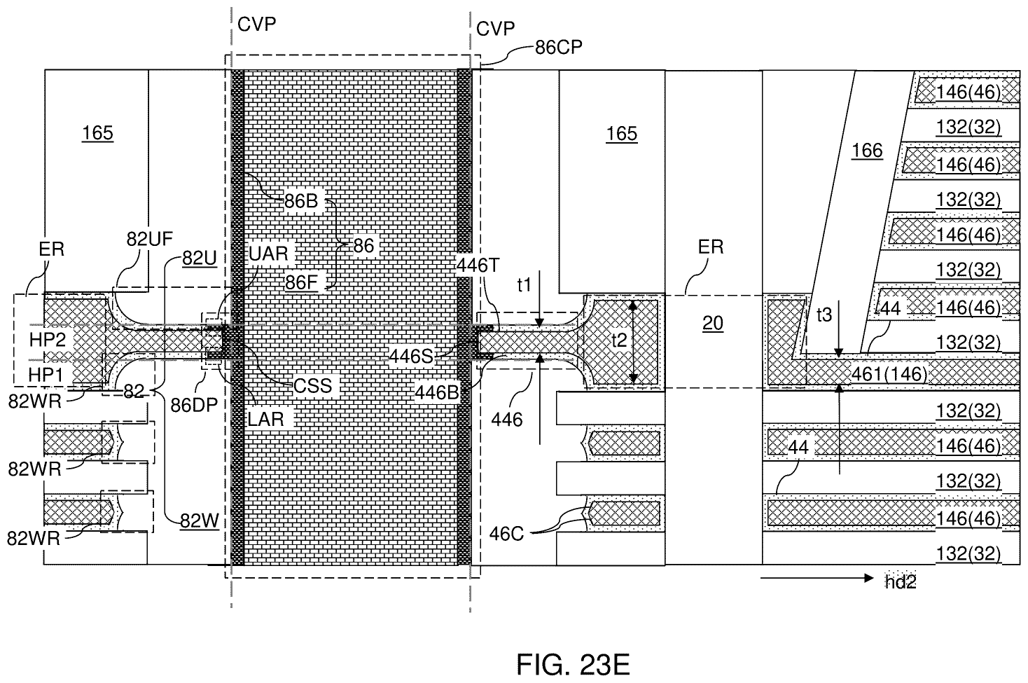

Referring to FIGS. 23A-23E, proximal portions of the outer blocking dielectric layers 44 are removed selectively to the electrically conductive layers 46, the upper tubular dielectric spacers 82U, and the lower tubular dielectric spacers 82W around the voids 87. A cylindrical sidewall 446S of a respective first electrically conductive layer 461 can be physically exposed around each void 87.

At least one electrically conductive material can be deposited in each void 87. Excess portions of the at least one electrically conductive material can be removed from above the horizontal plane including the top surface of the contact-level dielectric layer 80. Each remaining portion of the at least one electrically conductive material that fills a respective one of the voids 87 constitutes a layer contact via structure 86 that contacts a respective first electrically conductive layer 461 among the electrically conductive layers 46. Each layer contact via structure 86 vertically extends through a respective subset of the insulating layers 32 and through a respective subset of the electrically conductive layers 46.

In one embodiment, each electrically conductive layer 46 of the respective subset of the electrically conductive layers 46 except the first electrically conductive layer 461 comprises a pair of annular concave surfaces 46C that are adjoined to each other at a closed edge located within a respective horizontal plane (e.g., at a point in a vertical plane). The annular concave surfaces 46C are located opposite to the convex surfaces of the annular rib portions 82WR.

In one embodiment illustrated in FIG. 23C the at least one electrically conductive material of the layer contact via structure 86 may comprise a metal, such as W, Co, Ru, Mo, Cu, an alloy thereof or a combination thereof. The metal layer contact via structure 86 contacts the exposed cylindrical sidewall 446S of a respective first electrically conductive layer 461. Thus, a combination of an upper tubular dielectric spacer 82U, a lower tubular dielectric spacer 82W, and an annular thinned region 446 of a respective first electrically conductive layer 461 may fill a peripheral region of each contact via cavity 25 as formed at the processing steps of FIG. 16B, and a layer contact via structure 86 can be formed in a center region of the contact via cavity 25. The layer contact via structure 86 contacts a cylindrical sidewall 446S of the first electrically conductive layer 461, i.e., the cylindrical sidewall 446S of the annular thinned region 446 of the first electrically conductive layer 461.

In an alternative embodiment illustrated in FIG. 23D, the at least one electrically conductive material may comprise a metallic barrier material and a metal fill material. In this case, each layer contact via structure 86 may comprise a metallic barrier liner 86B and a metal fill material portion 86F that is laterally surrounded by the metallic barrier liner 86B. The metallic barrier liner 86B comprises the metallic barrier material. The metallic barrier material comprises a metallic diffusion barrier material. For example, the metallic barrier material comprises a conductive metallic nitride material such as TIN, TaN, WN, and/or MoN. The metallic barrier material may be deposited as a continuous material layer having a uniform thickness throughout by a conformal deposition process such as a chemical vapor deposition process. The thickness of the metallic barrier material may be in a range from 3 nm to 60 nm, such as from 6 nm to 30 nm, although lesser and greater thicknesses may also be employed. The metal fill material portion 86F comprises a metal fill material that provides high electrical conductivity. For example, the metal fill material comprises, and/or consists essentially of, an elemental metal such as W, Co, Ru, Mo, Cu, or a combination thereof. The metal fill material may be formed by a conformal deposition process, such as a chemical vapor deposition process. In this embodiment, the metallic barrier liner 86B of the layer contact via structure 86 contacts the exposed cylindrical sidewall 446S of a respective first electrically conductive layer 461.

In another alternative embodiment illustrated in FIG. 23E, the proximal portions of the outer blocking dielectric layers 44 that are removed selectively to the electrically conductive layers 46 include the cylindrical sidewalls of the outer blocking dielectric layers 44 exposed in the voids 87. This forms a lateral recess adjacent to the cylindrical sidewall 446S of the annular thinned portion 446 of the respective first electrically conductive layer 461. In this embodiment, the voids 87 include laterally-protruding annular portions, and the entirety of a laterally-protruding annular portion of each void 87 may be filled within the layer contact via structure 86 (e.g., the metallic barrier liner 86B of the layer contact via structure 86).

Optionally, the upper and lower horizontal portions of the outer blocking dielectric layers 44 are also recessed during removal of the cylindrical sidewalls of the outer blocking dielectric layers 44. In other words, the outer blocking dielectric layers 44 may be over etched to also partially recess the upper and lower horizontal portions of the outer blocking dielectric layers 44 located adjacent to the voids 87. This ensures that no portion of the outer blocking dielectric layers 44 covers the cylindrical sidewall 446S of the respective first electrically conductive layer 461.

In the embodiment of FIG. 23E, each layer contact via structure 86 comprises a respective cylindrical pillar portion 86CP and a respective dual-rimmed lateral protrusion portion 86DP that laterally protrudes outward from the cylindrical pillar portion 86CP and is in contact with a cylindrical sidewall of a respective first electrically conductive layer 461.

In one embodiment, for each layer contact via structure 86, a lower region of the cylindrical pillar portion 86CP is laterally surrounded by and is contacted by a lower tubular dielectric spacer 82W that underlies a first horizontal plane HP1 including a bottom annular surface of the dual-rimmed lateral protrusion portion 86DP. In one embodiment, for each layer contact via structure 86, an upper region of the cylindrical pillar portion 86CP is laterally surrounded by and is contacted by an upper tubular dielectric spacer 82U that overlies a second horizontal plane HP2 including a top annular surface of the dual-rimmed lateral protrusion portion 86DP. In one embodiment, for each layer contact via structure 86, the dual-rimmed lateral protrusion portion 86DP comprises an upper annular rim UAR, a lower annular rim LAR, and a cylindrical surface segment CSS that connects an inner periphery of an annular bottom surface of the upper annular rim UAR and an inner periphery of an annular top surface of the lower annular rim LAR.

In one embodiment, the annular bottom surface of the upper annular rim UAR contacts an annular top surface segment 446T of an annular region (e.g., the annular thinned region) 446 of the first electrically conductive layer 461; and the annular top surface of the lower annular rim LAR contacts an annular bottom surface segment 446B of the annular region 446 of the first electrically conductive layer 461. In one embodiment, the annular region 446 of the first electrically conductive layer 461 has a first thickness t1; and the first electrically conductive layer 461 comprises an enclosure region ER that laterally surrounds the annular region 446 and have a second thickness t2 that is greater than the first thickness. In one embodiment, a portion of the first electrically conductive layer 461 that laterally surrounds the memory opening fill structure 58 has a third thickness t3 that is less than the second thickness t2.

In one embodiment, the first electrically conductive layer 461 is embedded within an outer blocking dielectric layer 44; and a vertical extent of the dual-rimmed lateral protrusion portion 86DP equals a sum of the first thickness t1 and twice a thickness of the outer blocking dielectric layer 44. In one embodiment, the layer contact via structure 86 comprises a metallic barrier liner 86B and a metal fill material portion 86F; an entirety of the dual-rimmed lateral protrusion portion 86DP consists of a first portion of the metallic barrier liner 86B; and the cylindrical pillar portion 86CP comprises a second portion of the metallic barrier liner 86B and an entirety of the metal fill material portion 86F.

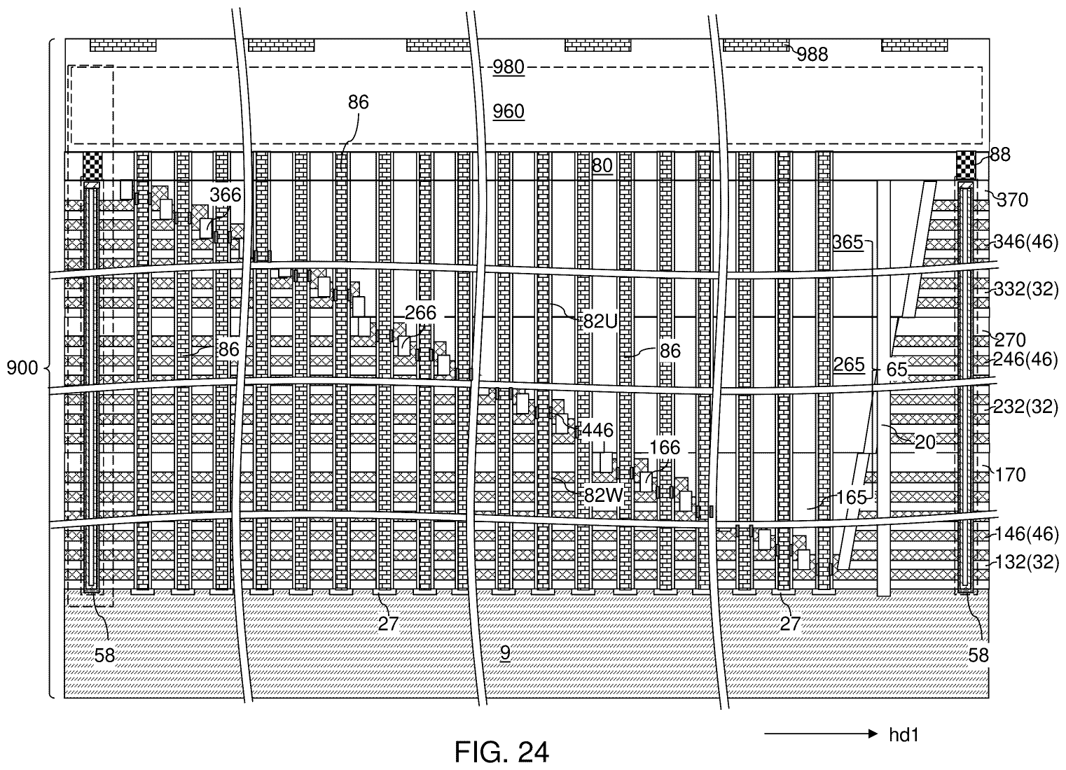

Referring to FIG. 24, drain contact via structures 88 can be formed through the contact-level dielectric layer directly on top surfaces of the drain regions 63. Additional dielectric material layers can be formed over the contact-level dielectric layer 80. The additional dielectric material layers may include at least one via-level dielectric layer, at least one additional line-level dielectric layer, and/or at least one additional line-and-via-level dielectric layer. The additional metal interconnect structures may comprise metal via structures, metal line structures, and/or integrated metal line-and-via structures. The dielectric material layers that are formed above the contact-level dielectric layer 80 are herein collectively referred to as memory-side dielectric material layers 960. The additional metal interconnect structures are collectively referred to as memory-side dielectric material layers 960. The memory-side dielectric material layers 960 comprise a bit-line-level dielectric material layer embedding bit lines, which are a subset of the memory-side metal interconnect structures 980.

Metal bonding pads, which are herein referred to as memory-side bonding pads 988, may be formed at the topmost level of the memory-side dielectric material layers 960. The memory-side bonding pads 988 may be electrically connected to the memory-side metal interconnect structures 980 and various nodes of the three-dimensional memory array including the alternating stacks of insulating layers 32 and electrically conductive layers 46 and the memory opening fill structures 58. A memory die 900 can thus be provided.

The memory-side dielectric material layers 960 are formed over the alternating stacks (32, 46). The memory-side metal interconnect structures 980 are embedded in the memory-side dielectric material layers 960. The memory-side bonding pads 988 can be embedded within the memory-side dielectric material layers 960, and specifically, within the topmost layer among the memory-side dielectric material layers 960. The memory-side bonding pads 988 can be electrically connected to the memory-side metal interconnect structures 980.

In summary, the memory die 900 comprises a memory array (32, 46, 58), memory-side metal interconnect structures 980, and memory-side bonding pads 988 embedded within memory-side dielectric material layers 960. The memory array may comprise a three-dimensional memory array including an alternating stack of insulating layers 32 and electrically conductive layers 46, and further comprises a two-dimensional array of NAND strings (e.g., memory opening fill structures 58) vertically extending through the alternating stack (32, 46). In one embodiment, the electrically conductive layers 46 comprise word lines and select gate electrodes of the two-dimensional array of NAND strings. In one embodiment, the memory-side metal interconnect structures 980 comprise bit lines for the two-dimensional array of NAND strings.

A logic die 700 can be provided. The logic die 700 includes a logic-side substrate 709, a peripheral circuit 720 located on the logic-side substrate 709 and comprising logic-side semiconductor devices (such as field effect transistors), logic-side metal interconnect structures 780 embedded within logic-side dielectric material layers 760, and logic-side bonding pads 778. The peripheral circuit 720 can be configured to control operation of the memory array within the memory die 900. Specifically, the peripheral circuit 720 can be configured to drive various electrical components within the memory array including, but not limited to, the electrically conductive layers 46, the drain regions 63, and a source contact structure to be subsequently formed. The peripheral circuit 720 can be configured to control operation of the vertical stack of memory elements in the memory array in the memory die 900. Particularly, the peripheral circuit 720 comprises word line driver transistors configured to drive the word lines in the memory die 900.

The logic die 700 can be attached to the memory die 900, for example, by bonding the logic-side bonding pads 788 to the memory-side bonding pads 988 at a bonding interface. The bonding between the memory die 900 and the logic die 700 may be performed employing a wafer-to-wafer bonding process in which a two-dimensional array of memory dies 900 is bonded to a two-dimensional array of logic dies 700, by a die-to-die bonding process, or by a die-to-wafer bonding process. The logic-side bonding pads 788 within each logic die 700 can be bonded to the memory-side bonding pads 988 within a respective memory die 900.

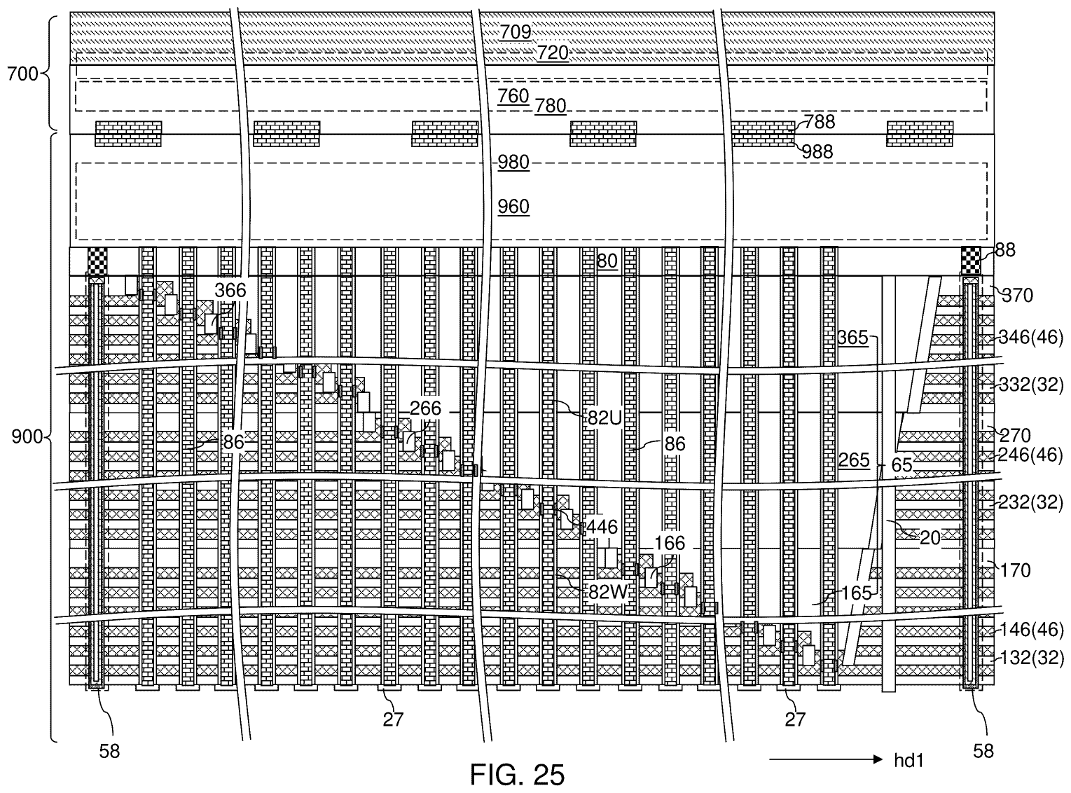

Referring to FIG. 25, the substrate 9 can be removed, for example, by grinding, polishing, cleaving, an isotropic etch process, an anisotropic etch process, and/or a combination thereof. In one embodiment, at least a terminal step of at least one removal process that is employed to remove the substrate 9 may comprise a selective wet etch process that etches the material of the substrate 9 (such as a semiconductor material of the substrate 9) selectively to dielectric materials of the memory films 50. In an illustrative example, if the substrate 9 comprises a semiconductor material, the terminal step of the at least one removal process may comprise a wet etch process using hot trimethyl-2 hydroxyethyl ammonium hydroxide (“hot TMY”) or tetramethyl ammonium hydroxide (TMAH). The entirety of the substrate 9 can be removed by the selective wet etch process. Backside end surfaces of the support pillar structures 20 can be physically exposed upon removal of the substrate 9.

An end portion of each memory opening fill structure 58 can be removed. In one embodiment, an end portion of each memory film 50 may be removed by performing a sequence of wet etch processes. A horizontal end portion of each vertical semiconductor channel 60 may be physically exposed. In one embodiment, the sequence of wet etch processes may be selective to the material of the vertical semiconductor channels 60.

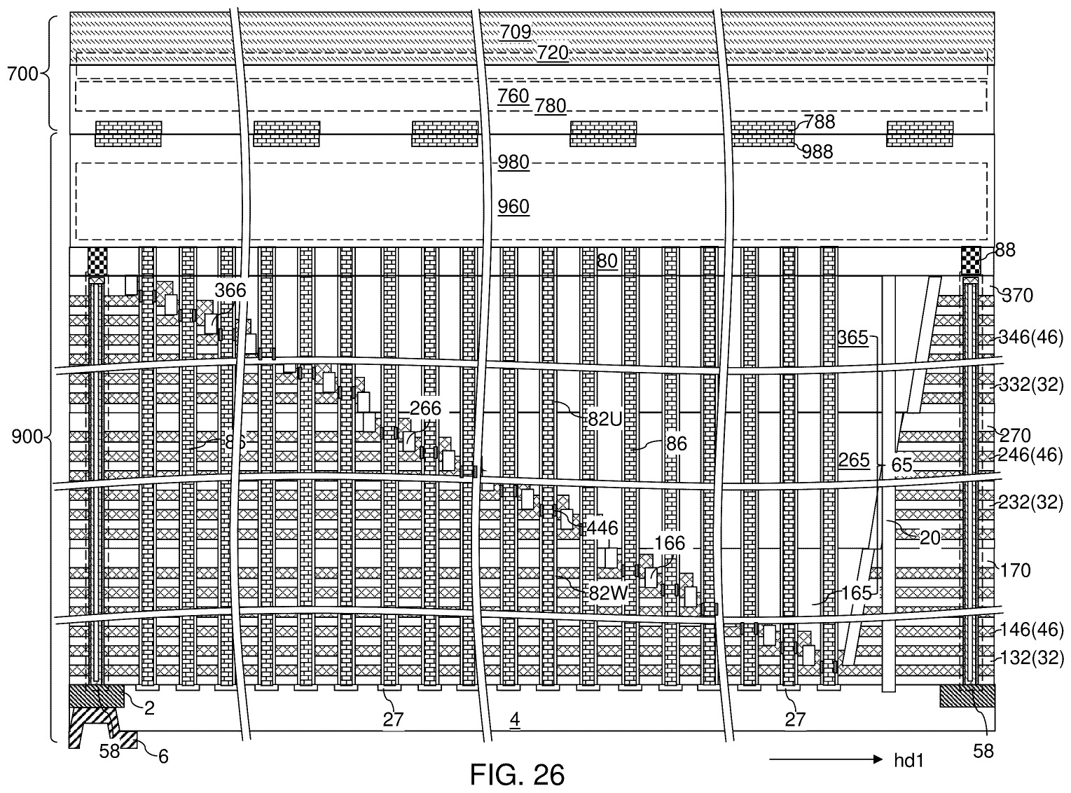

Referring to FIG. 26, at least one source structure 2 (e.g., a source region and/or source line) can be formed in contact vertical semiconductor channels 60. The at least one source structure 2 may comprise a heavily doped semiconductor material and/or a metallic material (e.g., a metal and/or an electrically conductive metal nitride or silicide). A backside dielectric layer 4 and backside contact structures 6 can be subsequently formed.

Referring to FIGS. 1A-26 and according to various embodiments of the present disclosure, a device structure comprises: an alternating stack (32, 46) of insulating layers 32 and electrically conductive layers 46; a memory opening 49 vertically extending through each layer within the alternating stack (32, 46); a memory opening fill structure 58 located in the memory opening 49 and comprising a vertical stack of memory elements (e.g., portions of the memory film 50) and a vertical semiconductor channel 60; and a layer contact via structure 86 vertically extending through a subset of the insulating layers 32 and through a subset of the electrically conductive layers 46, and in contact with at least cylindrical sidewall 446S of an annular region 446 of a first electrically conductive layer 461 which is a topmost electrically conductive layer of the subset of the electrically conductive layers. The annular region 446 of the first electrically conductive layer has a first thickness t1; and the first electrically conductive layer also includes an enclosure region ER that laterally surrounds the annular region 446 and has a second thickness t2 that is greater than the first thickness t1.

In one embodiment, a unform-thickness portion of the first electrically conductive layer 461 that laterally surrounds the memory opening fill structure 58 has a third thickness t3 that is less than the second thickness t2; and the enclosure region ER is located between the unform-thickness portion and the annular region 446.

In one embodiment, the layer contact via structure 86 vertically extends from a bottom horizontal plane including a bottom of the alternating stack (32, 46) to at least a top horizontal plate including a top of the alternating stack (32, 46).

In one embodiment shown in FIGS. 23C-23E, the annular region 446 of the first electrically conductive layer 461 laterally protrudes farther toward the layer contact via structure 86 than any underlying ones of the electrically conductive layers 46.

In one embodiment each electrically conductive layer 46 of the subset of the electrically conductive layers except the first electrically conductive layer 466 comprises a pair of annular concave surfaces 46C that are adjoined to each other at a closed edge located within a respective horizontal plane.

In one embodiment, the layer contact via structure 86 comprises a cylindrical pillar portion 86CP; a lower region of the cylindrical pillar portion 86CP is laterally surrounded by and is contacted by a lower tubular dielectric spacer 82W; and an upper region of the cylindrical pillar portion 86CP is laterally surrounded by and is contacted by an upper tubular dielectric spacer 82U.

In one embodiment, a retro-stepped dielectric material portion (165, 265, or 365) overlies a portion of the alternating stack (32, 46); and the upper tubular dielectric spacer 82U comprises an outer sidewall that vertically extends from a horizontally-extending surface segment of a stepped bottom surface of the retro-stepped dielectric material portion (165, 265, or 365) to a topmost surface of the retro-stepped dielectric material portion (165, 265, or 365). In one embodiment, the upper tubular dielectric spacer 82U comprises an annular base flange portion 82UF having an annular planar horizontal top surface, an annular convex tapered sidewall, and an annular planar horizontal bottom surface. In one embodiment, an inner cylindrical sidewall of the lower tubular dielectric spacer 82W and an inner cylindrical sidewall of the upper tubular dielectric spacer 82U are located within a cylindrical vertical plane CVP.

In one embodiment, the lower tubular dielectric spacer 82W comprises annular rib portions 82WR; and each of the annular rib portions 82WR laterally protrudes outward at a level of a respective electrically conductive layer 46 of the electrically conductive layers 46 within the subset of the electrically conductive layers 46. In one embodiment, each of the annular rib portions 82WR except a topmost annular rib portion 82WR of the annular rib portions 82WR comprises a pair of annular convex surfaces that are adjoined to each other at a closed edge located within a respective horizontal plane.

In one embodiment shown in FIG. 23E, the layer contact via structure 86 comprises the cylindrical pillar portion 86CP and a dual-rimmed lateral protrusion portion 86DP that laterally protrudes outward from the cylindrical pillar portion 86CP and contacts the cylindrical sidewall 446S of the first electrically conductive layer 461.

In one embodiment shown in FIG. 23E, the lower tubular dielectric spacer 82W underlies a first horizontal plane HP1 including a bottom annular surface of the dual-rimmed lateral protrusion portion 86DP; and the upper tubular dielectric spacer 82U overlies a second horizontal plane HP2 including a top annular surface of the dual-rimmed lateral protrusion portion 86DP.

In one embodiment shown in FIG. 23E, the dual-rimmed lateral protrusion portion 86DP comprises an upper annular rim UAR, a lower annular rim LAR, and a cylindrical surface segment CSS that connects an inner periphery of an annular bottom surface of the upper annular rim UAR and an inner periphery of an annular top surface of the lower annular rim LAR. In one embodiment, the annular bottom surface of the upper annular rim UAR contacts an annular top surface segment of the annular region 446 of the first electrically conductive layer 461; and the annular top surface of the lower annular rim LAR contacts an annular bottom surface segment of the annular region 446 of the first electrically conductive layer 461.

In one embodiment, the first electrically conductive layer 461 is embedded within an outer blocking dielectric layer 44; and a vertical extent of the dual-rimmed lateral protrusion portion 86DP equals a sum of the first thickness and twice a thickness of the outer blocking dielectric layer.

In various embodiments shown in FIGS. 23D and 23E, the layer contact via structure 86 comprises a metallic barrier liner 86B and a metal fill material portion 86F. An entirety of the dual-rimmed lateral protrusion portion 86DP consists of a first portion of the metallic barrier liner 86B; and the cylindrical pillar portion 86CP comprises a second portion of the metallic barrier liner 86B and an entirety of the metal fill material portion 86F.

The layer contact via structure 86 of various embodiments of the present disclosure has a compact size, is relatively simple to fabricate and has a lower change of electrical breakdown (e.g., shorting two or more vertically separated word lines) than conventional layer contact via structures.

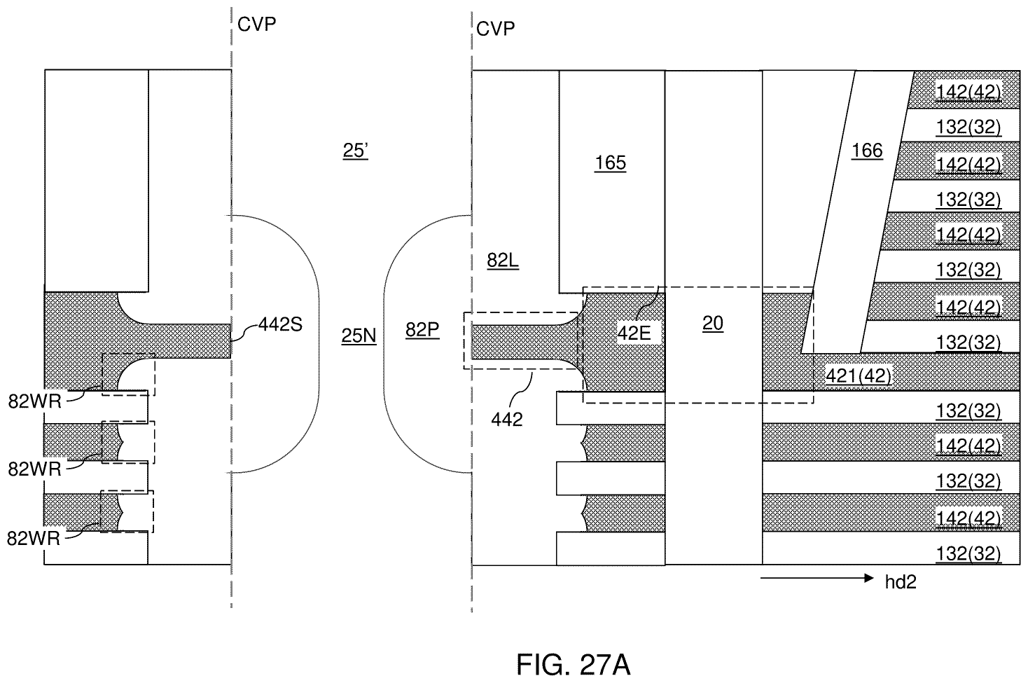

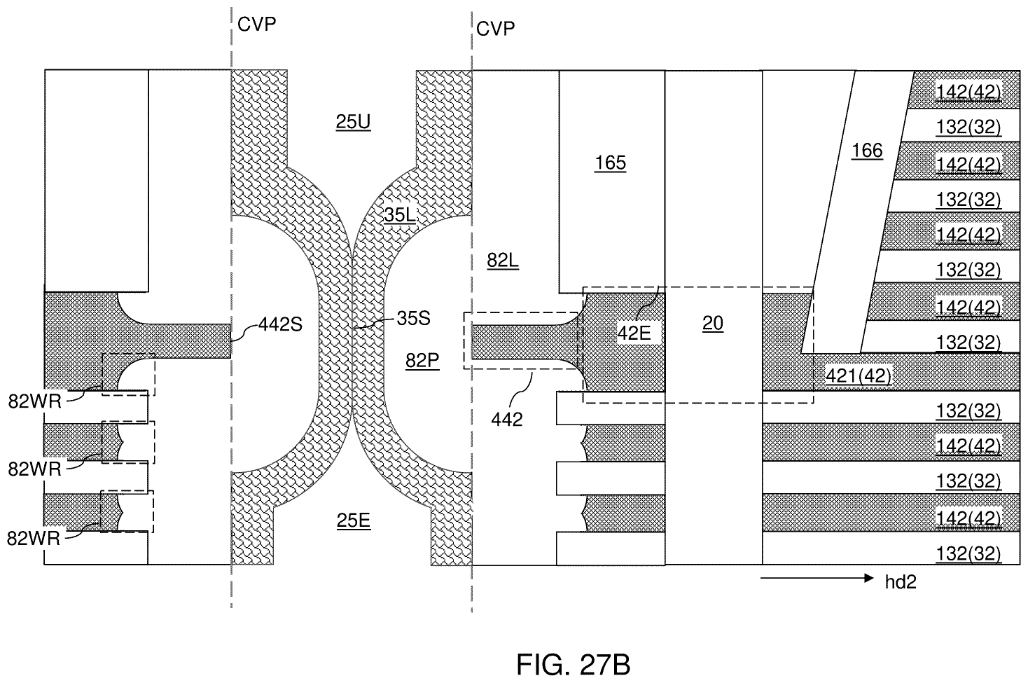

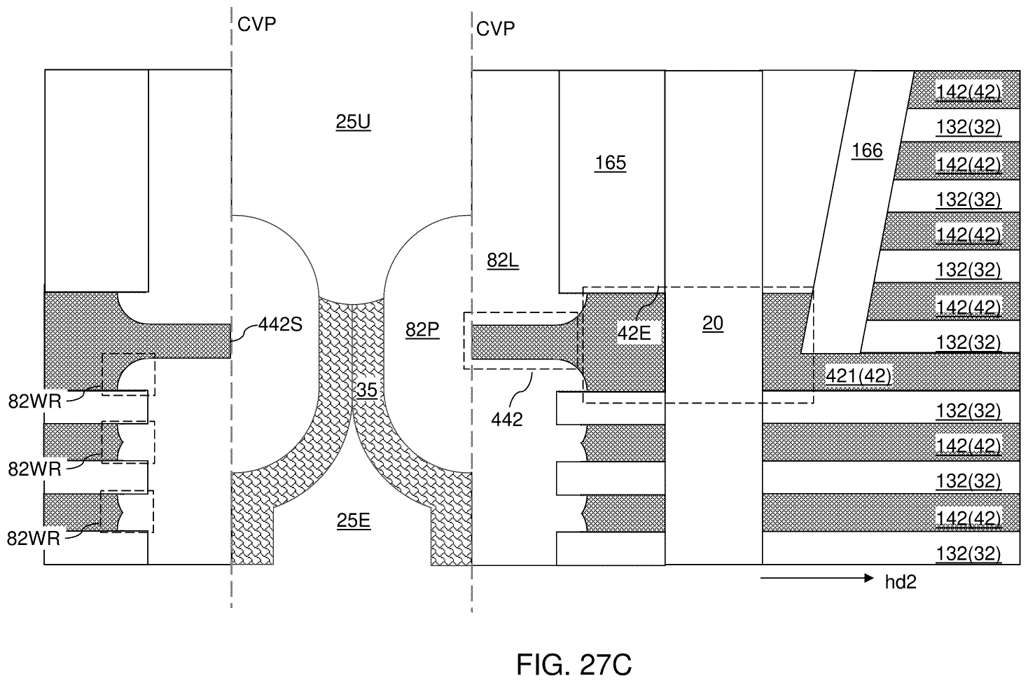

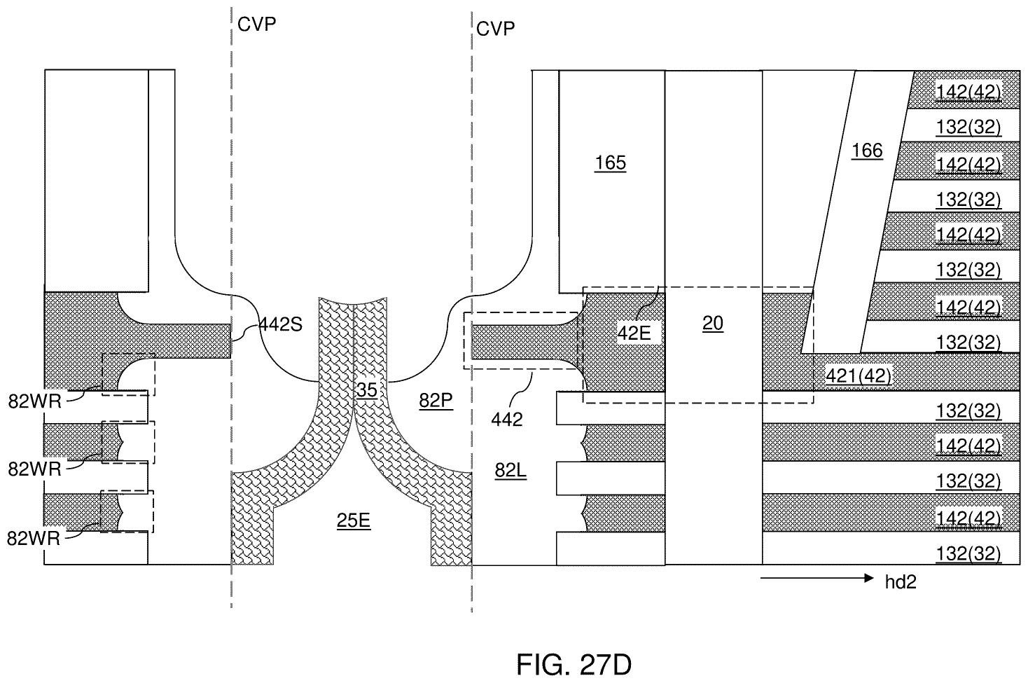

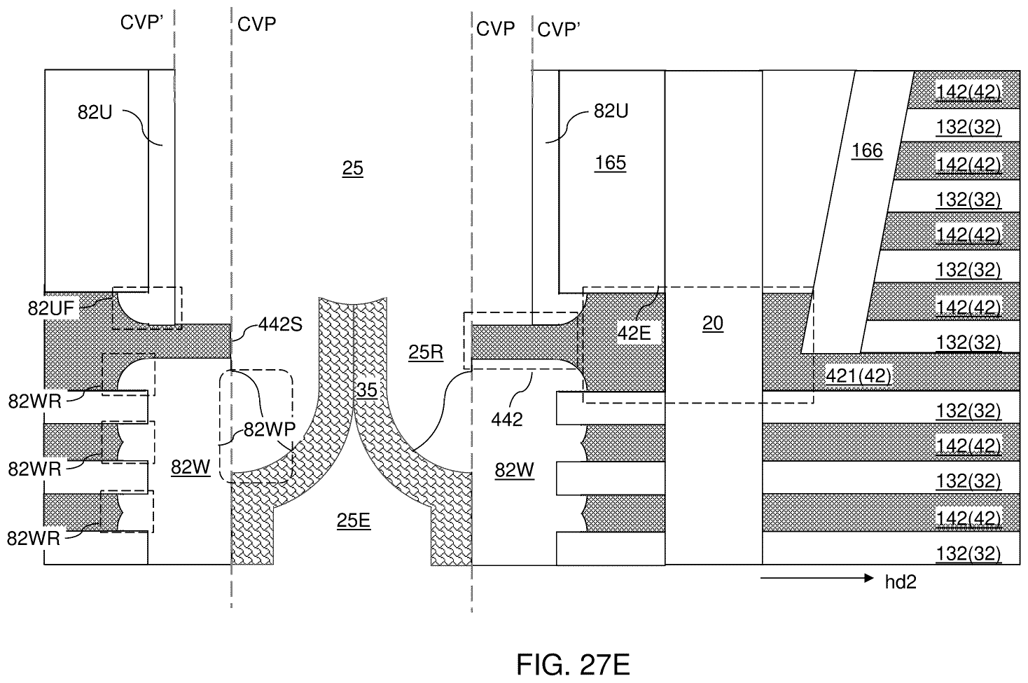

FIG. 27A-27E are sequential vertical cross-sectional views of a region around a contact via cavity during formation of a lower tubular dielectric spacer 82W and an upper tubular dielectric spacer 82U in a second exemplary structure according to a second embodiment of the present disclosure.

Referring to FIG. 27A, the second exemplary structure illustrated in FIG. 27A may be the same as the first exemplary structure described with reference to FIG. 16C. However, in the second embodiment, the anisotropic etching step of FIG. 16D is omitted and a protruding portion 82P of the dielectric spacer material layer 82L remains at the level of the first sacrificial material layer 421. For each contact via cavity 25, a necked void 25′ is formed in a volume of the contact via cavity 25 that is not filled with the dielectric spacer material layer 82L. The necked void 25′ has a neck region 25N at a level of the first sacrificial material layer 421 and the protruding portion 82P of the dielectric spacer material layer 82L.

Referring to FIG. 27B, a sacrificial fill liner layer 35L can be conformally deposited in peripheral portions of each necked void 25′ until the material of the sacrificial fill liner layer 35L fills and plugs the neck region 25N of each necked void 25′. The sacrificial fill liner layer 35L comprises a material that may be subsequently removed selectively to the material of the dielectric spacer material layer 82L. For example, if the dielectric spacer material layer 82L comprises silicon oxide, the sacrificial fill liner layer 35L may comprise a semiconductor material, such as polysilicon or amorphous silicon. A vertically-extending seam 35S can be formed at the geometrical center of the neck region of each necked void 25′. Remaining unfilled volumes of each necked void 25′ may comprise an encapsulated cavity (i.e., an air gap) 25E that underlies the vertically-extending seam 35S, and an upper void 25U that overlies the vertically-extending seam 35S and is connected to an ambient that overlies the contact-level dielectric layer 80. The sacrificial fill liner layer 35L may have an “X” shape with the center of the X shape located at the level of the first sacrificial material layer 421 and the protruding portion 82P of the dielectric spacer material layer 82L.

Referring to FIG. 27C, a selective isotropic etch process can be performed to isotropically etch the material of the sacrificial fill liner layer 35L selectively to the material of the dielectric spacer material layer 82L. For example, if the sacrificial fill liner layer 35L comprises amorphous silicon, a timed wet etch using hot trimethyl-2 hydroxyethyl ammonium hydroxide (“hot TMY”) or tetramethyl ammonium hydroxide (TMAH) may be performed to remove portions of the sacrificial fill liner layer 35L from around the upper void 25U within the volume of each necked void 25′ (i.e., the remaining portion of the contact via cavity 25). The duration of the selective isotropic etch process can be selected such that the lower portion of each vertically-extending seam 35S remains after the selective isotropic etch process.

Each remaining portion of the sacrificial fill liner layer 35L constitutes a sacrificial encapsulation liner 35 that encapsulates a respective encapsulated cavity 25E. In other words, the sacrificial encapsulation liner 35 plugs the neck region 25N of the necked void 25′ to maintain the encapsulated cavity 25E below the neck region 25N. In summary, an upper portion of the sacrificial fill liner layer 35L can be removed from an upper volume of each necked void 25′, and a combination of a sacrificial encapsulation liner 35 and an encapsulated cavity 25E may be formed within a lower volume of each necked void 25′. In one embodiment, each sacrificial encapsulation liner 35 may have a respective outer cylindrical sidewall located within a cylindrical vertical plane CVP.

Referring to FIG. 27D, an isotropic etch process can be performed, such as a dilute hydrofluoric acid wet etch process, which etches a physically exposed portion of the dielectric spacer material layer 82L selectively to the material of the sacrificial encapsulation liner 35 within each necked void 25′ (i.e., remaining portion of the contact via cavity 25). The duration of the isotropic etch process can be selected such that the dielectric spacer material layer 82L is only partially etched. For example, the etch distance of the isotropic etch process for the material of the dielectric spacer material layer 82L may be less than the lateral thickness of the portion of the dielectric spacer material layer 82L that vertically extends through the at least one retro-stepped dielectric material portion 65 at the processing steps described with reference to FIGS. 27A-27C. For example, the etch distance of the isotropic etch process for the material of the dielectric spacer material layer 82L may be in a range from 20% to 90%, such as from 50% to 80%, of the lateral thickness of the portion of the dielectric spacer material layer 82L that vertically extends through the at least one retro-stepped dielectric material portion 65 at the processing steps described with reference to FIGS. 27A-27C. The upper part of the protruding portion 82P may be recessed by the isotropic etch.

Referring to FIG. 27E, an anisotropic dry or wet etch process can be performed to selectively, anisotropically etch an additional portion of the dielectric spacer material layer 82L. The anisotropic etch process may comprise a sidewall spacer etch process. Specifically, horizontally-extending parts of the protruding portions 82P of the dielectric spacer material layer 82L can be etched selectively to the material of the sacrificial material layers 42 and the liner 35 above the annular thinned region 442 of each sacrificial material layer 42, and around the topmost portion of each sacrificial encapsulation liner 35. An upper remaining portion of the dielectric spacer material layer 82L in an upper region of each contact via cavity 25 comprises the upper dielectric tubular spacer 82U. A lower remaining portion of the dielectric spacer material layer comprises the lower dielectric tubular spacer 82W. Thus, the dielectric spacer material layer 82L can be patterned into lower dielectric tubular spacers 82W and upper dielectric tubular spacers 82U.

Each upper dielectric tubular spacer 82U may comprise a vertical tubular spacer having a uniform lateral thickness, and an annular base flange portion 82UF extending outward from a bottom end of the vertically-extending tubular portion and having a greater thickness than the uniform lateral thickness. A minimum lateral thickness of the lower dielectric tubular spacer 82W may be greater than the uniform lateral thickness of the tubular portion of the upper dielectric tubular spacer 82U around each contact via cavity 25. In one embodiment, the uniform lateral thickness of the upper dielectric tubular spacer 82U may be in a range from 10% to 80%, such as from 20% to 50%, of the lateral thickness of the lower dielectric tubular spacer 82W

For each contact via cavity vertically extending through a subset of the insulating layers 32 and a subset of the sacrificial material layers 42, the lower tubular dielectric spacer 82W vertically extends through each of the subset of the insulating layers 32 and each of the subset of the sacrificial material layers 42 except the first sacrificial material layer 421 which will be replaced with electrically conductive layers 46 and the first electrically conductive layer 461, respectively. In one embodiment, the lower tubular dielectric spacer 82W comprises: an inner cylindrical sidewall segment that is located within a cylindrical vertical plane CVP, and an annular inner protrusion region 82WP that is located within a volume that is laterally surrounded by the cylindrical vertical plane CVP and having a bottom periphery that is adjoined to a top periphery of the inner cylindrical sidewall segment. In one embodiment, a sidewall of each annular inner protrusion region 82WP may have a bell-shaped vertical cross-sectional profile that includes, from top to bottom, a convex tapered top surface segment, a concave tapered top surface segment, and a convex tapered bottom surface segment.

The annular inner protrusion region 82WP may be located below the first sacrificial material layer 421 and above the portion of the liner 35 that contacts a vertical inner surface of the lower tubular dielectric spacer 82W. In one embodiment, the lower tubular dielectric spacer 82W comprises annular rib portions WR that laterally outward at levels of the subset of the sacrificial material layers 42 except at the level of the first sacrificial material layer 421, and are vertically spaced apart among one another.

The upper tubular dielectric spacer 82U overlies the first sacrificial material layer 421, and comprises a vertically-extending tubular portion having a uniform lateral thickness between an inner cylindrical sidewall and an outer cylindrical sidewall, and an annular base flange portion 82UF extending outward from a bottom end of the vertically-extending tubular portion. An inner cylindrical sidewall of each upper tubular dielectric spacer 82U may be located within an additional cylindrical vertical plane CVP′ that is laterally offset outward relative to the cylindrical vertical plane CVP that includes an inner cylindrical sidewall of an underlying lower tubular dielectric spacer 82W.

In one embodiment, the lower tubular dielectric spacer 82W comprises a contoured inner sidewall and a contoured outer sidewall; and a minimum lateral distance between the contoured inner sidewall of the lower tubular dielectric spacer 82W and the contoured outer sidewall of the lower tubular dielectric spacer 82W is greater than the uniform lateral thickness of the upper tubular dielectric spacer 82U. An annular recess 25R remains between the vertically protruding portion of the liner 35 containing the seam 35S and the first sacrificial material layer 421 above the annular inner protrusion region 82WP.

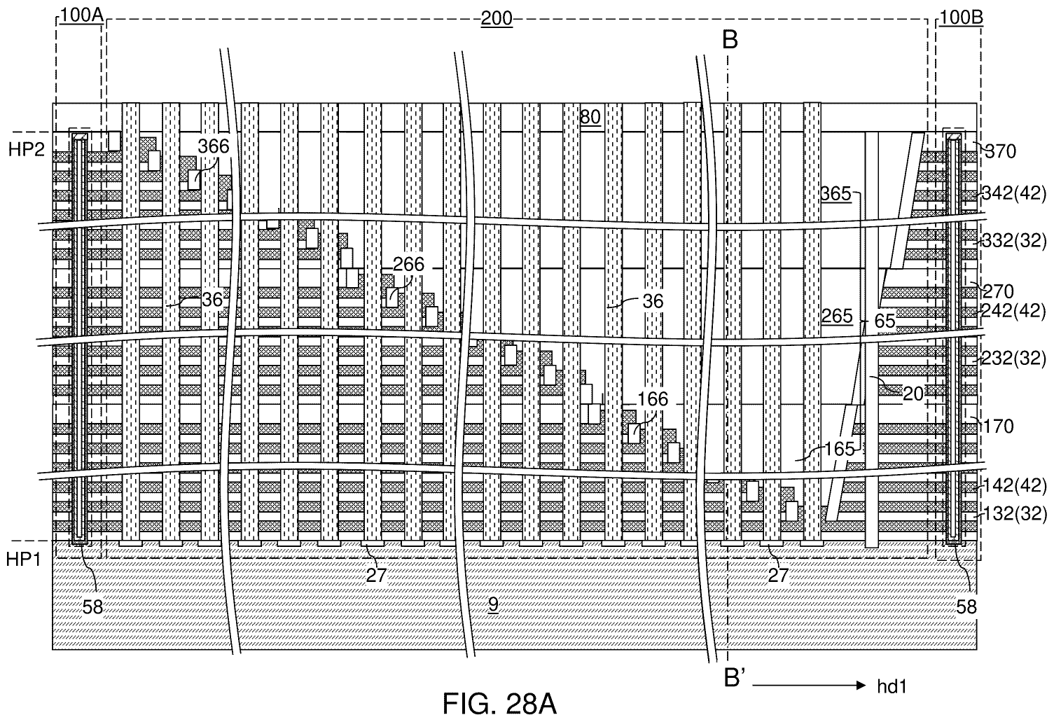

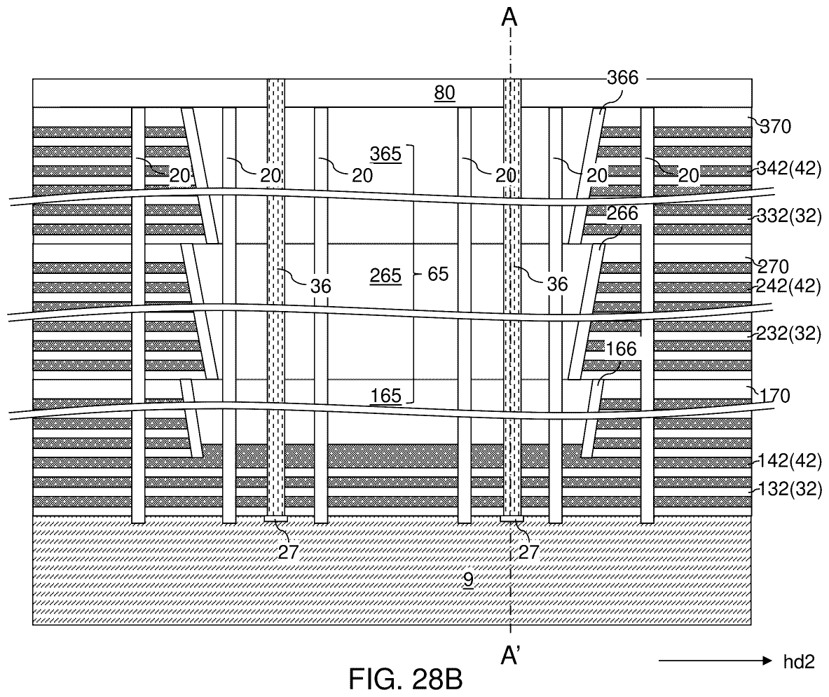

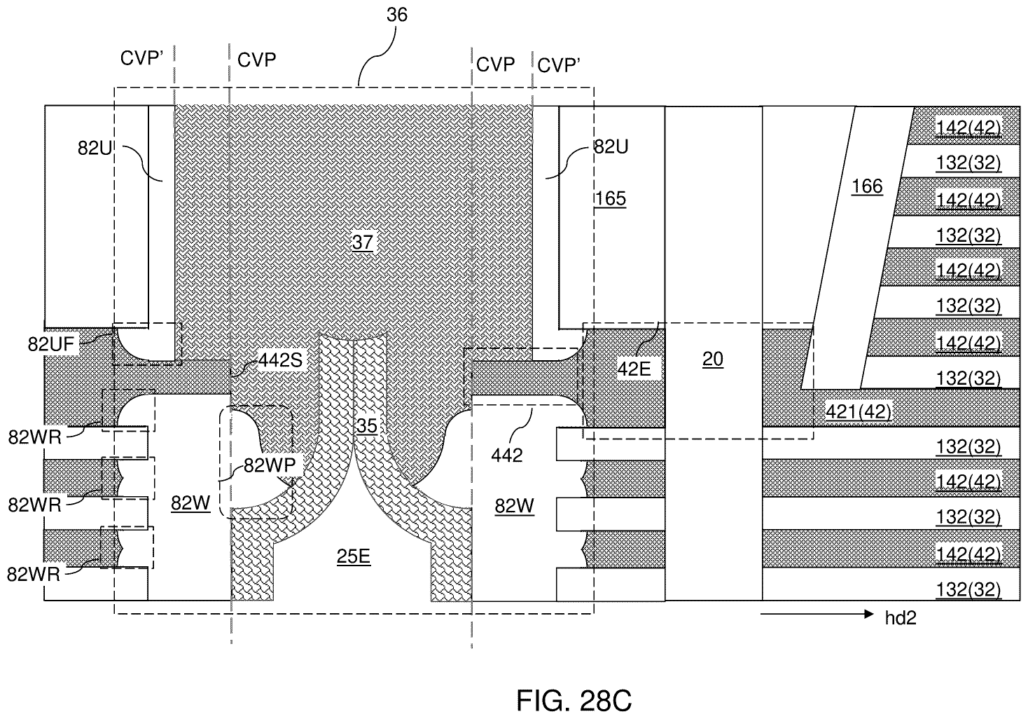

Referring to FIGS. 28A-28C, a sacrificial via fill material can be deposited in the volumes of the voids upper voids in the contact via cavities 25 that are laterally surrounded by the upper dielectric tubular spacers 82U, while the encapsulated cavity 25E below the liner 35 remains unfilled. Excess portions of the sacrificial via fill material can be removed from above the horizontal plane including the top surface of the contact-level dielectric layer 80. Each remaining portion of the sacrificial via fill material constitutes an upper sacrificial via fill portion 37. The upper sacrificial via fill portions 37 may comprise a semiconductor material (such as amorphous silicon, polysilicon or silicon-germanium), a carbon-based material (such as amorphous carbon or diamond-like carbon), a high-etch-rate silicate glass material (such as porous organosilicate glass), a polymer material, or any other material that may be subsequently removed selectively to the materials of the upper tubular dielectric spacers 82U and the lower tubular dielectric spacers 82W. A sacrificial via fill structure (35, 37) can be formed within each volume that is laterally surrounded by a upper dielectric tubular spacer 82U and a lower dielectric tubular spacer 82W. The sacrificial via fill structure (35, 37) may comprise a combination of a sacrificial encapsulation liner 35 and an upper sacrificial via fill portion 37. Each contiguous combination of an upper sacrificial via fill portion 37, an upper tubular dielectric spacer 82U, a lower tubular dielectric spacer 82W, a sacrificial encapsulation liner 35, an encapsulated cavity 25E, and an annular thinned region 442 constitutes an in-process contact-via-region assembly 36, as shown in FIG. 28C.

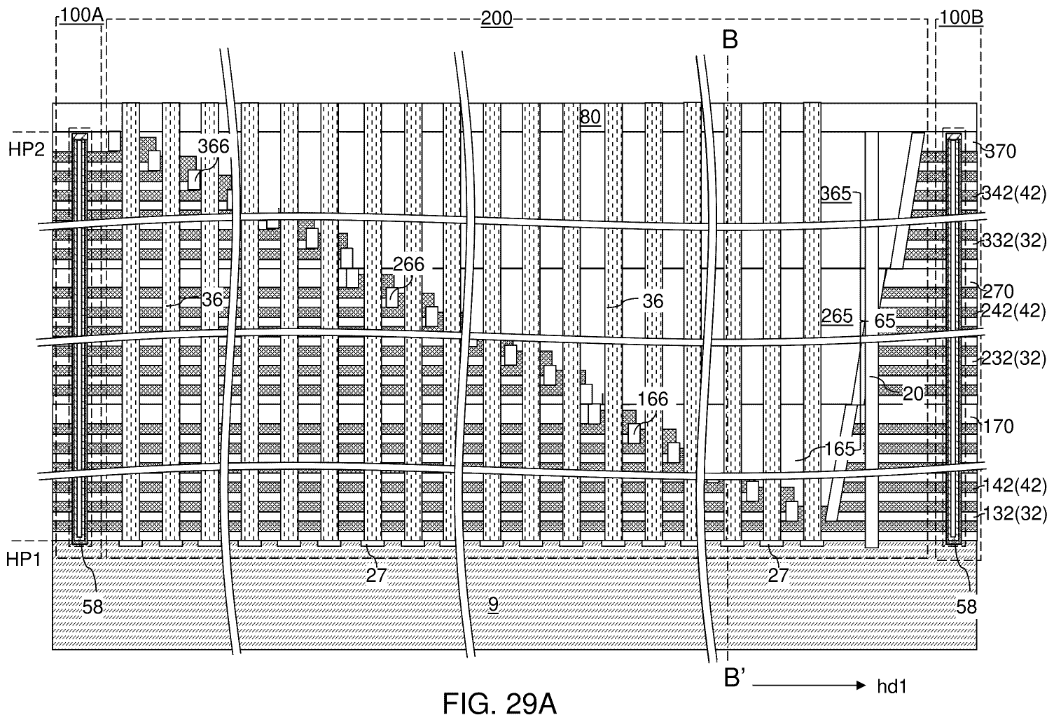

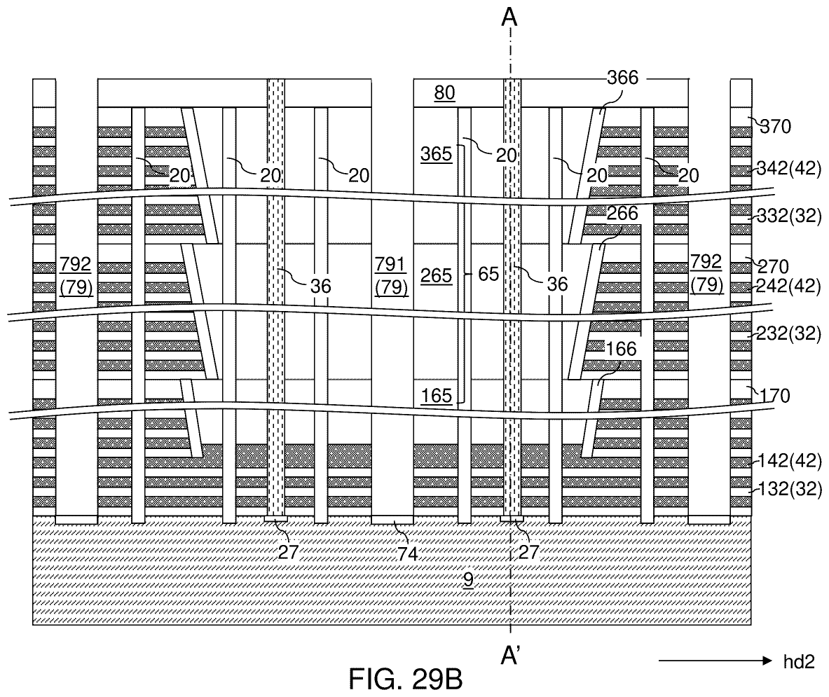

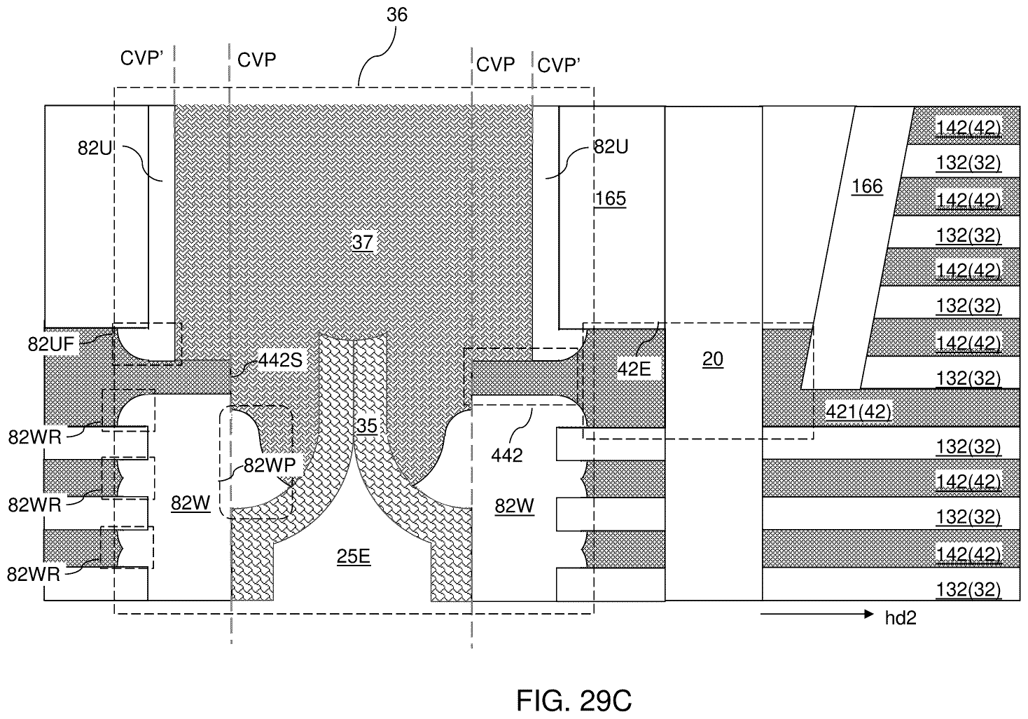

Referring to FIGS. 29A-29C, the processing steps described with reference to FIGS. 18A-18C may be performed to form the lateral isolation trenches 79.

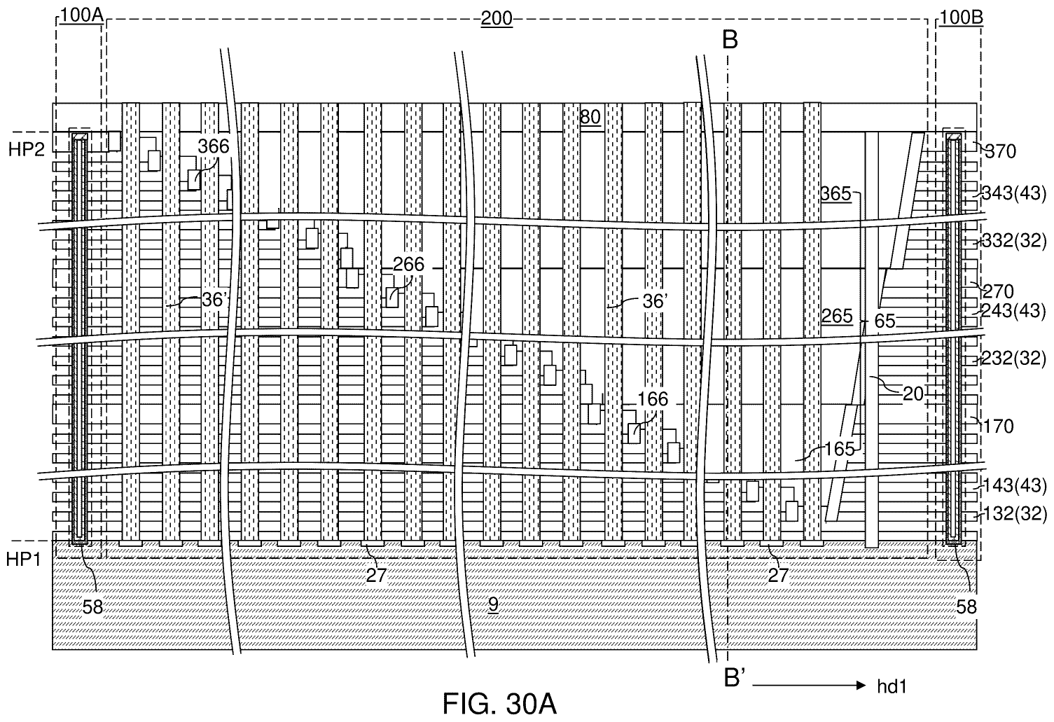

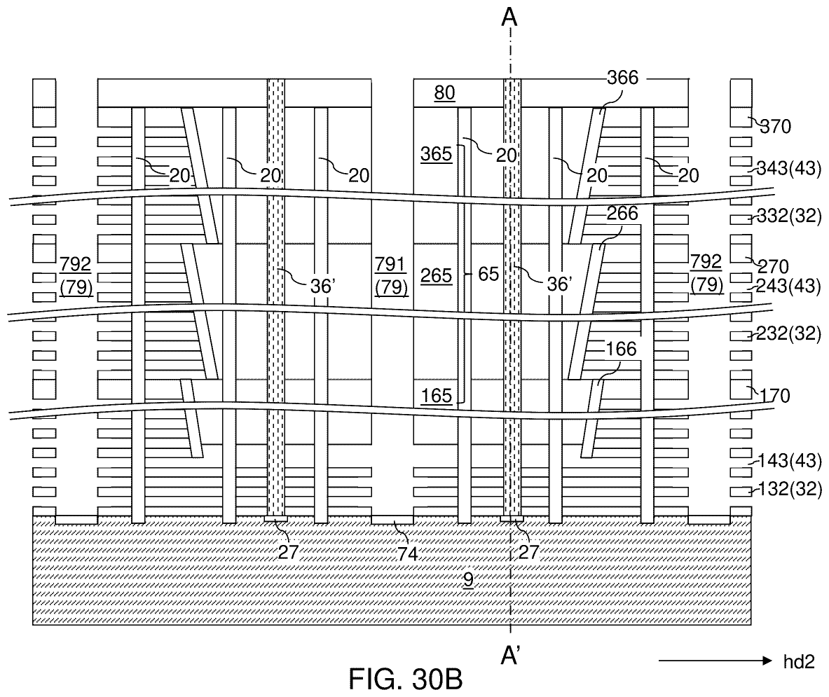

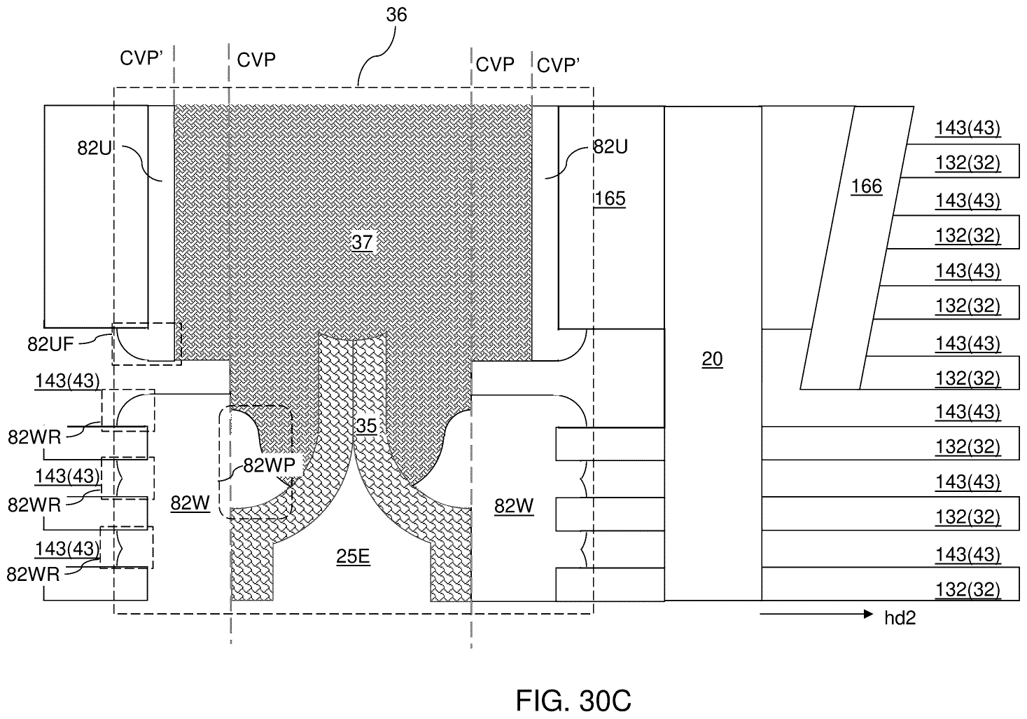

Referring to FIGS. 30A-30C, the processing steps described with reference to FIGS. 19A-19C may be performed to form the lateral recesses 43.

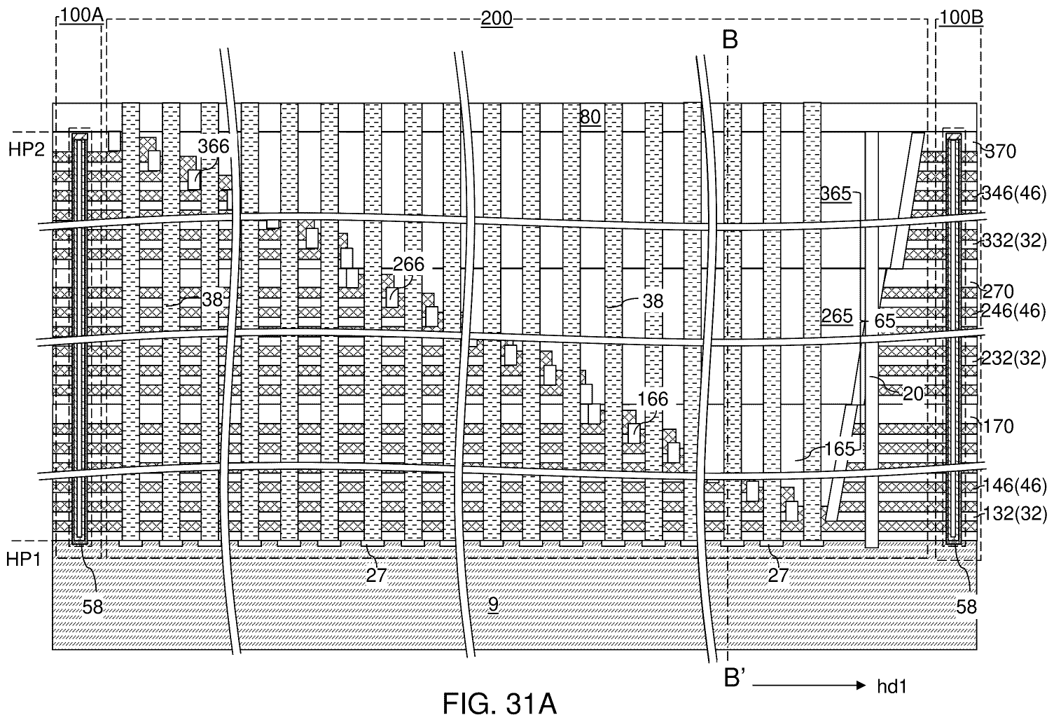

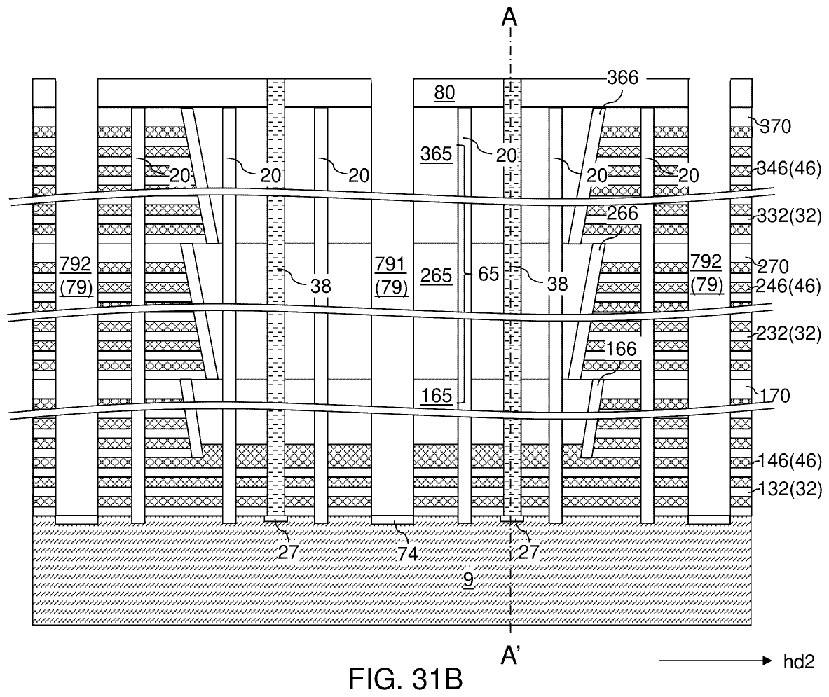

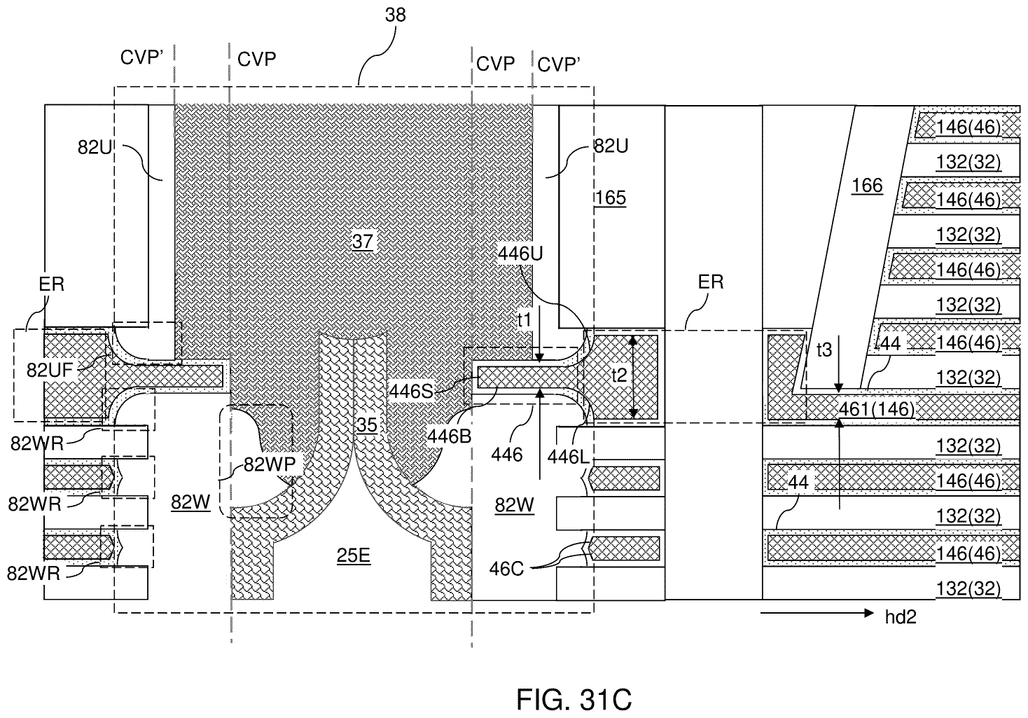

Referring to FIGS. 31A-31C, the processing steps described with reference to FIGS. 20A-20C may be performed to form the outer blocking dielectric layer 44 and the electrically conductive layer 46 within each of the lateral recesses 43. Each sacrificial via fill structure (35, 37) located within a respective contact via cavity 25 is contacted by a respective outer blocking dielectric layer 44 which embeds a respective electrically conductive layer 46, which is referred to as a first electrically conductive layer 461 for the sacrificial via fill structure (35, 37). The first electrically conductive layer 461 comprises a respective annular thinned region 446 which contains a uniform-thickness annular region having a first thickness t1, a respective enclosure region ER adjoined to a periphery of and laterally enclosing the respective annular thinned region 446 and having a second thickness t2 that is greater than the first thickness t1, and a respective uniform-thickness portion having a third thickness t3 and laterally surrounding the memory opening fill structures 58. The third thickness t3 may be less than the second thickness t2. The first thickness t1 may be in a range from 15 nm to 50 nm, such as from 20 nm to 40 nm, although lesser and greater thicknesses may also be employed. The second thickness t2 may be in a range from 40 nm to 100 nm, such as from 50 nm to 70 nm, although lesser and greater thicknesses may also be employed. The third thickness t3 may be in a range from 15 nm to 50 nm, such as from 20 nm to 30 nm, although lesser and greater thicknesses may also be employed. Each contiguous combination of a sacrificial via fill structure (35, 37), an upper tubular dielectric spacer 82U, a lower tubular dielectric spacer 82W, an annular thinned region 446 of a respective first electrically conductive layer 461, and a portion of an outer blocking dielectric layer 44 adjacent to the annular thinned region 446 constitutes an in-process contact-via-region assembly 38.

In summary, lateral recesses 43 can be formed by removing the sacrificial material layers 42 selectively to the insulating layers 32 and the sacrificial via fill structure (35, 37). A combination of a respective outer blocking dielectric layer 44 and a respective one of the electrically conductive layers 46 is formed in each lateral recess 43. Thus, the sacrificial material layers 42 are replaced with a combination of electrically conductive layers 46 and outer blocking dielectric layers 44. For each sacrificial via fill structure (35, 37), a first sacrificial material layer 421 that is proximal to the sacrificial via fill structure (35, 37) is replaced with a respective first electrically conductive layer 461. The annular thinned region 446 of the first electrically conductive layer 461 may comprise a cylindrical sidewall 446S, a planar annular top surface segment 446T having an inner periphery that is adjoined to a top periphery of the cylindrical sidewall 446S, a planar annular bottom surface segment 446B having an inner periphery that is adjoined to a bottom periphery of the cylindrical sidewall 446S, a tapered concave upper surface segment 446U having a vertically-concave profile and a horizontally concave profile and having a bottom periphery that is adjoined to an outer periphery of the planar annular top surface segment 446T, and a tapered concave lower surface segment 446L having a vertically-concave profile and a horizontally concave profile and having a top periphery that is adjoined to an outer periphery of the planar annular bottom surface segment 446B.

For each sacrificial via fill structure (35, 37) that vertically extends through a respective subset of the insulating layers 32 and a respective subset of the electrically conductive layers 46, the topmost electrically conductive layer 46 constitutes the first electrically conductive layer 461. The annular region 446 of the first electrically conductive layer 461 laterally protrudes farther inward toward the sacrificial via fill structure (35, 37) than any underlying ones of the electrically conductive layers 46.

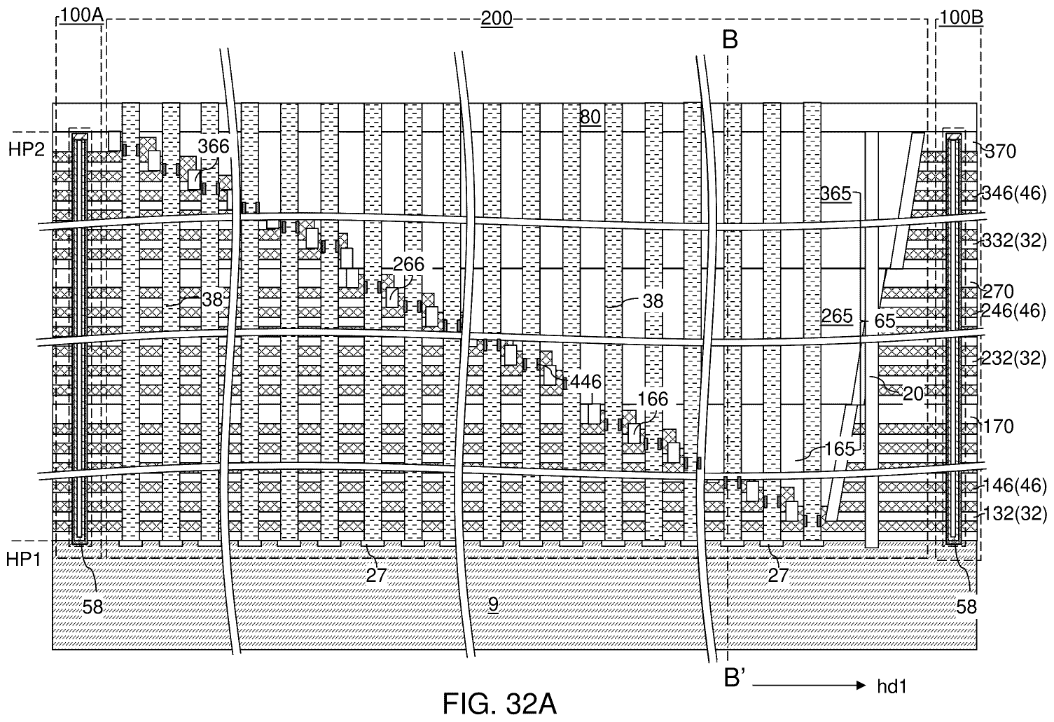

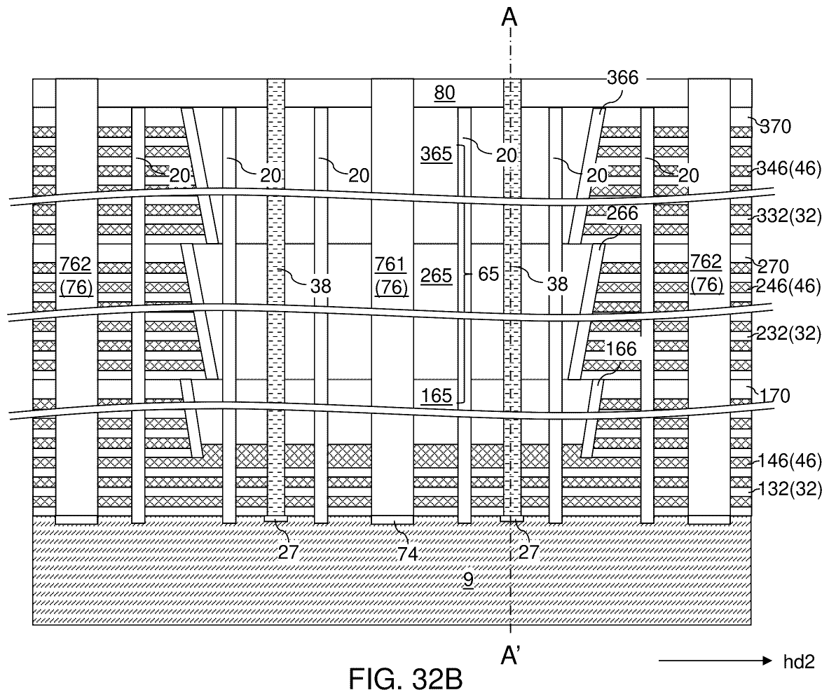

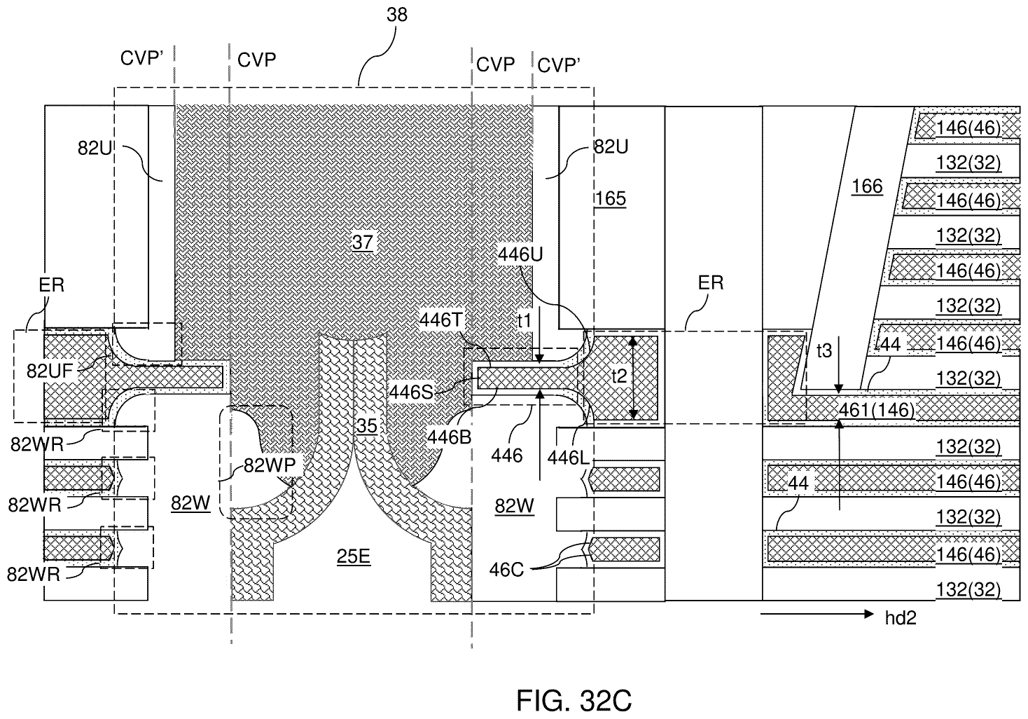

Referring to FIGS. 32A-32C, the processing steps described with reference to FIGS. 21A-21C may be performed to form lateral isolation trench fill structures 76 in the lateral isolation trenches 79.

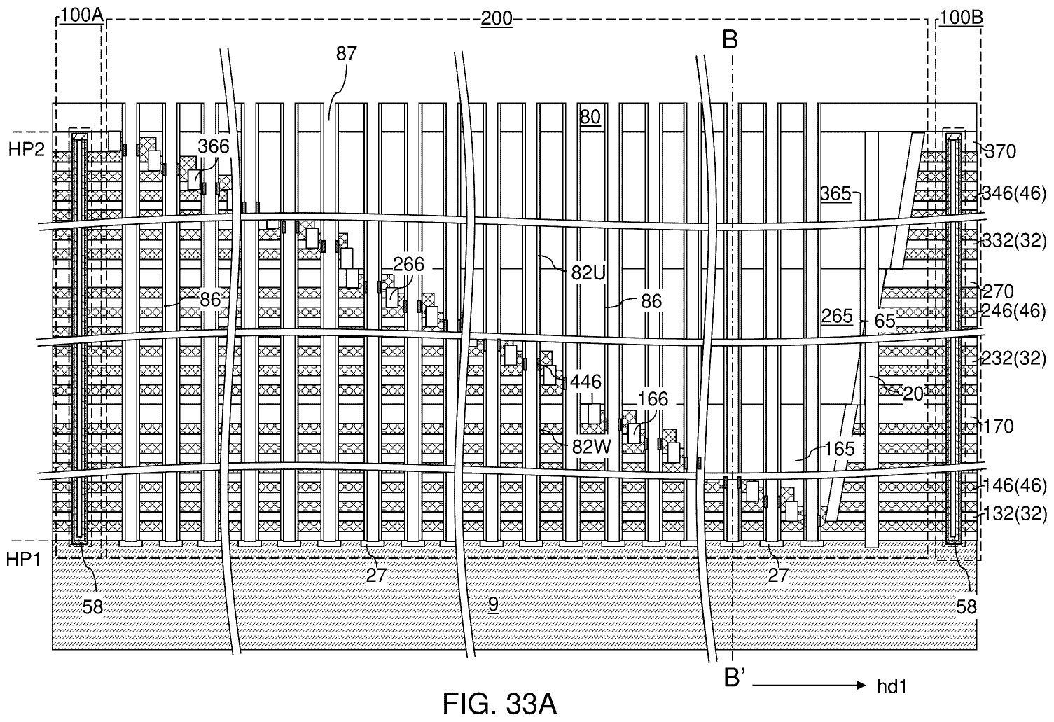

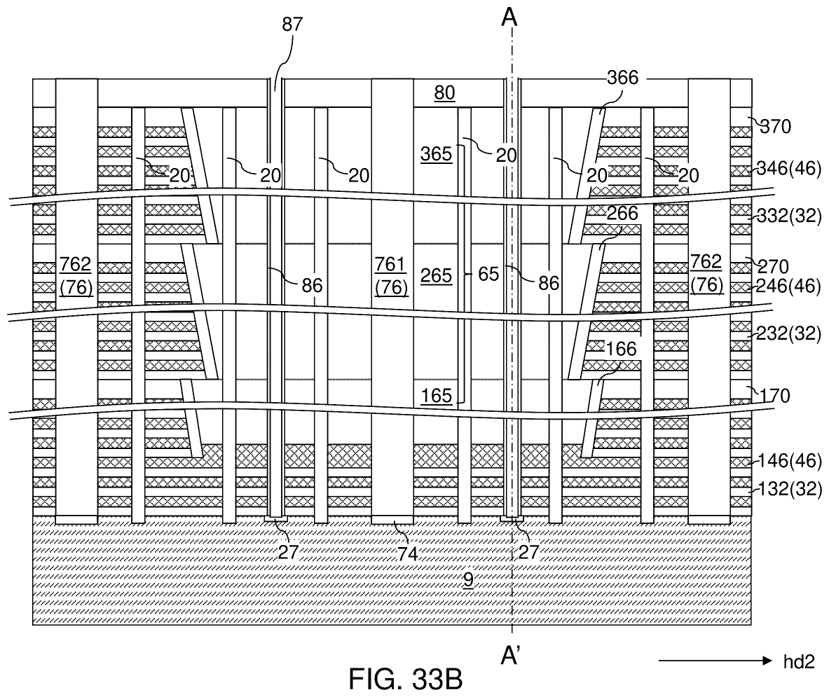

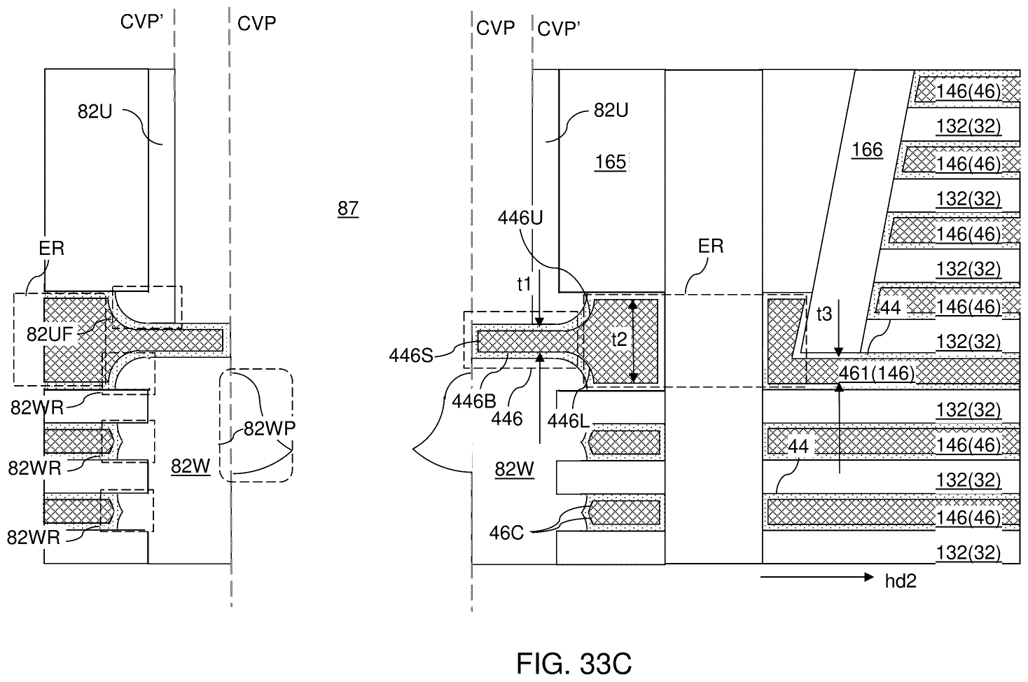

Referring to FIGS. 33A-33C, the sacrificial via fill structures (35, 37) can be removed selectively to the contact-level dielectric layer 80 and the lateral isolation trench fill structures 76 by performing a selective removal process, such as a selective etch process or an ashing process for carbon based sacrificial via fill structures (35, 37). Voids 87 are formed in the volumes from which the sacrificial via fill structures 83 are removed.

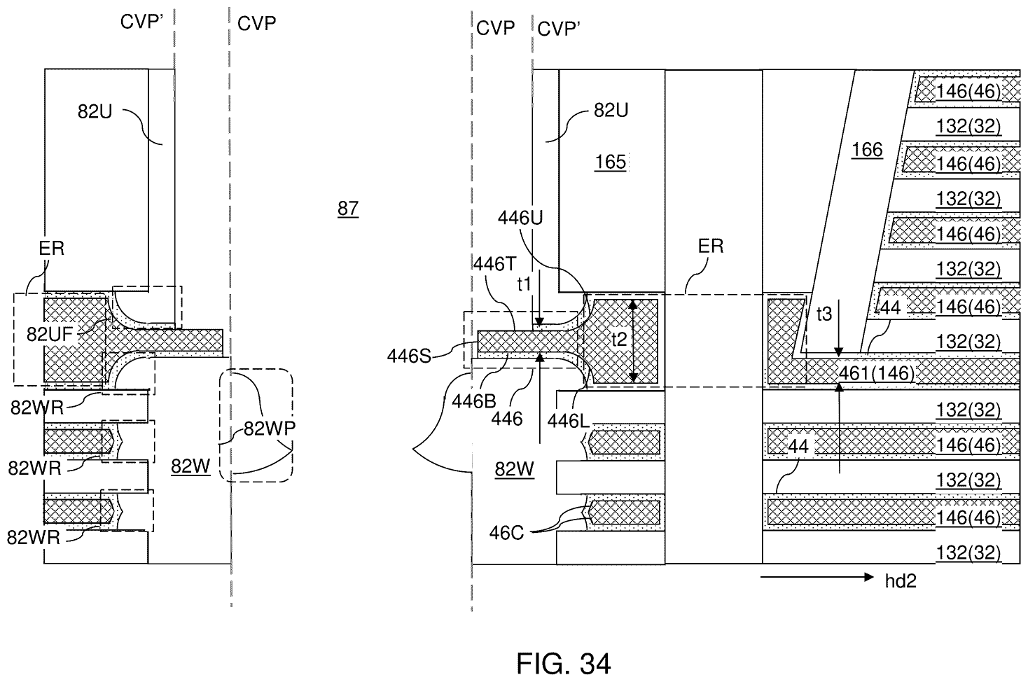

Referring to FIG. 34, a selective etch process can be performed to remove physically exposed proximal portions of the outer blocking dielectric layers selectively to the electrically conductive layers 46, the upper tubular dielectric spacers 82U, and the lower tubular dielectric spacers 82W around the voids 87. The selective etch process may comprise an isotropic etch process (such as a wet etch process) or an anisotropic etch process (such as a reactive ion etch process). A cylindrical sidewall 446S and the planar top surface segment 446T of the respective first electrically conductive layer 461 can be physically exposed around each void 87.

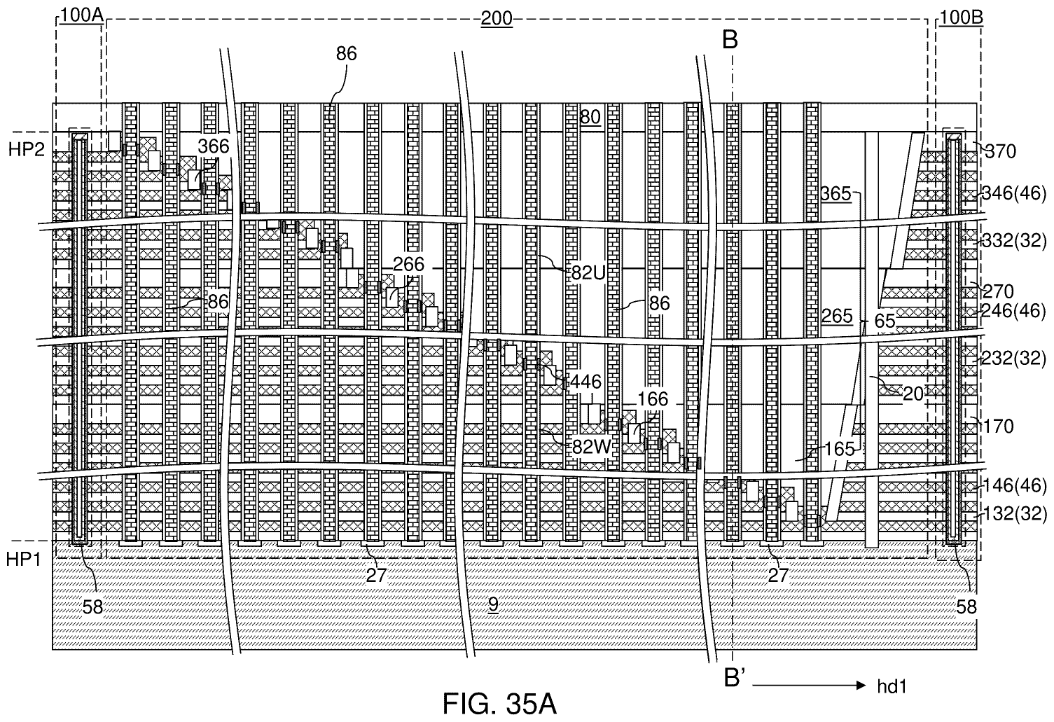

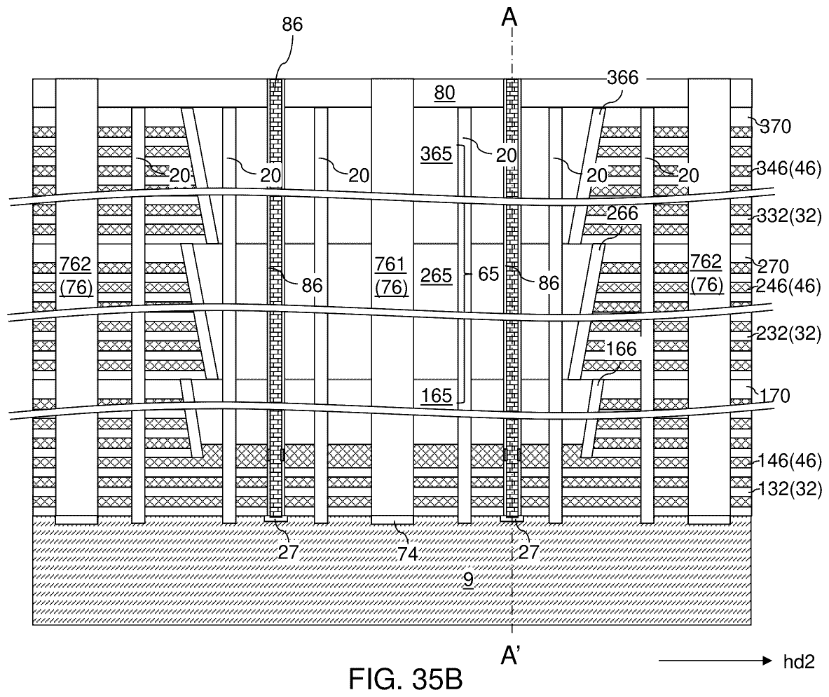

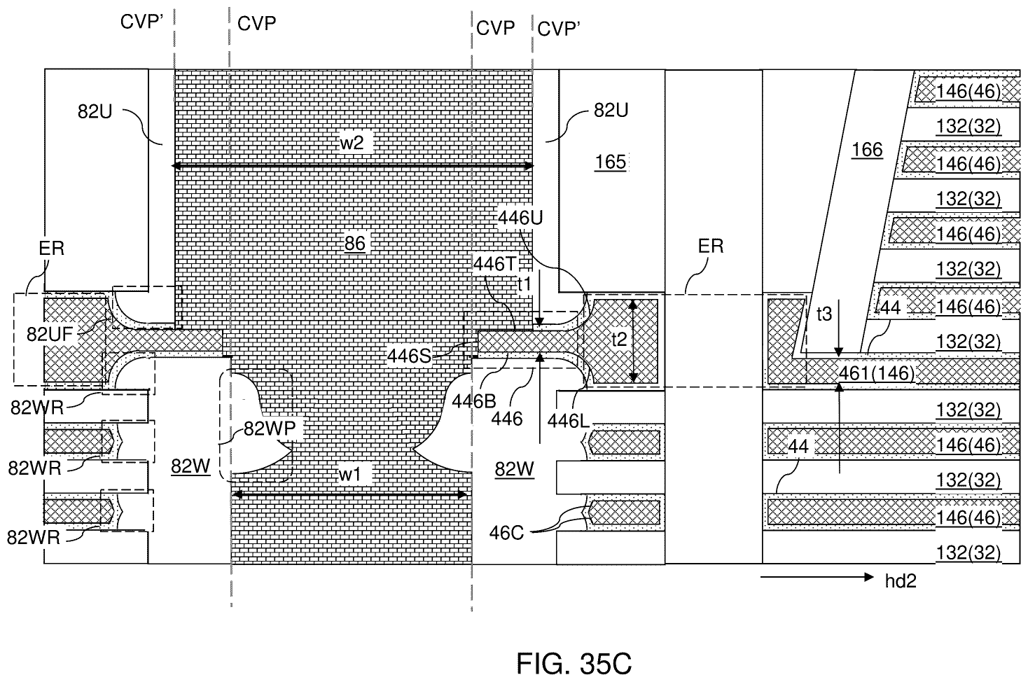

Referring to FIGS. 35A-35C, at least one electrically conductive material can be deposited in each void 87. Excess portions of the at least one electrically conductive material can be removed from above the horizontal plane including the top surface of the contact-level dielectric layer 80. Each remaining portion of the at least one electrically conductive material that fills a respective one of the voids 87 constitutes a layer contact via structure 86 that contacts a respective first electrically conductive layer 461 of the electrically conductive layers 46. Each layer contact via structure 86 vertically extends through a respective subset of the insulating layers 32 and through a respective subset of the electrically conductive layers 46.

The layer contact via structure 86 contacts the top planar surface segment 446T and the cylindrical sidewall 446S of the first electrically conductive layer 461, i.e., the planar top surface segment 446T and the cylindrical sidewall 446S of the annular thinned region 446 of the first electrically conductive layer 461. The outer blocking dielectric layer 44 remains on the planar bottom surface 446B of the annular thinned region 446 of the first electrically conductive layer 461.

In one embodiment, each electrically conductive layer 46 of the respective subset of the electrically conductive layers 46 except the first electrically conductive layer 461 comprises a pair of annular concave surfaces 46C that are adjoined to each other at a closed edge located within a respective horizontal plane (e.g., at a point in a vertical plane). The annular concave surfaces 46C are located opposite to the convex surfaces of the annular rib portions 82WR.

Thus, a combination of an upper tubular dielectric spacer 82U, a lower tubular dielectric spacer 82W, and an annular thinned region 446 of a respective first electrically conductive layer 461 may fill a peripheral region of each contact via cavity 25 as formed at the processing steps of FIG. 16B, and a layer contact via structure 86 can be formed in a center region of the contact via cavity 25.

In one embodiment, the at least one electrically conductive material of the layer contact via structure 86 may comprise a metallic barrier material and a metal fill material. The metallic barrier material comprises a metallic diffusion barrier material. For example, the metallic barrier material comprises a conductive metallic nitride material such as TiN, TaN, WN, and/or MoN. The metallic barrier material may be deposited as a continuous material layer having a uniform thickness throughout by a conformal deposition process such as a chemical vapor deposition process. The metal fill material portion 86F comprises a metal fill material that provides high electrical conductivity. For example, the metal fill material comprises, and/or consists essentially of, an elemental metal such as W, Co, Ru, Mo, Cu, or a combination thereof. The metal fill material may be formed by a conformal deposition process, such as a chemical vapor deposition process. Thus, each sacrificial via fill structure (35, 37) can be replaced with a layer contact via structure 86 such that the layer contact via structure 86 contacts at least an annular planar top surface segment 446T and the cylindrical sidewall 446S of the first electrically conductive layer 461.

In one embodiment, an annular planar bottom surface segment 446B of the annular region 446 of the first electrically conductive layer 461 is not in direct contact with the layer contact via structure 86, or has a lesser contact area with the layer contact via structure 86 than the annular planar top surface segment 446T of the annular region 446 of the first electrically conductive layer 461 (if the outer blocking dielectric layer 44 is undercut below the annular region 446). In one embodiment, the cylindrical sidewall 446S of the annular region 446 of the first electrically conductive layer 461 is laterally offset outward relative to a cylindrical vertical plane CVP.

In one embodiment, each layer contact via structure 86 comprises a lower cylindrical sidewall in contact with an inner cylindrical sidewall of the lower tubular dielectric spacer 82W within (i.e., surrounded by) a cylindrical vertical plane CVP. In one embodiment, the layer contact via structure 86 comprises an upper cylindrical sidewall in contact with an inner cylindrical sidewall of the upper tubular dielectric spacer 82U within another cylindrical vertical plane CVP′ that is laterally offset outward relative to the cylindrical vertical plane CVP.

In one embodiment, each layer contact via structure 86 vertically extends from a bottom horizontal plane including a bottommost surface of the alternating stack (32, 46) to at least a top horizontal plane including a topmost surface of the alternating stack (32, 46); and, for each layer contact via structure 86, the annular region 446 of the respective first electrically conductive layer 461 laterally protrudes farther inward toward the layer contact via structure 86 than any underlying ones of the electrically conductive layers 46.

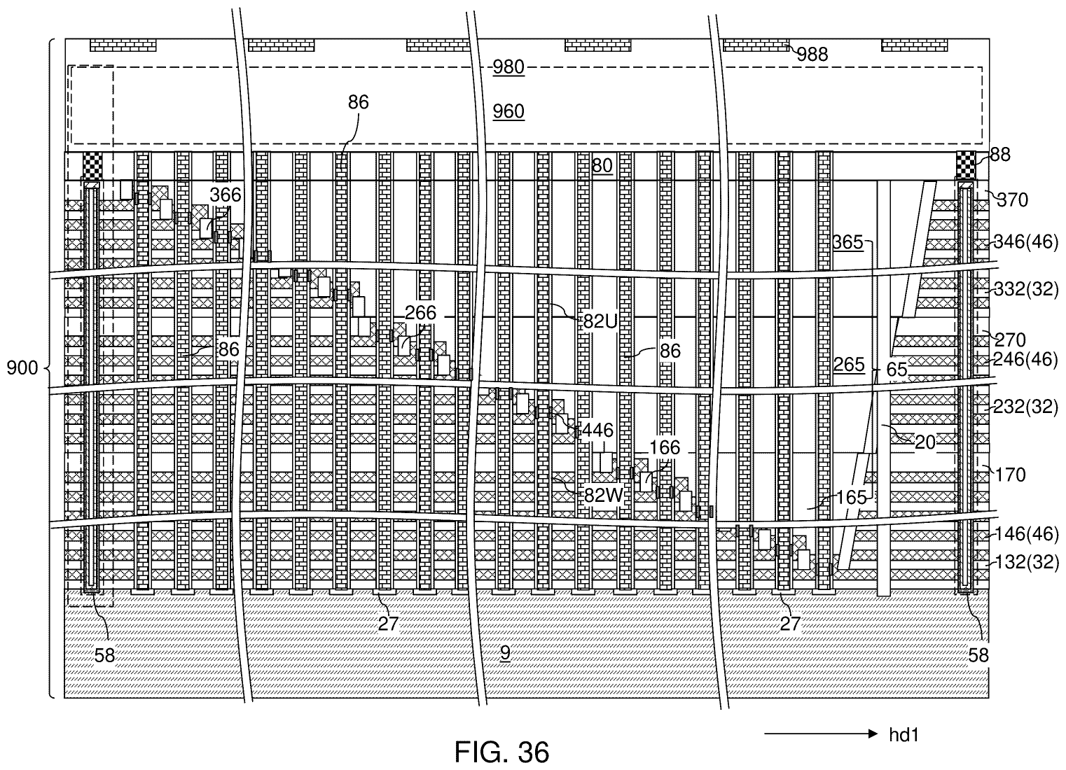

Referring to FIG. 36, the processing steps described with reference to FIG. 24 can be performed to form drain contact via structures 88, memory-side dielectric material layers 960, memory-side metal interconnect structures 980, and memory-side bonding pads 988.

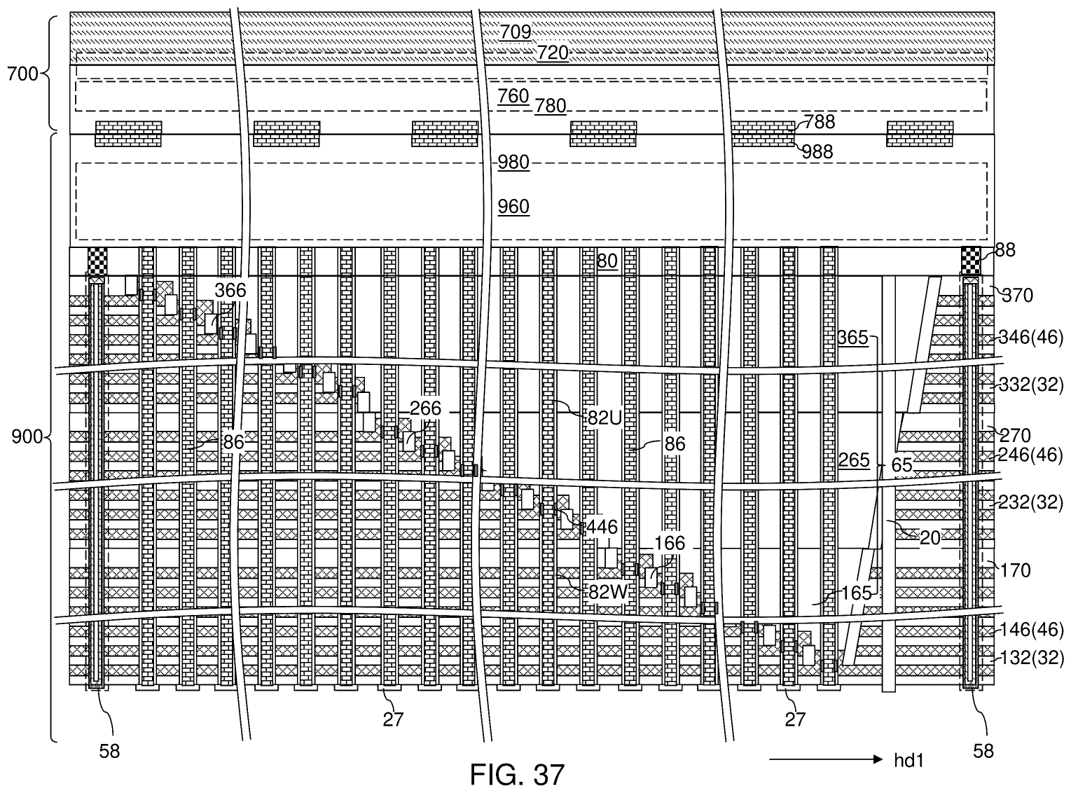

Referring to FIG. 37, the processing steps described with reference to FIG. 25 can be performed to remove the substrate 9.

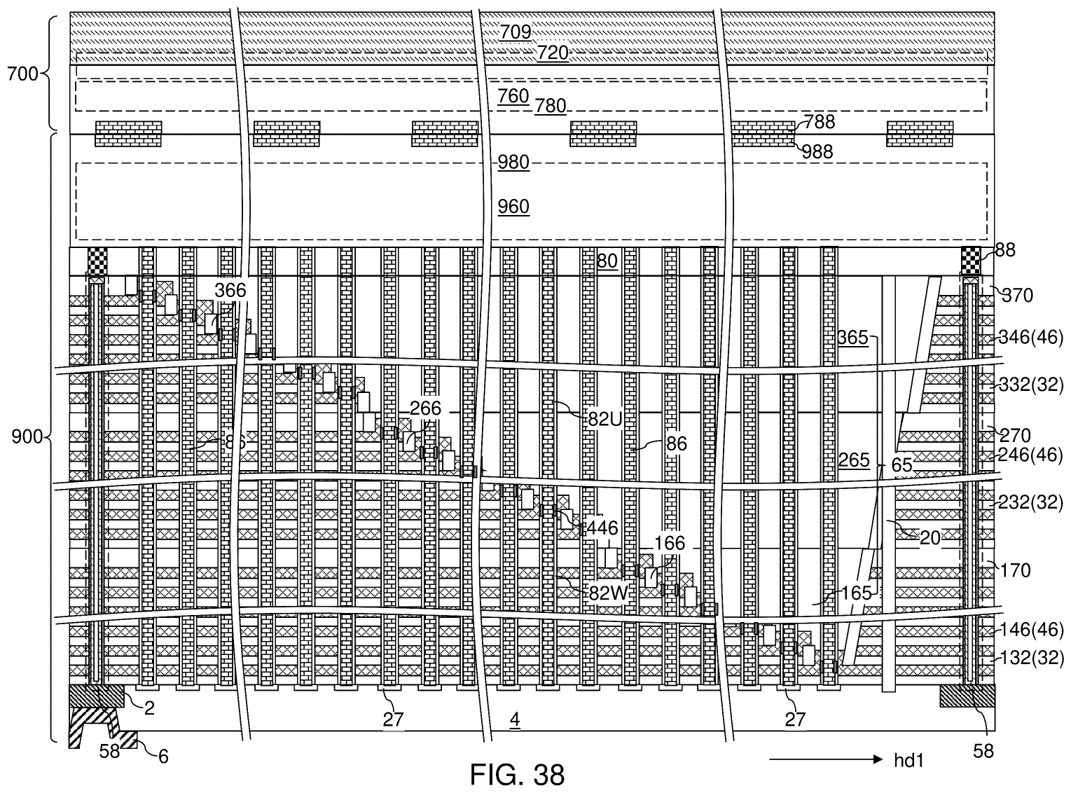

Referring to FIG. 38, the processing steps described with reference to FIG. 26 can be performed to form at least one source structure 2, a backside dielectric layer 4, and backside contact structures 6 can be subsequently formed.

Referring collectively to FIGS. 1A-38 and according to various embodiments of the present disclosure, a device structure is provided, which comprises: an alternating stack (32, 46) of insulating layers 32 and electrically conductive layers 46; a memory opening 49 vertically extending through each layer within the alternating stack (32, 46); a memory opening fill structure 58 located in the memory opening 49 and comprising a vertical stack of memory elements and a vertical semiconductor channel 60; a layer contact via structure 86 vertically extending through a subset of the insulating layers 32 and through a subset of the electrically conductive layers 46, and in contact with at least a planar annular top surface segment 446T and a cylindrical sidewall 446S of an annular region 446 of a first electrically conductive layer 461 which is a topmost electrically conductive layer of the subset of the electrically conductive layers 46; and a lower tubular dielectric spacer 82W vertically extending through each of the subset of the insulating layers 32 and each of the subset of the electrically conductive layers 46 except the first electrically conductive layer 461, and in contact with the layer contact via structure 86.

In one embodiment, a dielectric metal oxide outer blocking dielectric layer 44 contacts a planar annular bottom surface segment 446B of the annular region 446 of a first electrically conductive 461 and the lower tubular dielectric spacer 82W. In one embodiment, the annular bottom surface segment of the annular region 446 of the first electrically conductive layer 461 is not in direct contact with the layer contact via structure 86, or has a lesser contact area with the layer contact via structure 86 than the annular top surface segment of the annular region 446 of the first electrically conductive layer 461.

In one embodiment, the lower tubular dielectric spacer 82W comprises: an inner cylindrical sidewall segment that is located within a cylindrical vertical plane CVP and contacts a first surface segment of the layer contact via structure 86; and an annular inner protrusion region 82WP that is located within a volume that is laterally surrounded by the cylindrical vertical plane CVP and having a bottom periphery that is adjoined to a top periphery of the inner cylindrical sidewall segment. In one embodiment, a sidewall of the annular inner protrusion region 82WP has a bell-shaped vertical cross-sectional profile that includes, from top to bottom, a convex tapered top surface segment, a concave tapered top surface segment, and a convex tapered bottom surface segment. In one embodiment, the cylindrical sidewall of the annular region 446 of the first electrically conductive layer 461 is laterally offset outward relative to the cylindrical vertical plane CVP.

In one embodiment, the device structure comprises an upper tubular dielectric spacer 82U overlying the first electrically conductive layer 461 and in contact with the layer contact via structure 86. In one embodiment, the upper tubular dielectric spacer 82U comprises: a vertically-extending tubular portion having a uniform lateral thickness between an inner cylindrical sidewall and an outer cylindrical sidewall; and an annular base flange portion 82UF extending outward from a bottom end of the vertically-extending tubular portion. In one embodiment, the layer contact via structure 86 comprises a lower cylindrical sidewall in contact with an inner cylindrical sidewall of the lower tubular dielectric spacer 82W within a cylindrical vertical plane CVP. In one embodiment, the layer contact via structure 86 comprises an upper cylindrical sidewall in contact with an inner cylindrical sidewall of the upper tubular dielectric spacer 82U within another cylindrical vertical plane CVP′ that is laterally offset outward relative to the cylindrical vertical plane CVP.

In one embodiment, the lower tubular dielectric spacer 82W comprises a contoured inner sidewall and a contoured outer sidewall; the upper tubular dielectric spacer 82U comprises a vertically-extending tubular portion having a uniform lateral thickness between an inner cylindrical sidewall and an outer cylindrical sidewall; and a minimum lateral distance between the contoured inner sidewall of the lower tubular dielectric spacer 82W and the contoured outer sidewall of the lower tubular dielectric spacer 82W is greater than the uniform lateral thickness of the upper tubular dielectric spacer 82U. In one embodiment, the lower tubular dielectric spacer 82W comprises annular rib portions 82WR that laterally outward at levels of the subset of the electrically conductive layers 46 except at the level of the first electrically conductive layer 461, and are vertically spaced apart among one another.

In one embodiment, the layer contact via structure 86 vertically extends from a bottom horizontal plane including a bottom of the alternating stack to at least a top horizontal plate including a top of the alternating stack (32, 46); the annular region 446 of the first electrically conductive layer 461 has a first thickness t1; and the first electrically conductive layer 461 further comprises an enclosure region ER that laterally surrounds the annular region 446 and having a second thickness t2 that is greater than the first thickness t1. In one embodiment, a unform-thickness portion of the first electrically conductive layer 461 that laterally surrounds the memory opening fill structure 58 has a third thickness t3 that is less than the second thickness t2; and the enclosure region ER is located between the unform-thickness portion and the annular region 446. In one embodiment, the layer contact via structure 86 vertically extends from a bottom horizontal plane including a bottommost surface of the alternating stack (32, 46) to at least a top horizontal plane including a topmost surface of the alternating stack (32, 46); and the annular region 446 of the first electrically conductive layer 461 laterally protrudes farther inward toward the layer contact via structure 86 than any underlying ones of the electrically conductive layers 46.

In the second embodiment, the sacrificial encapsulation liner 35 is located close to the protruding portion 446 of the first electrically conductive layer 461 in the contact via cavity 25. This permits a more controlled formation of an insulating pedestal (i.e., the annular inner protrusion region) 82WP below the protruding portion 446 of the first electrically conductive layer 461, a greater control of the lateral thickness of the upper tubular spacer 82U, and reduces or prevents over etching of the lower tubular dielectric spacer 82W located below the liner 35. Thus, the lower tubular dielectric spacer 82W covers the sidewalls of the electrically conductive layers 46 located below the protruding portion 446 of the first electrically conductive layer 461 in the contact via cavity 25, and the chance of a short circuit between the contact via cavity 86 and the electrically conductive layers 46 located below the protruding portion 446 of the first electrically conductive layer 461 in the contact via cavity 25 is reduced. Furthermore, the insulating pedestal 82WP mechanically supports the protruding portion 446 of the first electrically conductive layer 461 in the contact via cavity 25, and thus permits formation of the protruding portion 446 having a sufficient lateral length for a larger contact area with the contact via cavity 86, and reduces the chance of downward collapse of the protruding portion 446 into the contact via cavity 25.

Although the foregoing refers to particular preferred embodiments, it will be understood that the disclosure is not so limited. It will occur to those of ordinary skill in the art that various modifications may be made to the disclosed embodiments and that such modifications are intended to be within the scope of the disclosure. Compatibility is presumed among all embodiments that are not alternatives of one another. The word “comprise” or “include” contemplates all embodiments in which the word “consist essentially of” or the word “consists of” replaces the word “comprise” or “include,” unless explicitly stated otherwise. Whenever two or more elements are listed as alternatives in a same paragraph or in different paragraphs, a Markush group including a listing of the two or more elements is also impliedly disclosed. Whenever the auxiliary verb “can” is employed in this disclosure to describe formation of an element or performance of a processing step, an embodiment in which such an element or such a processing step is not performed is also expressly contemplated, provided that the resulting apparatus or device can provide an equivalent result. As such, the auxiliary verb “can” as applied to formation of an element or performance of a processing step should also be interpreted as “may” or as “may, or may not” whenever omission of formation of such an element or such a processing step is capable of providing the same result or equivalent results, the equivalent results including somewhat superior results and somewhat inferior results. Where an embodiment employing a particular structure and/or configuration is illustrated in the present disclosure, it is understood that the present disclosure may be practiced with any other compatible structures and/or configurations that are functionally equivalent provided that such substitutions are not explicitly forbidden or otherwise known to be impossible to one of ordinary skill in the art. If publications, patent applications, and/or patents are cited herein, each of such documents is incorporated herein by reference in their entirety.

What is claimed is:

1. A device structure, comprising:
an alternating stack of insulating layers and electrically conductive layers;
a memory opening vertically extending through each layer within the alternating stack;
a memory opening fill structure located in the memory opening and comprising a vertical stack of memory elements and a vertical semiconductor channel;
a layer contact via structure vertically extending through a subset of the insulating layers and through a subset of the electrically conductive layers, and in contact with at least a planar annular top surface segment and a cylindrical sidewall of an annular region of a first electrically conductive layer which is a topmost electrically conductive layer of the subset of the electrically conductive layers; and
a lower tubular dielectric spacer vertically extending through each of the subset of the insulating layers and each of the subset of the electrically conductive layers except the first electrically conductive layer, and in contact with the layer contact via structure.

2. The device structure of claim 1, further comprising a dielectric metal oxide outer blocking dielectric layer which contacts a planar annular bottom surface segment of the annular region of a first electrically conductive and the lower tubular dielectric spacer.

3. The device structure of claim 2, wherein the planar annular bottom surface segment of the annular region of the first electrically conductive layer is not in direct contact with the layer contact via structure, or has a lesser contact area with the layer contact via structure than the annular top surface segment of the annular region of the first electrically conductive layer.

4. The device structure of claim 1, wherein the lower tubular dielectric spacer comprises:
an inner cylindrical sidewall segment that is located within a cylindrical vertical plane and contacts a first surface segment of the layer contact via structure; and
an annular inner protrusion region that is located within a volume that is laterally surrounded by the cylindrical vertical plane and having a bottom periphery that is adjoined to a top periphery of the inner cylindrical sidewall segment.

5. The device structure of claim 4, wherein a sidewall of the annular inner protrusion region has a bell-shaped vertical cross-sectional profile that includes, from top to bottom, a convex tapered top surface segment, a concave tapered top surface segment, and a convex tapered bottom surface segment.

6. The device structure of claim 5, wherein the cylindrical sidewall of the annular region of the first electrically conductive layer is laterally offset outward relative to the cylindrical vertical plane.

7. The device structure of claim 1, further comprising an upper tubular dielectric spacer overlying the first electrically conductive layer and in contact with the layer contact via structure.

8. The device structure of claim 7, wherein the upper tubular dielectric spacer comprises:
a vertically-extending tubular portion having a uniform lateral thickness between an inner cylindrical sidewall and an outer cylindrical sidewall; and
an annular base flange portion extending outward from a bottom end of the vertically-extending tubular portion.

9. The device structure of claim 7, wherein the layer contact via structure comprises a lower cylindrical sidewall in contact with an inner cylindrical sidewall of the lower tubular dielectric spacer within a cylindrical vertical plane.

10. The device structure of claim 9, wherein the layer contact via structure comprises an upper cylindrical sidewall in contact with an inner cylindrical sidewall of the upper tubular dielectric spacer within another cylindrical vertical plane that is laterally offset outward relative to the cylindrical vertical plane.

11. The device structure of claim 7, wherein:
the lower tubular dielectric spacer comprises a contoured inner sidewall and a contoured outer sidewall;
the upper tubular dielectric spacer comprises a vertically-extending tubular portion having a uniform lateral thickness between an inner cylindrical sidewall and an outer cylindrical sidewall; and
a minimum lateral distance between the contoured inner sidewall of the lower tubular dielectric spacer and the contoured outer sidewall of the lower tubular dielectric spacer is greater than the uniform lateral thickness of the upper tubular dielectric spacer.

12. The device structure of claim 1, wherein:
the lower tubular dielectric spacer comprises annular rib portions having convex surfaces that laterally outward at levels of the subset of the electrically conductive layers except at the level of the first electrically conductive layer, and are vertically spaced apart from each other; and
the subset of the electrically conductive layers comprise pairs of annular concave surfaces that are adjoined to each other at a closed edge located within a respective horizontal plane, and are located opposite to the convex surfaces of the annular rib portions.

13. The device structure of claim 1, wherein:
the layer contact via structure vertically extends from a bottom horizontal plane including a bottom of the alternating stack to at least a top horizontal plate including a top of the alternating stack;
the annular region of the first electrically conductive layer has a first thickness; and
the first electrically conductive layer further comprises an enclosure region that laterally surrounds the annular region and having a second thickness that is greater than the first thickness.

14. The device structure of claim 13, wherein:
a unform-thickness portion of the first electrically conductive layer that laterally surrounds the memory opening fill structure has a third thickness that is less than the second thickness; and
the enclosure region is located between the unform-thickness portion and the annular region.

15. A method of forming a device structure, comprising:
forming an alternating stack of insulating layers and sacrificial material layers over a substrate;
forming memory stack structures through the alternating stack, wherein each of the memory stack structures comprises a respective vertical stack of memory elements located at levels of the sacrificial material layers and a vertical semiconductor channel;
forming a contact via cavity through a subset of the sacrificial material layers within the alternating stack and a subset of the insulating layers within the alternating stack;
laterally recessing each layer within the subset of the insulating layers and the subset of the sacrificial material layers other than a first sacrificial material layer which is a topmost sacrificial material layer of the subset of the sacrificial material layers by a respective lateral recess distance that is greater than a lateral recess distance for the first sacrificial material layer;
depositing a dielectric spacer material layer in a peripheral region of the contact via cavity;
patterning the dielectric spacer material layer into a lower dielectric tubular spacer and an upper dielectric tubular spacer;
forming a sacrificial via fill structure within a volume that is laterally surrounded by the upper dielectric tubular spacer and the lower dielectric tubular spacer;
replacing the sacrificial material layers with electrically conductive layers, wherein the first sacrificial material layer is replaced at least with a first electrically conductive layer; and
replacing the sacrificial via fill structure with a layer contact via structure such that the layer contact via structure contacts at least a cylindrical sidewall of the first electrically conductive layer.

16. The method of claim 15, wherein the dielectric spacer material layer is patterned such that a minimum lateral thickness of the lower dielectric tubular spacer is greater than a uniform lateral thickness of a tubular portion of the upper dielectric tubular spacer.

17. The method of claim 15, wherein a necked void is formed in a volume of the contact via cavity that is not filled with the dielectric spacer material layer upon formation of the dielectric spacer material layer, wherein the necked void has a neck region at a level of the first sacrificial material layer.

18. The method of claim 17, further comprising forming an X-shaped sacrificial encapsulation liner by conformally depositing a sacrificial fill liner layer in the necked void and removing a portion of the sacrificial fill liner layer from an upper volume of the necked void, wherein a combination of the sacrificial encapsulation liner and an encapsulated void is formed within a lower volume of the necked void.

19. The method of claim 18, further comprising:
performing an isotropic etch process that etches a physically exposed portion of the dielectric spacer material layer selectively to a material of the sacrificial encapsulation liner after formation of the sacrificial encapsulation liner; and
performing an anisotropic etch process that etches an additional portion of the dielectric spacer material layer, wherein an upper remaining portion of the dielectric spacer material layer comprises the upper dielectric tubular spacer, and a lower remaining portion of the dielectric spacer material layer comprises the lower dielectric tubular spacer.

20. The method of claim 15, further comprising:
forming stepped surfaces by patterning the alternating stack in a staircase region;
thickening portions of the sacrificial material layers that are physically exposed at the stepped surfaces, wherein the first sacrificial material layer comprises a first nominal thickness region and a first thickened region that are physically exposed in the staircase region;
laterally recessing the subset of the insulating layers around the contact via cavity by performing a first isotropic etch process that etches a material of the insulating layers selectively to a material of the sacrificial material layers; and
isotropically etching the subset of the sacrificial material layers around the contact via cavity by performing a second isotropic etch process, wherein a remaining portion of the first thickened region comprises an annular thinned region that is laterally surrounded by an enclosure region which comprises a portion of the first thickened region that is not thinned by the second isotropic etch process.
